(19) United States
(12) Patent Application Publication
(10) Pub. No.: US 2026/0212080 A1
(43) Pub. Date: Jul. 23, 2026

(54) Autoencoders for the Processing of 3D Representations in Digital Oral Care

(71) Applicant: Solventum Intellectual Properties Company, Maplewood, MN (US)

(72) Inventors: Michael B. Starr, Toomevara (IE); Jonathan D. Gandrud, Woodbury, MN (US); Seyed Amir Hossein Hosseini, Saint Paul, MN (US); Mariah Sonja Pereira Penha, Dublin (IE)

(21) Appl. No.: 19/139,465

(22) PCT Filed: Dec. 14, 2023
(86) PCT No.: PCT/IB2023/062710

§ 371 Date: Jun. 16, 2025

Related U.S. Application Data
(60) Provisional application No. 63/432,627, filed on Dec. 14, 2022.
(60) Provisional application No. 63/462,855, filed on Apr. 28, 2023.

(51) Int. Cl. G06F 30/27

(52) U.S. Cl. CPC G06F 30/27

(57) ABSTRACT

Systems and techniques for encoding and reconstructing three-dimensional (3D) representations of oral care data are disclosed. The method involves receiving an input 3D representation of oral care data and utilizing the processing circuitry to execute an encoder of a trained autoencoder network. The encoder encodes the input 3D representation into a latent space representation with a lower dimensionality. Subsequently, the processing circuitry executes a decoder of the trained autoencoder network to reconstruct the latent space representation, generating an output 3D representation that closely resembles the original input. To quantify the accuracy of the reconstruction, the processing circuitry computes a reconstruction error, which measures the difference between at least one mesh element of the input 3D representation and the corresponding mesh element of the output 3D representation. Efficient encoding and reconstruction of 3D representations of oral care data, facilitating improved analysis, diagnosis, and treatment planning in oral care applications is realized.

### RELATED DOCUMENTS

The entire disclosure of PCT Application No. PCT/IB2022/057373 is incorporated herein by reference. The entire disclosures of each of PCT Applications with Publication Nos. WO2022123402A1, WO2021245480A1, and WO2020026117A1 are incorporated herein by reference. The entire disclosure of each of the following Provisional U.S. patent applications is incorporated herein by reference: 63/432,627; 63/366,492; 63/366,495; 63/352,850; 63/366,490; 63/366,494; 63/370,160; 63/366,507; 63/352,877; 63/366,514; 63/366,498; 63/366,514; and 63/264,914.

### TECHNICAL FIELD

This disclosure relates to configurations and training of neural networks to improve the accuracy of automatic cleanup and improvement operations for 3D oral care representations, such as 3D triangle meshes, using autoencoders.

### SUMMARY

The present disclosure describes systems and techniques for training and using one or more machine learning models, such as neural networks, to perform cleanup operations of 3D oral care representations, such as 3D triangle meshes. Such cleanup operations may include techniques to detect anomalies in 3D meshes, techniques to remove anomalies from 3D meshes and techniques to replace or fill-in missing portions of a 3D mesh (e.g., portions of a 3D mesh where a hole or rough edge were created by the removal of anomalous aspects of the mesh). The techniques may be trained to identify (e.g., using an encoder-decoder structure, such as a variational autoencoder) mesh elements which require further processing, such as removal. The techniques may be trained to fill in missing portions of a mesh (e.g., using an encoder-decoder structure, such as a masked autoencoder). Encoder-decoder structures may be trained to perform such mesh cleanup techniques, which may in some implementations add one or more mesh elements to a trial 3D mesh, may in some implementations remove one or more mesh elements from a trial 3D mesh, or may in some implementations transform (e.g., translate, rotate, smooth and the like) one or more mesh elements in a trial 3D mesh. An encoder-decoder structure may include at least one encoder or at least one decoder. Non-limiting examples of an encoder-decoder structure include a 3D U-Net, a transformer, a pyramid encoder-decoder or an autoencoder, among others. Non-limiting examples of autoencoders include variational autoencoders, regularized autoencoders, masked autoencoders or capsule autoencoders.

An example of anomaly detection is described as follows. An encoder-decoder structure may be trained to reconstruct a 3D triangle mesh of a particular type of 3D oral care representation (e.g., a tooth, comprising crown and/or root). Such an encoder-decoder structure may, in some implementations, be trained to perform the reconstruction of a particular tooth type, so as to become adept at reconstructing that particular type of tooth (e.g., an upper right 1^{st} molar or a lower left central incisor). After training is complete, the encoder-decoder structure may be deployed for use in digital oral care (e.g., for oral care appliance generation). A trial tooth crown mesh may be introduced to the input of the reconstruction encoder-decoder structure (e.g., a variational autoencoder which has been trained to reconstruct 3D oral care representations—examples of which are disclosed herein, optionally utilizing continuous normalizing flows) and be encoded into a latent form which may subsequently undergo reconstruction. When a reconstruction autoencoder is trained to reconstruct a particular type of 3D oral care representation, such as a tooth crown, reconstruction error may be computed for use in anomaly detection. For example, a reconstruction autoencoder may be trained to reconstruct a particular tooth crown type. Reconstruction error may be computed to quantify the difference between a trial input crown and a reconstructed crown. In the event that the reconstruction error is below a threshold, the anomaly detection model may conclude that the trial input crown mesh was of the distribution of crown meshes that was used to train the reconstruction autoencoder. That is, if a normal upper right central incisor is presented to the input of an autoencoder that was trained to reconstruct upper right central incisors from a dataset of cohort patient cases, then the reconstruction error can reasonably be expected to be less than a threshold.

However, if the input crown mesh is not from the distribution of crown meshes that was used to train the reconstruction autoencoder (e.g., the crown mesh has hardware—such as an orthodontic bracket—installed), then the reconstruction error can be expected to be above a threshold, signaling the presence of an anomaly. The reconstruction error may be computed for localized portions of the reconstructed tooth mesh, even at the level of granularity of the mesh element (e.g., vertex, point, face, edge or voxel), and so one or more subsections of the reconstructed tooth mesh may be flagged as anomalous. In some implementations, one or more of the anomalous aspects (e.g., mesh element features), may undergo modification (e.g., using mesh processing techniques know to one skilled in the art—such as mesh element removal or smoothing). In the case of orthodontic treatment, a patient's teeth may be scanned by an intraoral scanner, yielding 3D points. The 3D points (e.g., a point cloud) may be converted into a 3D mesh. The 3D mesh of the scanned dental arch may undergo segmentation, yielding a 3D mesh of each crown, which can then be used in the generation of oral care appliances, such as clear aligner trays. Sometimes the patient may already have hardware attached to the teeth at the time that such a intraoral scan is performed. Appliance generation (e.g., such as the generation of clear tray aligners) may, in some instances, proceed more smoothly if the hardware is removed. The anomaly detection techniques described herein (e.g., anomaly detection autoencoders) may be trained to detect hardware on the patient's teeth, so that the hardware may subsequently be removed from 3D meshes of a patient's teeth (e.g., using automated processes). Such an automated anomaly detection procedure may, in some implementations, be performed with greater data precision than by a technician (e.g., in a manufacturing environment) or by a clinician (e.g., “chairside” in the clinic—so that the results of anomaly detection may be used as a part of mesh cleanup operations that are performed as a part of automated appliance creation operations which may be performed in the clinician's office—for example—in the case that an appliance is to be 3D printed “same day” in the doctor's office).

An example of 3D mesh in-filling is as follows. A masked encoder-decoder structure, such as a masked autoencoder, may be trained on examples of 3D oral care representations, such as crowns and/or roots. For each training example, a mask may be applied (e.g., a stochastically generated mask), which may flag one or more aspects of an input 3D mesh (e.g., one or more mesh elements). A masked autoencoder may be trained for reconstruction. In some implementations, the masked autoencoder may be ignore the masked aspects of the inputted 3D oral care representation (e.g., may ignore the flagged mesh elements). The masked autoencoder may be trained using many such masked examples of 3D oral care representations (e.g., 3D meshes of tooth crowns and/or roots) and become capable to reconstruct the inputted 3D oral care representation in spite of the masked aspects (e.g., masked or hidden mesh elements) of the inputted 3D oral care representation. This process of masking the input training examples may serve to augment the training dataset, to an extent. The training of an autoencoder may, in some implementations, continue until the reconstruction error of the reconstructed meshes drops below a threshold. Reconstruction error may be computed for a whole 3D oral care representation or one or more portions of the 3D oral care representation (e.g., reconstruction error may flag or label sets of mesh elements as corresponding to anomalies in a reconstructed tooth mesh, such as hardware, extraneous material, divots, undercuts, abfractions, lingual bars, or the like).

The methods of this disclosure may train an ML model (e.g., a masked autoencoder) to fill-in missing aspects of a 3D representation (e.g., missing mesh elements). A masked autoencoder may be trained, at least in part, on a data of masked 3D representations. A masked autoencoder may be trained to function as a type of reconstruction autoencoder (e.g., which has been configured to impute missing data). A variational autoencoder (VAE) may, in some implementations, be trained for such imputation. A 3D representation may be masked by replacing at least one aspect of the 3D representation in the training dataset with a masking token (e.g., replacing at least one coordinate of one mesh element of the 3D representation with a masking token). For example, when a masked autoencoder is trained to fill-in missing portions of a 3D mesh of a tooth (e.g., portions that were occluded during intra-oral scanning), training examples may be generated by replacing at least one coordinate of at least one mesh element of the input 3D representation of oral care data (e.g., a mesh describing a tooth or other aspects of dentition) with a masking token. The masked autoencoder may be trained to reconstruct the input 3D representation, in spite of the missing data (e.g., as a reconstruction autoencoder that fills-in missing data according to the distribution of the training dataset). Stated another way, the masked autoencoder may be trained to reconstruct the masked aspects of the input 3D representation of oral care data (e.g., masked mesh elements of a tooth). A mesh element may include a vertex, an edge, a face, voxel or a point. For example, the input 3D representation of oral care data may be either a 3D mesh or a 3D point cloud. In some implementations, a mask (e.g., which involves the use of a masking token) may be applied to the input 3D oral care representation prior to providing the training data to the masked autoencoder. In some implementations, a mask may be randomly generated. In some implementations, the masking token may be provided to the masked autoencoder, and may signal to the masked autoencoder that the masked mesh element is present in a structure of the input 3D oral care representation, but one or more of the mesh element features in the corresponding mesh element feature vector (e.g., XYZ coordinates) of that mesh element are not made available to the autoencoder. In some implementations, the modified 3D oral care representation may include a plurality of mesh elements masked in contiguous blocks. In some implementations, the input 3D representation of oral care data represents a tooth (e.g., a tooth mesh, etc.). In some implementations, training the masked autoencoder may involve training the masked autoencoder based on the distribution of a dataset which is associated with the input 3D oral care mesh. In some implementations, the masked autoencoder may comprise a multi-dimensional encoder configured to encode the input 3D oral care representation into a latent space representation and a multi-dimensional decoder configured to reconstruct the latent space representation into the facsimile of the input 3D oral care representation. In some implementations, a reconstruction error may be computed to quantify a difference between the input 3D oral care representation and the facsimile of the input 3D oral care representation. In some implementations, the reconstruction error may be associated with at least one of a reconstruction loss calculation or KL-divergence calculation. In some implementations, additional inputs to the masked autoencoder may include at least one of: (i) one or more vectors P containing at least one value pertaining to at least one method of computing a dimension of at least one tooth, or (ii) one or more vectors R at least one of tooth name, designation, tooth type and tooth classification.

Methods of this disclosure may train a reconstruction autoencoder (e.g., a variational autoencoder network), which contains one or more encoders and one or more decoders. The encoder of a trained reconstruction autoencoder network may encode an input 3D oral care representation into a latent space representation. The decoder of the trained autoencoder network may reconstruct the latent space representation to form an output 3D oral care representation that is a facsimile of the input 3D oral care representation. In some implementations, a reconstruction error may be computed to quantify a difference between a at least one mesh element of the input 3D oral care representation and a corresponding at least one mesh element of the output 3D oral care representation. Anomaly detection may be performed based on the reconstruction error. The input 3D oral care representation may comprise at least one of a 3D mesh, a point cloud, or a voxelized representation. In some implementations, a mesh element (and the corresponding mesh element) are at least one of a respective edge, a respective vertex, a respective face, a respective voxel, or a respective point of a point cloud. When the reconstruction error exceeds a predetermined threshold value for one or more mesh elements in the input 3D representation of oral care data, the at least one mesh element or the corresponding at least one mesh element may receive a classification label. For example, when a tooth mesh with attached hardware is provided to a trained reconstruction autoencoder, the reconstruction autoencoder may generate a reconstructed tooth mesh that has high reconstruction error (e.g., the reconstructed mesh elements corresponding to the attached hardware may be flagged with high reconstruction error, because those mesh elements are not drawn from the distribution of the training dataset that the reconstruction autoencoder was trained to reconstruct). In some implementations, computing the reconstruction error may involve computing a distance between at least one aspect of the input 3D representation of oral care data and the corresponding aspect in the output 3D representation of oral care data. In some implementations, the trained autoencoder network may be trained according to a paradigm that includes continuous normalizing flows. The input 3D representation(s) of oral care data may include one or more 3D meshes or one or more 3D point clouds describing one or more teeth of the input 3D oral care representation to the trained autoencoder network. Optional additional inputs to the trained autoencoder may include: (i) one or more vectors P containing at least one value pertaining to at least one method of computing a dimension of at least one tooth, or (ii) one or more vectors R at least one of tooth name, designation, tooth type and tooth classification. The autoencoder may be trained, at least in part, through the calculation of loss, such a loss associated with at least one of a term associated with a reconstruction loss calculation, or a term associated with a KL-divergence loss calculation. Methods of this disclosure may, in some instances, be deployed at a clinical context.

### BRIEF DESCRIPTION OF DRAWINGS

FIG. 1 shows a method of augmenting training data for use in training machine learning (ML) models of this disclosure.

FIG. 2 shows a method of training a capsule autoencoder.

FIG. 3 shows a method of training a tooth reconstruction autoencoder.

FIG. 4 shows a method of using a deployed tooth reconstruction autoencoder.

FIG. 5 shows a reconstructed tooth mesh, which has been reconstructed using a reconstruction autoencoder, according to techniques of this disclosure.

FIG. 6 shows a reconstructed tooth mesh, which has been reconstructed using a reconstruction autoencoder, according to techniques of this disclosure.

FIG. 7 shows a visualization of reconstruction error for a tooth.

FIG. 8 shows reconstruction error values for several tooth reconstructions.

FIG. 9 shows method of training a reconstruction autoencoder.

FIG. 10 shows non-limiting example code for a reconstruction autoencoder.

FIG. 11 shows examples of 3D representations which have been reconstructed, according to techniques of this disclosure.

FIG. 12 shows a latent space where loss incorporates reconstruction loss but does not incorporate KL-Divergence loss.

FIG. 13 shows a latent space in which the loss includes both reconstruction loss and KL-divergence loss.

FIG. 14 shows a U-Net structure for use in a denoising diffusion probabilistic model for 3D representation segmentation.

FIG. 15 shows a method of training a capsule autoencoder to segment a 3D representation.

FIG. 16 describes techniques for mesh element labeling and/or mesh cleanup.

FIG. 17 shows a method of performing anomaly detection in 3D representations of the patient's dentition.

FIG. 18 shows a method of training a masked autoencoder to fill-in missing aspects of a 3D representation.

FIG. 19 shows a method of using a trained masked autoencoder to fill-in missing aspects of a 3D representation.

FIG. 20 shows a method of training a masked autoencoder to fill-in missing aspects of a 3D representation.

FIG. 21 shows a method of training a masked capsule autoencoder to fill-in missing aspects of a 3D representation.

FIG. 22 shows a U-Net structure, which may be used to extract hierarchical features from a 3D representation.

FIG. 23 shows a pyramid encoder-decoder structure, which may be used to extract hierarchical features from a 3D representation.

### DETAILED DESCRIPTION

Multiple techniques in digital oral care may benefit from the use of a first module (e.g., an autoencoder neural network) which has been trained to reconstruct a 3D oral care representation (e.g., trained to reconstruct a tooth mesh—comprising crown, root and/or attached articles). A 3D encoder may be trained to encode an oral care mesh into a latent form, and a 3D decoder may be trained to reconstruct that latent form into a facsimile of the received oral care mesh, where techniques disclosed herein may be used to measure the resulting reconstruction error. The first module may create a representation. A second module may use that representation for prediction. There may be one or more instances of the first module, and there may be one or more instances of the second module.

Described herein are techniques which may make use of an autoencoder which has been trained for oral care mesh reconstruction, which provides the advantage of encoding a potentially complex oral care mesh into a latent form (e.g., such as a latent vector or latent capsule) which may have reduced dimensionality and may be ingested by an instance of the second module (e.g., a predictive model for mesh cleanup, setups prediction, tooth restoration design generation, classification of 3D representations, validation of 3D representations, or setups comparison) for prediction purposes. While the dimensionality of the latent form may be reduced relative to the received oral care mesh, information about the reconstruction characteristics of the received oral care mesh may be retained. This latent representation of the original oral care mesh may be received as input to the predictive model of the second module, providing the advantage of improving accuracy and data precision in comparison to other techniques. The latent representation may, in some implementations, be modified according to the techniques of this disclosure to enable the predictive model of the second module to customize output data. An advantage of computing reconstruction error on a reconstructed oral care mesh is to verify that the reconstructed oral care mesh is a facsimile of the received oral care mesh (e.g., where one or more dimensions or other aspects of the reconstructed oral care mesh are measured to be within a threshold reconstruction error of the received oral care mesh). In some implementations, the first module may also be trained to produce other kinds of representations, such as those generated by neural networks performing convolution and/or pooling operations (e.g., a network with a size 5 convolution kernel which also performs average pooling, or a network such as a U-Net).

Either or both of the first and/or second modules may receive a variety of input data, as described herein, including tooth meshes for one or both arches of the patient. The tooth data may be presented in the form of 3D representations, such as meshes or point clouds. These data may be preprocessed, for example, by arranging the constituent mesh elements into lists and computing an optional mesh element feature vector for each mesh element. Such feature vectors may provide valuable information about the shape and/or structure of an oral care mesh to either or both of the first and/or second modules. For example, the first module, which generates the representations, may receive the vertices of a 3D mesh (or of a 3D point cloud) and compute a mesh element feature vector for each vertex. Such a feature vector may contain the XYZ coordinates of each vertex, in addition to other optional mesh element features described herein. Additional inputs may be received at the ingress point(s) of either or both of the first and/or second modules, such as one or more oral care metrics. Oral care metrics may be used for measuring one or more physical aspects of an oral care mesh (e.g., physical relationships within a tooth or between teeth). In some instances, an oral care metric may be computed for either or both of a malocclusion oral care mesh example and aground oral care mesh example which is then used in the training of either or both of the first and second modules. The metric value may be received as input of either or both of the first and second modules, as a way of training the underlying model of that particular module to encode a distribution of such a metric over the several examples of the training dataset. During training, the network may then receive this metric value as an input, to assist in training the network to link that inputted metric value to the physical aspects of the ground truth oral care mesh which is used in loss calculation. Such a loss calculation may quantify the difference between a prediction and a ground truth example (e.g., between a predicted oral care mesh and a ground truth oral care mesh). By providing the network data describing a metric value, the techniques of this disclosure may, through the course of loss calculation and subsequent backpropagation, train the network to encode a distribution of a given metric. In deployment, one or more oral care parameters (procedure parameters or restoration design parameters) may be defined to specify one or more aspects of an intended oral care mesh, which is to be generated using either or both of the first and/or second modules which has been trained for that purpose. In some implementations, an oral care parameter may be defined which corresponds to an oral care metric, which may be received as input to either or both of a deployed first module and/or a deployed second module, and be taken as an instruction to that module to generate an oral care mesh with the specified customization. This interplay between oral care metrics and oral care parameters may also apply to the training and deployment of other predictive models in oral care as well.

The predictive models of the present disclosure may, in some implementations, produce more accurate results by the incorporation of one or more of the following inputs: archform information V, interproximal reduction (IPR) information U, tooth dimension information P, tooth gap information Q, latent capsule representations of oral care meshes T, latent vector representations of oral care meshes A, procedure parameters K (which may describe a clinician's intended treatment of the patient), doctor preferences L (which may describe the typical procedure parameters chosen by a doctor), flags regarding tooth status M (such as for fixed or pinned teeth), tooth position information N, tooth orientation information O, tooth name/dental notation R, oral care metrics S (comprising at least one of oral care metrics and restoration design metrics).

Some implementations of the autoencoder-based mesh cleanup techniques described herein may be trained to remove (or modify) generic triangle mesh defects, such as: degenerate triangle with zero surface area; redundant triangle that covers the same surface area as another triangle; non-manifold edge with more than two adjacent triangles, also referred to as a “fin”; non-manifold vertex with more than one adjacent sequence of connected triangles (triangle fans); intersecting triangles (where two triangles penetrate each other); spikes-sharp features composed of multiple triangles, often conical, caused by one or more vertices being displaced from the actual surface; folds (sharp features composed of multiple triangles, often Z-shaped with a small undercut area, caused by one or more vertices being displaced from the actual surface); islands/small components, which represent disconnected objects in a scan which should only contain a single object (e.g., typically the smaller objects are deleted); small holes in the mesh surface, either from the original scan or from deletions due to the previous defects (e.g., the hole may be removed by filling the hold, for example by adding one or more mesh elements); rough boundary-a smooth boundary is desirable for extending the gingiva surface, creating a model base.

Some implementations of the autoencoder-based mesh cleanup techniques described herein may be trained to remove (or modify) aspects of meshes which are unwanted under certain circumstances and/or domain-specific defects, such as: extraneous material (portions of the intraoral scan outside the anatomical area of interest, e.g., non-tooth surfaces that are not within some distance of tooth surfaces, or scan artifacts that do not represent actual anatomy); divots-concave depressions in surfaces (e.g., which may be scan artifacts, which should be fixed, or anatomical features, which are generally left intact); undercuts (sides of a tooth of lower radius than the crown, such that physical impressions or aligners may become difficult to remove or emplace). Undercuts may be a natural feature or due to damage such as an abfraction. Other features that may be subject to the cleanup operations of this disclosure include abfractions (erosion of a tooth near the gumline, causing or exacerbating an undercut); appliances-orthodontic hardware such as attachments, brackets, wires, buttons, lingual bars, Carriere appliances, or the like, which may be present in intraoral scans. Digital removal and replacement with synthetic tooth/gingiva surfaces may be, in some circumstances, be required before any subsequent appliance creation steps may proceed.

Systems of this disclosure may, in some instances, be deployed at a clinical context (such as a dental or orthodontic office) for use by clinicians (e.g., doctors, dentists, orthodontists, nurses, hygienists, oral care technicians). Such systems which are deployed at a clinical context may enable clinicians to process oral care data (such as dental scans) in the clinic environment, or in some instances, in a “chairside” context (where the patient is present in the clinical environment). A non-limiting list of examples of techniques may include: segmentation, mesh cleanup, coordinate system prediction, CTA trimline generation, restoration design generation, appliance component generation or placement or assembly, generation of other oral care meshes, the validation of oral care meshes, setups prediction, removal of hardware from tooth meshes, hardware placement on teeth, imputation of missing values, clustering on oral care data, oral care mesh classification, setups comparison, metrics calculation, or metrics visualization. The execution of these techniques may, in some instances, enable patient data to be processed, analyzed and used in appliance creation by the clinician before the patient leaves the clinical environment (which may facilitate treatment planning because feedback may be received from the patient during the treatment planning process).

Systems of this disclosure may automate operations in digital orthodontics (e.g., setups prediction, hardware placement, setups comparison), in digital dentistry (e.g., restoration design generation) or in combinations thereof. Some techniques may apply to either or both of digital orthodontics and digital dentistry. A non-limiting list of examples is as follows: segmentation, mesh cleanup, coordinate system prediction, oral care mesh validation, imputation of oral care parameters, oral care mesh generation or modification (e.g., using autoencoders, transformers, continuous normalizing flows or denoising diffusion models), metrics visualization, appliance component placement or appliance component generation or the like. In some instances, systems of this disclosure may enable a clinician or technician to process oral care data (such as scanned dental arches). In addition to segmentation, mesh cleanup, coordinate system prediction or validation operations, the systems of this disclosure may enable orthodontic treatment planning, which may involve setups prediction as at least one operation. Systems of this disclosure may also enable restoration design generation, where one or more restored tooth designs are generated and processed in the course of creating oral care appliances. Systems of this disclosure may enable either or both of orthodontic or dental treatment planning, or may enable automation steps in the generation of either or both of orthodontic or dental appliances. Some appliances may enable both of dental and orthodontic treatment, while other appliances may enable one or the other.

Aspects of the present disclosure can provide a technical solution to the technical problem of labeling, using one or more encoder-decoder structures, one or more mesh elements of a 3D representation of the patient's dentition (e.g., for use in the segmentation or cleanup of the 3D representation, or for anomaly detection). That is, by practicing techniques disclosed herein computing systems specifically adapted to perform mesh element labelling for anomaly detection on 3D representations of the patient's dentition are improved. Furthermore, techniques for filling-in holes or missing mesh elements of a 3D representation of the patient's dentition are improved. For example, aspects of the present disclosure improve the performance of a computing system having a 3D representation of the patient's dentition by reducing the consumption of computing resources. In particular, aspects of the present disclosure reduce computing resource consumption by decimating 3D representations of the patient's dentition (e.g., reducing the counts of mesh elements used to describe aspects of the patient's dentition) so that computing resources are not unnecessarily wasted by processing excess quantities of mesh elements. Additionally, decimating the meshes does not reduce the overall predictive accuracy of the computing system (and indeed may actually improve predictions because the input provided to the ML model after decimation is a more accurate (or better) representation of the patient's dentition). For example, noise or other artifacts which are unimportant (and which may reduce the accuracy of the predictive models) are removed. That is, aspects of the present disclosure provide for more efficient allocation of computing resources and in a way that improves the accuracy of the underlying system.

Furthermore, aspects of the present disclosure may need to be executed in a time-constrained manner, such as when an oral care appliance must be generated for a patient immediately after intraoral scanning (e.g., while the patient waits in the clinician's office). As such, aspects of the present disclosure are necessarily rooted in the underlying computer technologies of mesh element labelling by encoder-decoder structures (e.g., variational autoencoders or masked autoencoders) and the filling-in of missing portions of patient dentition (e.g., comprising hundreds of thousands of mesh elements), and cannot be performed by a human, even with the aid of pen and paper. For instance, implementations of the present disclosure must be capable of: 1) storing thousands or millions of mesh elements of the patient's dentition in a manner that can be processed by a computer processor; 2) performing calculation on thousands or millions of mesh elements, e.g., to quantify aspects of the shape and or/structure of an individual tooth in the 3D representation of the patient's dentition; 3) encoding the patient's dentition into latent form; 4) reconstructing the latent form into one or more 3D representations; and 5) filling-in missing portions of the patient's dentition (e.g., involving the generation of hundreds or thousands of mesh elements); or 6) performing anomaly detection in 3D representations of the patient's dentition, and do so during the course of a short office visit.

This disclosure pertains to digital oral care, which encompasses the fields of digital dentistry and digital orthodontics. This disclosure generally describes methods of processing three-dimensional (3D) representations of oral care data. It should be understood, without loss of generality, that there are various types of 3D representations. One type of 3D representation is a 3D geometry. A 3D representation may include, be, or be part of one or more of a 3D polygon mesh, a 3D point cloud (e.g., such as derived from a 3D mesh), a 3D voxelized representation (e.g., a collection of voxels—for sparse processing), or 3D representations which are described by mathematical equations. Although the term “mesh” is used frequently throughout this disclosure, the term should be understood, in some implementations, to be interchangeable with other types of 3D representations. A 3D representation may describe elements of the 3D geometry and/or 3D structure of an object.

Dental arches S1, S2, S3 and S4 all contain the exact same tooth meshes, but those tooth meshes are transformed differently, according to the following description. A first arch S1 includes a set of tooth meshes arranged (e.g., using transforms) in their positions in the mouth, where the teeth are in the mal positions and orientations. A second arch S2 includes the same set of tooth meshes from S1 arranged (e.g., using transforms) in their positions in the mouth, where the teeth are in the ground truth setup positions and orientations. A third arch S3 includes the same meshes as S1 and S2, which are arranged (e.g., using transforms) in their positions in the mouth, where the teeth are in the predicted final setup poses (e.g., as predicted by one or more of the techniques of this disclosure). S4 is a counterpart to S3, where the teeth are in the poses corresponding to one of the several intermediate stages of orthodontic treatment with clear tray aligners.

It should be understood, without the loss of generality, that the techniques of this disclosure which apply to final setups are also applicable to intermediate staging in orthodontic treatment, particularly geometric deep learning (GDL) Setups, reinforcement learning (RL) Setups, variational autoencoder (VAE) Setups, Capsule Setups, multilayer perceptron (MLP) Setups, Diffusion Setups, pose transfer (PT) Setups, Similarity Setups, force directed graphs (FDG) Setups, Transformer Setups, Setups Comparison, or Setups Classification. The Metrics Visualization aspects of this disclosure may also be configured to visualize data from both final setups and intermediate stages. MLP Setups, VAE Setups and Capsule Setups each fall within the scope of Autoencoder Setups. Some implementations of MLP Setups may fall within the Scope of Transformer Setups. Representation Setups refers to any of MLP Setups, VAE Setups, Capsule Setups and any other setups prediction machine learning model which uses an autoencoder to create the representation for at least one tooth.

Each of the setups prediction techniques of this disclosure is applicable to the fabrication of clear tray aligners and/or indirect bonding trays. The setups predictions techniques may also be applicable to other products that involve final teeth poses, also. A pose may comprise a position (or location) and a rotation (or orientation).

A 3D mesh is a data structure which may describe the geometry or shape of an object related to oral care, including but not limited to a tooth, a hardware element, or a patient's gum tissue. A 3D mesh may include one or more mesh elements such as one or more of vertices, edges, faces and combinations thereof. In some implementations, mesh element may include voxels, such as in the context of sparse mesh processing operations. Various spatial and structural features may be computed for these mesh elements and be provided to the predictive models of this disclosure, with the predictive models of this disclosure providing the technical advantage of improving data precision in the form of the models of this disclosure outputting more accurate predictions.

A patient's dentition may include one or more 3D representations of the patient's teeth (e.g., and/or associated transforms), gums and/or other oral anatomy. An orthodontic metric (OM) may, in some implementations, quantify the relative positions and/or orientations of at least one 3D representation of a tooth relative to at least one other 3D representation of a tooth. A restoration design metric (RDM) may, in some implementations, quantify at least one aspect of the structure and/or shape of a 3D representation of a tooth. An orthodontic landmark (OL) may, in some implementations, locate one or more points or other structural regions of interest on a 3D representation of a tooth. An OL may, in some implementations, be used in the generation of an orthodontic or dental appliance, such as a clear tray aligner or a dental restoration appliance. A mesh element may, in some implementations, comprise at least one constituent element of a 3D representation of oral care data. For example, in the case of a tooth that is represented by a 3D mesh, mesh elements may include at least: vertices, edges, faces and voxels. A mesh element feature may, in some implementations, quantify some aspect of a 3D representation in proximity to or in relation with one or more mesh elements, as described elsewhere in this disclosure. Orthodontic procedure parameters (OPP) may, in some implementations, specify at least one value which defines at least one aspect of planned orthodontic treatment for the patient (e.g., specifying desired target attributes of a final setup in final setups prediction). Orthodontic Doctor preferences (ODP) may, in some implementations, specify at least one typical value for an OPP, which may, in some instances, be derived from past cases which have been treated by one or more oral care practitioners. Restoration Design Parameters (RDP) may, in some implementations, specify at least one value which defines at least one aspect of planned dental restoration treatment for the patient (e.g., specifying desired target attributes of a tooth which is to undergo treatment with a dental restoration appliance). Doctor Restoration Design Preferences (DRDP) may, in some implementations, specify at least one typical value for an RDP, which may, in some instances, be derived from past cases which have been treated by one or more oral care practitioners. 3D oral care representations may include, but are not limited to: 1) a set of mesh element labels which may be applied to the 3D mesh elements of teeth/gums/hardware/appliance meshes (or point clouds) in the course of mesh segmentation or mesh cleanup; 2) 3D representation(s) for one or more teeth/gums/hardware/appliances for which shapes have been modified (e.g., trimmed, distorted, or filled-in) in the course of mesh segmentation or mesh cleanup; 3) one or more coordinate systems (e.g., describing one, two, three or more coordinate axes) for a single tooth or a group of teeth (such as a full arch—as with the LDE coordinate system); 4) 3D representation(s) for one or more teeth for which shapes have been modified or otherwise made suitable for use in dental restoration; 5) 3D representation(s) for one or more dental restoration appliance components; 6) one or more transforms to be applied to one or more of: dental restoration appliance library component placement relative to one or more teeth, a tooth to be placed for an orthodontic setup (either final setup or intermediate stage), a hardware element to be placed relative to one or more teeth or the like; 7) an orthodontic setup; 8) a 3D representation of a hardware element (such as facial bracket, lingual bracket, orthodontic attachment, button, hook, bite ramp, etc.) to be placed relative to one or more teeth, etc.; 8) a 3D representation of a bonding pad for a hardware element (which may be generated for a specific tooth by outlining a perimeter on the tooth, specifying a thickness to form a shell, and then subtracting-out the tooth via a Boolean operation); 9) 3D representation of a clear tray aligner (CTA); 10) the location or shape of a CTA trimline (e.g., described as either a mesh or polyline); 11) archform that describes the contours or layout of an arch of teeth (e.g., described as a 3D polyline or as a 3D mesh or surface), which may follow the incisal edges one or more teeth, which may follow the facial surfaces of one or more teeth, which may in some implementations correspond to the maloccluded arch and in other implementations correspond to the final setup arch (the effects of malocclusion on the shape of the archform may be diminished by smoothing or averaging of the shape of the archform), which may be described by one or more control points and/or a spline; 12) 3D representation of a fixture models (e.g., depictions of teeth and gums for use in thermoforming clear tray aligners, or depictions of teeth/gums/hardware for use in thermoforming indirect bonding trays); 13) one or more latent space vectors (or latent capsules) produced by the 3D encoder stage of a 3D autoencoder which has been trained on the reconstruction of oral care meshes (e.g., a variational autoencoder which has been trained for tooth reconstruction); 14) one or more oral care metrics values (e.g., such as orthodontic metrics or restoration design generation metrics) for one or more teeth; 15) one or more landmarks (e.g., 3D points) which describe the shapes and/or geometrical attributes of one or more teeth, other dentition structures or hardware structures (e.g., to be used in orthodontic setups creation or restoration appliance component generation or placement); 16) 3D representation created by scanning (e.g., optically scanning, CT scanning or MRI scanning) a 3D printed part corresponding to one or more teeth/gums/hardware/appliances (e.g., a scanned fixture model); 17) 3D printed aligners (including optionally local thickness, reinforcing rib geometry, flap positioning, or the like) 18) 3D representation of the patient's dentition that was captured chairside by a clinician or medical practitioner (e.g., in a context where the 3D representation is validated chairside, before the patient leaves the clinic, so that errors can be detected and re-scans performed as necessary); 19) dental restoration tooth design (e.g., for veneers, crowns, bridges or dental restoration appliances); 20) 3D representations of one or more teeth for use in digital oral care treatment; 21) other 3D printed parts pertaining to oral care procedures or other fields; 22) IPR cut surfaces; 23) one or more orthodontic setups transforms associated with one or more IPR cut surfaces; 24) a (digital) pontic tooth design which may fill at least a portion of the space between teeth to allow room in an orthodontic setup for an erupting tooth to later emerge from the gums; or 25) a component of a fixture model (e.g., comprising fixture model components such as interproximal webbing, block-out, bite locks, bite ramps, interproximal reinforcement, gingival ridges, torque points, power ridges, pontic tooth or dimples, among others).

Techniques of this disclosure may require a training dataset of hundreds or thousands of cohort patient cases, to ensure that the neural network is able to encode the distribution of patient cases which are likely to be encountered in clinical treatment. A cohort patient case may include a set of tooth crown meshes, a set of tooth root meshes, or a data file containing attributes of the case (e.g., a JSON file). A typical example of a cohort patient case may contain up to 32 crown meshes (e.g., which may each contain tens of thousands of vertices or tens of thousands of faces), up to 32 root meshes (e.g., which may each contain tens of thousands of vertices or tens of thousands of faces), multiple gingiva mesh (e.g., which may each contain tens of thousands of vertices or tens of thousands of faces) or one or more JSON files which may each contain tens of thousands of values (e.g., objects, arrays, strings, real values, Boolean values or Null values).

The techniques of this disclosure may be advantageously combined. For example, the Setups Comparison tool may be used to compare the output of the GDL Setups model against ground truth data, compare the output of the RL Setups model against ground truth data, compare the output of the VAE Setups model against ground truth data and compare the output of the MLP Setups model against ground truth data. With each of these setups prediction models compared against ground truth data, it may be possible to determine which model gives the best performance on a certain dataset or within a given problem domain. Furthermore, the Metrics Visualization tool can enable a global view of the final setups and intermediate stages produced by one or more of the setups prediction models, with the advantage of enabling the selection of the best setups prediction model. The Metrics Visualization tool, furthermore, enables the computation of metrics which have a global scope over a set of intermediate stages. These global metrics may, in some implementations, be consumed as inputs to the neural networks for predicting setups (e.g., GDL Setups, RL Setups, VAE Setups, Capsule Setups, MLP Setups, Diffusion Setups, PT Setups, Similarity Setups, among others). The global metrics may also be provided to FDG Setups. The local metrics from this disclosure (i.e., a local metric is a metric which may be computed for one stage or setup of treatment, rather than over several stages or setups) may, in some implementations, be consumed by the neural networks herein for predicting setups, with the advantage of improving predictive results. The metrics described in this disclosure may, in some implementations, be visualized using the Metric Visualization tool.

The VAE and MAE models for mesh element labelling and mesh in-filling can be advantageously combined with the setups prediction neural networks, for the purpose of mesh cleanup ahead of or during the prediction process. In some implementations, the VAE for mesh element labelling may be used to flag mesh elements for further processing, such as metrics calculation, removal or modification. In some instances, such flagged mesh elements may be provided as inputs to a setups prediction neural network, to inform that neural network about important mesh features, attributes or geometries, with the advantage of improving the performance of the resulting setups prediction model. In some implementations, mesh in-filling may cause the geometry of a tooth to become more nearly complete, enabling the better functioning of a setups prediction model (i.e., improved correctness of prediction on account of better-formed geometry). In some instances, a neural network to classify a setup (i.e., the Setups Classifier) may aid in the functioning of a setups prediction neural network, because the setups classifier tells that setups prediction neural network when the predicted setup is acceptable for use and can be provided to a method for aligner tray generation. A Setups Classifier (e.g., GDL Setups, RL Setups, VAE Setups, Capsule Setups, MLP Setups, Diffusion Setups, PT Setups, Similarity Setups and FDG Setups, among others) may aid in the generation of final setups and also in the generation of intermediate stages. Furthermore, a Setups Classifier neural network may be combined with the Metrics Visualization tool. In other implementations, a Setups Classification neural network may be combined with the Setups Comparison tool (e.g., the Setup Comparison tool may output an indication of how a setup produced in part by the Setups Classifier compares to a setup produced by another setups prediction method). In some implementations, the VAE for mesh element labelling may identify one or more mesh elements for use in a metrics calculation. The resulting metrics outputs may be visualized by the Metrics Visualization tool.

In some examples, the Setups Classifier neural network may aid in the setups prediction technique described in U.S. Patent Application No. US20210259808A1 (which is incorporated herein by reference in its entirety) or the setups prediction technique described in PCT Application with Publication No. WO2021245480A1 (which is incorporated herein by reference in its entirety) or in PCT Application No. PCT/IB2022/057373 (which is incorporated herein by reference in its entirety). The Setups Classifier would help one or more of those techniques to know when the predicted final setup is most nearly correct. In some instances, the Setups Classifier neural network may output an indication of how far away from final setup a given setup is (i.e., a progress indicator).

In some implementations, the latent space embedding vector(s) from the reconstruction VAE can be concatenated with the inputs to the setups prediction neural network described in WO2021245480A1. The latent space vectors can also be incorporated as inputs to the other setups prediction models: GDL Setups, RL Setups, VAE Setups, Capsule Setups, MLP Setups and Diffusion Setups, among others. The advantage is to impart the reconstruction characteristics (e.g., latent vector dimensions of a tooth mesh) to that neural network, hence improving the generated setups prediction.

In some examples, the various setups prediction neural networks of this disclosure may work together to produce the setups required for orthodontic treatment. For example, the GDL Setups model may produce a final setup, and the RL Setups model may use that final setup as input to produce a series of intermediate stages setups. Alternatively, the VAE Setups model (or the MLP Setups model) may create a final setup which may be used by an RL Setups model to produce a series of intermediate stages setups. In some implementations, a setup prediction may be produced by one setups prediction neural network, and then taken as input to another setups prediction neural network for further improvements and adjustments to be made. In some implementations, such improvements may be performed in iterative fashion.

In some implementations, a setups validation model, such as the model disclosed in US Provisional Application No. U.S. 63/366,495, may be involved in this iterative setups prediction loop. First a setup may be generated (e.g., using a model trained for setups prediction, such as GDL Setups, RL Setups, VAE Setups, Capsule Setups, MLP Setups, Diffusion Setups, PT Setups, Similarity Setups and FDG Setups, among others), then the setup undergoes validation. If the setup passes validation, the setup may be outputted for use. If the setup fails validation, the setup may be sent back to one or more of the setups prediction models for corrections, improvements and/or adjustments. In some instances, the setups validation model may output an indication of what is wrong with the setup, enabling the setups generation model to make an improved version upon the next iteration. The process iterates until done.

Generally speaking, in some implementations, two or more of the following techniques of the present disclosure may be combined in the course of orthodontic and/or dental treatment: GDL Setups, Setups Classification, Reinforcement Learning (RL) Setups, Setups Comparison, Autoencoder Setups (VAE Setups or Capsule Setups), VAE Mesh Element Labeling, Masked Autoencoder (MAE) Mesh In-filling, Multi-Layer Perceptron (MLP) Setups, Metrics Visualization, Imputation of Missing Oral Care Parameters Values, Tooth Classification Using Latent Vector, FDG Setups, Pose Transfer Setups, Restoration Design Metrics Calculation, Neural Network Techniques for Dental Restoration and Orthodontics (e.g., 3D Oral Care Representation Generation or Modification Using Transformers), Landmark-based (LB) Setups, Diffusion Setups, Imputation of Tooth Movement Procedures, Capsule Autoencoder Segmentation, Diffusion Segmentation, Similarity Setups, Validation of Oral Care Representations (e.g., using autoencoders), Coordinate System Prediction and Restoration Design Generation, or 3D Oral Care Representation Generation or Modification Using Denoising Diffusion Models.

In some instances, tooth shape-based inputs may be provided to a neural network for setups predictions. In other instances, non-shape-based inputs can be used, such as a tooth name or designation, as it pertains to dental notation. In some implementations, a vector R of flags may be provided to the neural network, where a ‘1’ value indicates that the tooth is present and a ‘0’ value indicates that the tooth is absent from the patient case (though other values are possible). The vector R may comprise a 1-hot vector, where each element in the vector corresponds to a tooth type, name or designation. Identifying information about a tooth (e.g., the tooth's name) can be provided to the predictive neural networks of this disclosure, with the advantage of enabling the neural network to become trained to handle different teeth in tooth-specific ways. For example, the setups prediction model may learn to make setups transformations predictions for a specific tooth designation (e.g., upper right central incisor, or lower left cuspid, etc.). In the case of the mesh cleanup autoencoders (either for labelling mesh element or for in-filling missing mesh data), the autoencoder may be trained to provide specialized treatment to a tooth according to that tooth's designation, in this manner. In the case of a setups classification neural network, a listing of tooth name(s) present in the patient's arch may better enable the neural network to output an accurate determination of setup classification, because tooth designation is a valuable input to training such a neural network. Tooth designation/name may be defined, for example, according to the Universal Numbering System, Palmer System, or the FDI World Dental Federation notation (ISO 3950).

In one example, where all except the (up to four) wisdom teeth are present in the case, a vector R may be defined as an optional input to the setups prediction neural networks of this disclosure, where there is a 0 in the vector element corresponding to each of the wisdom teeth, and a 1 in the elements corresponding to the following teeth: UR7, UR6, UR5, UR4, UR3, UR2, UR1, UL1, UL2, UL3, UL4, UL5, UL6, UL7, LL7, LL6, LL5, LL4, LL3, LL2, LL1, LR1, LR2, LR3, LR4, LR5, LR6, LR7

In some instances, the position of the tooth tip may be provided to a neural network for setups predictions. In other instances, one or more vectors S of the orthodontic metrics described elsewhere in this disclosure may be provided to a neural network for setups predictions. The advantage is an improved capacity for the network to become trained to understand the state of a maloccluded setup and therefore be able to predict a more accurate final setup or intermediate stage.

In some implementations, the neural networks may take as input one or more indications of interproximal reduction (IPR) U, which may indicate the amount of enamel that is to be removed from a tooth during the course orthodontic treatment (either mesially or distally). In some implementations, IPR information (e.g., quantity of IPR that is to be performed on one or more teeth, as measured in millimeters, or one or more binary flags to indicate whether or not IPR is to be performed on each tooth identified by flagging) may be concatenated with a latent vector A which is produced by a VAE or a latent capsule T autoencoder. The vector(s) and/or capsule(s) resulting from such a concatenation may be provided to one or more of the neural networks of the present disclosure, with the technical improvement or added advantage of enabling that predictive neural network to account for IPR. IPR is especially relevant to setups prediction methods, which may determine the positions and poses of teeth at the end of treatment or during one or more stages during treatment. It is important to account for the amount of enamel that is to be removed ahead of predicted tooth movements.

In some implementations, one or more procedure parameters K and/or doctor preferences vectors L may be introduced to a setups prediction model. In some implementations, one or more optional vectors or values of tooth position N (e.g., XYZ coordinates, in either tooth local or global coordinates), tooth orientation O (e.g., pose, such as in transformation matrices or quaternions, Euler angles or other forms described herein), dimensions of teeth P (e.g., length, width, height, circumference, diameter, diagonal measure, volume-any of which dimensions may be normalized in comparison to another tooth or teeth), distance between adjacent teeth Q. These “dimensions of teeth P” may in some instances be used to describe the intended dimensions of a tooth for dental restoration design generation.

In some implementations, tooth dimensions P (e.g., length, width, height, or circumference) may be measured inside a plane, such as the plane that intersects the centroid of the tooth, or the plane that intersects a center point that is located midway between the centroid and either the incisal-most extent or the gingival-most extent of the tooth. The tooth dimension of height may be measured as the distance from gums to incisal edge. The tooth dimension of width may be measured as the distance from the mesial extent to the distal extent of the tooth. In some implementations, the circularity or roundness of the tooth cross-section may be measured and included in the vector P. Circularity or roundness may be defined as the ratio of the radii of inscribed and circumscribed circles.

The distance Q between adjacent teeth can be implemented in different ways (and computed using different distance definitions, such as Euclidean or geodesic). In some implementations, a distance Q1 may be measured as an averaged distance between the mesh elements of two adjacent teeth. In some implementations, a distance Q2 may be measured as the distance between the centers or centroids of two adjacent teeth. In some implementations, a distance Q3 may be measured between the mesh elements of closest approach between two adjacent teeth. In some implementations, a distance Q4 may be measured between the cusp tips of two adjacent teeth. Teeth may, in some implementations, be considered adjacent within an arch. Teeth may, in some implementations, also be considered adjacent between opposing arches. In some implementations, any of Q1, Q2, Q3 and Q4 may be divided by a term for the purpose of normalizing the resulting value of Q. In some implementations, the normalizing term may involve one or more of: the volume of a tooth, the count of mesh elements in a tooth, the surface area of a tooth, the cross-sectional area of a tooth (e.g., as projected into the XY plane), or some other term related to tooth size.

Other information about the patient's dentition or treatment needs (or related parameters) may be concatenated with the other input vectors to one or more of MLP, GAN, generator, encoder structure, decoder structure, transformer, VAE, conditional VAE, regularized VAE, 3D U-Net, capsule autoencoder, diffusion model, and/or any of the neural networks models listed elsewhere in this disclosure.

The vector M may contain flags which apply to one or more teeth. In some implementations, M contains at least one flag for each tooth to indicate whether the tooth is pinned. In some implementations, M contains at least one flag for each tooth to indicate whether the tooth is fixed. In some implementations, M contains at least one flag for each tooth to indicate whether the tooth is pontic. Other and additional flags are possible for teeth, as are combinations of fixed, pinned and pontic flags. A flag that is set to a value that indicates that a tooth should be fixed is a signal to the network that the tooth should not move over the course of treatment. In some implementations, the neural network loss function may be designed to be penalized for any movement in the indicated teeth (and in some particular cases, may be heavily penalized). A flag to indicate that a tooth is pontic informs the network that the tooth gap is to be maintained, although that gap is allowed to move. In some cases, M may contain a flag indicating that a tooth is missing. In some implementations, the presence of one or more fixed teeth in an arch may aid in setups prediction, because the one or more fixed teeth may provide an anchor for the poses of the other teeth in the arch (i.e., may provide a fixed reference for the pose transformations of one or more of the other teeth in the arch). In some implementations, one or more teeth may be intentionally fixed, so as to provide an anchor against which the other teeth may be positioned. In some implementations, a 3D representation (such as a mesh) which corresponds to the gums may be introduced, to provide a reference point against which teeth can be moved.

Without the loss of generality, one or more of the optional input vectors K, L, M, N, O, P, Q, R, S, U and V described elsewhere in this disclosure may also be provided to the input or into an intermediate layer of one or more of the predictive models of this disclosure. In particular, these optional vectors may be provided to the MLP Setups, GDL Setups, RL Setups, VAE Setups, Capsule Setups and/or Diffusion Setups, with the advantage of enabling the respective model to output setups which better meet the orthodontic treatment needs of the patient. In some implementations, such inputs may be provided, for example, by being concatenated with one or more latent vectors A which are also provided to one or more of the predictive models of this disclosure. In some implementations, such inputs may be provided, for example, by being concatenated with one or more latent capsules T which are also provided to one or more of the predictive models of this disclosure.

In some implementations, one or more of K, L, M, N, O, P, Q, R, S, U and V may be introduced to the neural network (e.g., MLP or Transformer) directly in a hidden layer of the network. In some instances, one or more of K, L, M, N, O, P, Q, R, S, U and V may be introduced directly into the internal processing of an encoder structure.

In some implementations, a setups prediction model (such as GDL Setups, RL Setups, VAE Setups, Capsule Setups, MLP Setups, PT Setups, Similarity Setups and Diffusion Setups) may take as input one or more latent vectors A which correspond to one or more input oral care meshes (e.g., such as tooth meshes). In some implementations, a setups prediction model (such as GDL Setups, RL Setups, VAE Setups, Capsule Setups, MLP Setups and Diffusion Setups) may take as input one or more latent capsules T which correspond to one or more input oral care meshes (e.g., such as tooth meshes). In some implementations, a setups prediction method may take as input both of A and T.

Various loss calculation techniques are generally applicable to the techniques of this disclosure (e.g., GDL Setups, RL Setups, VAE Setups, Capsule Setups, MLP Setups, Diffusion Setups, PT Setups, Similarity Setups, Setups Classification, Tooth Classification, VAE Mesh Element Labelling, MAE Mesh In-Filling and the imputation of procedure parameters).

These losses include L1 loss, L2 loss, mean squared error (MSE) loss, cross entropy loss, among others. Losses may be computed and used in the training of neural networks, such as multi-layer perceptron's (MLP), U-Net structures, generators and discriminators (e.g., for GANs), autoencoders, variational autoencoders, regularized autoencoders, masked autoencoders, transformer structures, or the like. Some implementations may use either triplet loss or contrastive loss, for example, in the learning of sequences.

Losses may also be used to train encoder structures and decoder structures. A KL-Divergence loss may be used, at least in part, to train one or more of the neural networks of the present disclosure, such as a mesh reconstruction autoencoder or the generator of GDL Setups, which the advantage of imparting Gaussian behavior to the optimization space. This Gaussian behavior may enable a reconstruction autoencoder to produce a better reconstruction (e.g., when a latent vector representation is modified and that modified latent vector is reconstructed using a decoder, the resulting reconstruction is more likely to be a valid instance of the inputted representation). There are other techniques for computing losses which may be described elsewhere in this disclosure. Such losses may be based on quantifying the difference between two or more 3D representations.

MSE loss calculation may involve the calculation of an average squared distance between two sets, vectors or datasets. MSE may be generally minimized. MSE may be applicable to a regression problem, where the prediction generated by the neural network or other machine learning model may be a real number. In some implementations, a neural network may be equipped with one or more linear activation units on the output to generate an MSE prediction. Mean absolute error (MAE) loss and mean absolute percentage error (MAPE) loss can also be used in accordance with the techniques of this disclosure.

Cross entropy may, in some implementations, be used to quantify the difference between two or more distributions. Cross entropy loss may, in some implementations, be used to train the neural networks of the present disclosure. Cross entropy loss may, in some implementations, involve comparing a predicted probability to a ground truth probability. Other names of cross entropy loss include “logarithmic loss,” “logistic loss,” and “log loss”. A small cross entropy loss may indicate a better (e.g., more accurate) model. Cross entropy loss may be logarithmic. Cross entropy loss may, in some implementations, be applied to binary classification problems. In some implementations, a neural network may be equipped with a sigmoid activation unit at the output to generate a probability prediction. In the case of multi-class classifications, cross entropy may also be used. In such a case, a neural network trained to make multi-class predictions may, in some implementations, be equipped with one or more softmax activation functions at the output (e.g., where there is one output node for class that is to be predicted). Other loss calculation techniques which may be applied in the training of the neural networks of this disclosure include one or more of: Huber loss, Hinge loss, Categorical hinge loss, cosine similarity, Poisson loss, Logcosh loss, or mean squared logarithmic error loss (MSLE). Other loss calculation methods are described herein and may be applied to the training of any of the neural networks described in the present disclosure.

One or more of the neural networks of the present disclosure may, in some implementations, be trained, at least in part by a loss which is based on at least one of: a Point-wise Mesh Euclidean Distance (PMD) and an Earth Mover's Distance (EMD). Some implementations may incorporate a Hausdorff Distance (HD) calculation into the loss calculation. Computing the Hausdorff distance between two or more 3D representations (such as 3D meshes) may provide one or more technical improvements, in that the HD not only accounts for the distances between two meshes, but also accounts for the way that those meshes are oriented, and the relationship between the mesh shapes in those orientations (or positions or poses). Hausdorff distance may improve the comparison of two or more tooth meshes, such as two or more instances of a tooth mesh which are in different poses (e.g., such as the comparison of predicted setup to ground truth setup which may be performed in the course of computing a loss value for training a setups prediction neural network).

Reconstruction loss may compare a predicted output to a ground truth (or reference) output. Systems of this disclosure may compute reconstruction loss as a combination of L1 loss and MSE loss, as shown in the following line of pseudocode: reconstruction loss=0.5*L1 (all_points_target,all_points_predicted)+0.5*MSE (all_points_target,all_points_predicted). In the above example, all_points_target is a 3D representation (e.g., a 3D mesh or point cloud) corresponding to ground truth data (e.g., a ground truth tooth restoration design, or a ground truth example of some other 3D oral care representation). In the above example, all_points_predicted is a 3D representation (e.g., a 3D mesh or point cloud) corresponding to generated or predicted data (e.g., a generated tooth restoration design, or a generated example of some other kind of 3D oral care representation). Other implementations of reconstruction loss may additionally (or alternatively) involve L2 loss, mean absolute error (MAE) loss or Huber loss terms.

The entirety of the following paper is incorporated herein by reference in its entirety: “Attention Is All You Need”; Ashish Vaswani, Noam Shazeer, Niki Parmar, Niki Parmar, Llion Jones, Aidan N. Gomez, Łukasz Kaiser, Illia Polosukhin; NIPS 2017. The neural network-based models of this disclosure may provide additional advantages in implementations in which they are integrated with a neural network structure referred to as a “transformer.”

Before recently developed models such as the transformer model, RNN-type models represented the state of the art for natural language processing (NLP). One example application of NLP is the generation of new text based upon prior words or text. Transformers have in turn provided significant improvements over GRU, LSTM and other such RNN-based NLP techniques due to an important attribute of the transformer model, which has the property of multi-headed attention. In some implementations, the NLP concept of multi-headed attention may describe the relationship between each word in a sentence (or paragraph or document or corpus of documents) and each other word in that sentence (or paragraph or document or corpus of documents). These relationships may be generated by a multiheaded attention module, and may be encoded in vector form. This vector may describe how each word in a sentence (or paragraph or document or corpus of documents) should attend to each other word in that sentence (or paragraph or document or corpus of documents). RNN, LSTM and GRU models process a sequence, such a sentence, one word at a time from the start to the end of the sequence. Furthermore, the model may only account for a given subset (called a window) of the sentence when making a prediction. However, transformer-based models may, in some instances, account for the entirety of the preceding text by processing the sequence in its entirety in a single step. Transformer, RNN, LSTM, and GRU models can all be adapted for use in predictive models in digital dentistry and digital orthodontics, particularly for the setup prediction task. In some implementations, an exemplary transformer model for use with 3D meshes and 3D transforms in setups prediction (or other oral care techniques) may be adapted from the Bidirectional Encoder Representation from Transformers (BERT) and/or Generative Pre-Training (GPT) models. For example, a GPT (or BERT) model may first be trained on other data, such as text or documents data, and then be used in transfer learning. Such a transfer learning process may receive a previously trained GPT or BERT model, and then do further training using data comprising 3D oral care representations. Such transfer learning may be performed to train oral care models such as: segmentation, mesh cleanup, coordinate system prediction, setups prediction, validation of 3D oral care representations, transform prediction for placement of oral care meshes (e.g., teeth, hardware, appliance components, fixture model components), tooth restoration design generation (or generation of other 3D oral care representations—such as appliance components, fixture models or archforms), classification of 3D oral care representations, imputation of missing oral care parameters, clustering of clinicians or clustering of clinician preferences, or the like.

Oral care data may comprise one or more of (or combinations of): 3D representations of tooth (e.g., meshes, point clouds or voxels), sections of tooth meshes (such as subsets of mesh elements), tooth transforms (such as in matrix, vector and/or quaternion form, or combinations thereof), transforms for appliance components, transforms for fixture model components, and mesh coordinate system definitions (such as represented by transforms, for example, transformation matrices) and/or other 3D oral care representations described herein.

Transformers may be trained for generating transforms to position teeth into setups poses (or to place appliance components for use in appliance generation or to place fixture model components for use in fixture model generation). Some implementations may operate in an offline prediction context, and some implementations operation in an online reinforcement learning (RL) context. In some implementations, a transformer may be initially trained in an offline context and then undergo further fine-tuning training in the online context. In the offline prediction context, the transformer may be trained from a dataset of cohort patient case data. In the online RL context, the transformer may be trained from either a physics model, or a CAD model, for example. The transformer may learn from static data, such as transformations (e.g., trajectory transformer). In some implementations, the transform may provide a mapping from malocclusion to setup (e.g., receiving transformation matrices as input and generating transformation matrices as ouput). Some implementations of transformers may be trained to process 3D representations, such as 3D meshes, 3D point clouds or voxels (e.g., using a decision transformer) takes as input geometry (e.g., mesh, point cloud, voxels etc.), outputs transformations. The decision transformer may be coupled with a representation generation module that encodes representation of the patient's dentition (e.g., teeth), such as a VAE, a U-Net, an encoder, a transformer encoder, a pyramid encoder-decoder or a simple dense or fully connected network, or a combination thereof. In some implementations, the representation generation module (e.g., VAE, the U-Net, the encoder, the pyramid encoder-decoder or the dense network for generating the tooth representation) may be trained to generate the representation on one or more teeth. The representation generation module may be trained on all teeth in both arches, only the teeth within the same arch (either upper or lower), only anterior teeth, only posterior teeth, or some other subset of teeth. In some implementations, such a model may be trained on each individual tooth (e.g., an upper right cuspid), so that the model is trained or otherwise configured to generate highly accurate representations for an individual tooth. In some implementations, an encoder structure may encode such a representation. In some implementations, a decision transformer may learn in an online context, in an offline context or both. An online decision transformer may be trained (e.g., using RL techniques) to output action, state, and/or reward. In some implementations, transformations may be discretized, to allow for piecewise or stepwise actions.

In some implementations, a transformer may be trained to process an embedding of the arch (i.e., to predict transforms for multiple teeth concurrently), to predict a setup. In some implementations, embeddings of individual teeth may be concatenated into a sequence, and then input into the transformer. A VAE may be trained to perform this embedding operation, a U-Net may be trained to perform such an embedding, or a simple dense or fully connected network may be trained, or a combination thereof. In some implementations, the transformer-based techniques of this disclosure may predict an action for an individual tooth, or may predict actions for multiple teeth (e.g., predict transformations for each of multiple teeth).

A 3D mesh transformer may include a transformer encoder structure (which may encode oral care data), and may be followed by a transformer decoder structure. The 3D mesh transformer encoder may encode oral care data into a latent representation, which may be combined with attention information (e.g., to concatenate a vector of attention information to the latent representation). In some implementations, the attention information may help the decoder focus on the relevant oral care data during the decoding process (e.g., to focus on tooth order or mesh element connectivity), so that the transformer decoder can generate a useful output for the 3D mesh transformer (e.g., an output which may be used in the generation of an oral care appliance). Either or both of the transformer encoder or transformer decoder may generate a latent representation. The output of the transformer decoder (or transformer encoder) may be reconstructed using a decoder into, for example, one or more tooth transforms for a setup, one or more mesh element labels for segmentation, coordinate systems transforms for use in coordinate system generation, or one or more points of a point cloud or voxels or other mesh elements for another 3D representation). A transformer may include modules such as one or more of: multi-headed attention modules, feed forward modules, normalization modules, linear modules, and softmax modules, and convolution models for latent vector compression, and/or representation.

The encoder may be stacked one or more times, thereby further encoding the oral care data, and enabling different representations of the oral care data to be learned (e.g., different latent representations). These representations may be embedded with attention information (which may influence the decoder's focus to the relevant portions of the latent representation of the oral care data) and may be provided to the decoder in continuous form (e.g., as a concatenation of latent representations-such as latent vectors). In some implementations, the encoded output of the encoder (e.g., latent representations) may be used by downstream processing steps in the generation of oral care appliances. For example, the generated latent representation may be reconstructed into transforms (e.g., for the placement of teeth in setups, or the placement of appliance components or fixture model components), or may be reconstructed into 3D representations (e.g., 3D point clouds, 3D meshes or others disclosed herein). Stated another way, the latent representation which is generated by the transformer (e.g., containing continuously encoded attention information) may be provided to a decoder which has been configured to reconstruct the latent representation into the specific data structure which is required by a particular domain area. Continuously encoded attention information may include attention information which has undergone processing by multiple multi-headed attention modules within the transformer encoder or transformer decoder, to name one example. Furthermore, a loss may be computed for a particular domain using data from that domain. The loss calculation may train the transformer decoder to accurately reconstruct the latent representation into the output data structure pertaining to a particular domain.

For example, when the decoder generates a transform for an orthodontic setup, the decoder may be configured with outputs that describe, for example, the 16 real values which comprise a 4×4 transformation matrix (other data structures for describing transforms are possible). Stated a different way, the latent output generated by the transformer encoder (or transformer decoder) may be used to predict setups tooth transforms for one or more teeth, to place those teeth in setup positions (e.g., either final setups or intermediate stages). Such a transformer encoder (or transformer decoder) may be trained, at least in part using a reconstruction loss (or a representation loss, among others described herein) function, which may compare predicted transforms to ground truth (or reference) transforms.

In a further example, when the decoder generates a transform for a tooth coordinate system, the decoder may be configured with outputs that describe, for example, the 16 real values which comprise a 4×4 transformation matrix (other data structures for describing transforms are possible). Stated a different way, the latent output generated by the transformer encoder (or transformer decoder) may be used to predict local coordinate systems for one or more teeth. Such a transformer encoder (or transformer decoder) may be trained, at least in part using a representation loss (or a reconstruction loss, among others described herein) function, which may compare predicted coordinate systems to ground truth (or reference) coordinate systems.

In a further example, when the decoder generates a 3D point cloud (or other 3D representation—such as 3D mesh, voxelized representation, or the like), the decoder may be configured with outputs that describe, for example, one or more 3D points (e.g., comprising XYZ coordinates). Stated a different way, the latent output generated by the transformer encoder (or transformer decoder) may be used to predict mesh elements for a generated (or modified) 3D representation. Such a transformer encoder (or transformer decoder) may be trained, at least in part using a reconstruction loss (or an L1, L2 or MSE loss, among others described herein) function, which may compare predicted 3D representations to ground truth (or reference) 3D representations.

In a further example, when the decoder generates mesh element labels for 3D representation segmentation or 3D representation cleanup, the decoder may be configured with outputs that describe, for example, labels for one or more mesh elements. Stated a different way, the latent output generated by the transformer encoder (or transformer decoder) may be used to predict mesh element labels for mesh segmentation or mesh cleanup. Such a transformer encoder (or transformer decoder) may be trained, at least in part using a cross entropy loss (or others described herein) function, which may compare predicted mesh element labels to ground truth (or reference) mesh element labels.

Multi-headed attention and transformers may be advantageously applied to the setups-generation problem. Multi-headed attention is a module in a 3D transformer encoder network which computes the attention weights for the provided oral care data and produces an output vector with encoded information on how each example of oral care data should attend to each other oral care data in an arch. An attention weight is a quantification of the relationship between pairs of oral care data.

A 3D representation of oral care data (e.g., comprising voxels, a point cloud, or a 3D mesh composed of vertices, faces or edges) may be provided to the transformer. The 3D representation may describe the patient's dentition, a fixture model (or components of a fixture model), an appliance (or components of an appliance), or the like. In some implementations, a transformer decoder (or a transformer encoder) may be equipped with multi-head attention. Multi-headed attention may enable the transformer decoder (or transformer encoder) to attend to different portions of the 3D representation of oral care data. For example, multi-headed attention may enable the transformer to attend to mesh elements within local neighborhoods (or cliques), or to attend to global dependencies between mesh elements (or cliques). For example, multi-headed attention may enable a transformer for setups prediction (e.g., a setups prediction model which is based on a transformer) to generate a transform for a tooth, and to substantially concurrently attend to each of the other teeth in the arch while that transform is generated. Stated another way, the transform for each tooth may be generated in light of the poses of one or more other teeth in the arch, leading to a more accurate transform (e.g., a transform which conforms more closely to the ground truth or reference transform). In the example of 3D representation generation (e.g., the generation of a 3D point cloud), a transformer model may be trained to generate a tooth restoration design. Multi-headed attention may enable the transformer to attend to multiple portions of the tooth (or to the surfaces of the adjacent teeth) while the tooth undergoes the generative process. For example, the transformer for restoration design generation may generate the mesh elements for the incisal edge of an incisor while, at least substantially concurrently, attending to the mesh elements of the mesial, distal, facial or lingual surfaces of the incisor. The result may be the generation of mesh elements to form an incisal edge for the tooth which merges seamlessly with the adjacent surfaces of the tooth. This use of multi-headed attentions results in more accurate modeling of the distribution of the training dataset, over techniques which do not apply multi-headed attention.

In some implementations of the present disclosure, one or more attention vectors may be generated which describe how aspects of the oral care data interacts with other aspects of the oral care data associated with the arch. In some implementations, the one or more attention vectors may be generated to describe how one or more portions of a tooth T1 interact with one or more portions of a tooth T2, a tooth T3, a tooth T4, and so one. A portion of a mesh may be described as a set of mesh elements, as defined herein. In some implementations, the interacting portions of tooth T1 and tooth T2 may be determined, in part, through the calculation of mesh correspondences, as described herein. Any of these models (RNN, GRU, LSTM and Transformer) may be advantageously applied to the task of setups transform prediction, such as in the models described herein. A transformer may be particularly advantageous in that a transformer may enable the transforms for multiple teeth, or even an entire arch to be generated at once, rather than individually, as may be the case with some other models, such as an encoder structure. In other implementations, attention-free transformers may be used to make predictions based on oral care data.

One implementation of the GDL Setups neural network model may include a representation generation module (e.g., containing a U-Net structure, an autoencoder encoder, a transformer encoder, another type of encoder-decoder structure, or an encoder, etc.) which may provide its output to a module which is trained to generate tooth transformers (e.g., a set of fully connected layers with optional skip connections, or an encoder structure) to generate the prediction of a transform for each individual tooth. Skip connections may, in some implementations, connect the outputs of a particular layer in a neural network to the inputs of another later in the neural network (e.g., a layer which is not immediately adjacent to the originating layer). The transform-generation module (e.g., an encoder) may handle the transform prediction one tooth at a time. Other implementations may replace this encoder structure with a transformer (e.g., transformer encoder or transformer decoder), which may handle all the predictions for all teeth substantially concurrently. Stated another way, a transformer may be configured to receive a large number of input values, larger than some other neural network models (e.g., than a typical MLP). This is because an increased number of inputs may be accommodated by the transformer, the predictions corresponding to those inputs may be generated substantially concurrently. The representation generation module (e.g., U-Net structure) may provide its output to the transformer, and the transformer may generate the setups transforms for all of the several teeth at once, with the technical advantage of improved accuracy (because the transforms for each tooth is generated in light of the transform for each of the adjacent or nearby teeth-leading to fewer collisions and better conformance with the goals of treatment). A transformer may be trained to output a transformation, such as a transform encoded by a 4×4 matrix (or some other size), a quaternion, a translation vector, Euler angles or some other form. The transformation may place a tooth into a setups pose, may place a fixture model component into a pose suitable for fixture model generation, or may place an appliance component into a pose suitable for appliance generation (e.g., dental restoration appliance, clear tray aligner, etc.). In some implementations, the transform may define a coordinate system for aspects of the patient's dentition, such as a tooth mesh (e.g., a local coordinate system for a tooth). In some implementations, the inputs to the transformer may first be encoded using a neural network (e.g., a latent representation or embedding may be generated), such as one or more linear layers, and/or one or more convolutional layers. In some implementations, the transformer may first be trained on an offline dataset, and subsequently be trained using a secondary actor-critic network, which may enable online reinforcement learning.

Transformers may, in some implementations, enable large model capacity and/or enable an attention mechanism (e.g., the capability to pay attention and respond to certain inputs). The attention mechanisms (e.g., multi-headed attention) that are found within transformers may enable intra-sequence relationships to be encoded into neural network features. Intra-sequence relationships may be encoded, for example, by associating an order number (e.g., 1, 2, 3, etc.) with each tooth in an arch, or by associating an order number with each mesh element in a 3D representation (e.g., of a tooth). In implementations where latent vectors of teeth are provided to the transformer, intra-sequence relationships may be encoded, for example, by associating an order number (e.g., 1, 2, 3, etc.) with each element in the latent vector.

Transformers may be scaled by increasing the number of attention heads and/or by increasing the number of transformer layers. Stated differently, one or more aspects of a transformer may be independently trained to handle discrete tasks, and later combined to allow the resulting transformer to perform all of the tasks for which the individual components had been trained, without degrading the predictive accuracy of the neural network. Scaling a convolutional network may be more difficult, because the models may be less malleable or may be less interchangeable.

Convolution has an ability to be rotation and translation invariant, which leads to improved generalization, because a convolution model may not need to account for the manner in which the input data in rotated or translated. Transformers have an ability to be permutation invariant, because intra-sequence relationships may be encoded into neural network features.

In some implementations for the generation or modification of 3D oral care representations, transformers may be combined with convolution-based neural networks, such as by vertically stacking convolution layers and attention layers. Stacking transformer blocks with convolutional blocks enables the resulting structure to have the translation invariance of convolution, and also the permutation invariance of a transformer. Such stacking may improve model capacity and/or model generalization. CoAtNet is an example of a network architecture which combines convolutional and attention-based elements and may be applied to the processing of oral care data. In some instances, a network for the modification or generation of 3D oral care representations may be trained, at least in part, from CoAtNet (or another model that combines convolution and self-attention/transformers) using transfer learning.

The techniques of this disclosure may include operations such as 3D convolution, 3D pooling, 3D unconvolution and 3D unpooling. 3D convolution may aid segmentation processing, for example in down sampling a 3D mesh. 3D un-convolution undoes 3D convolution, for example, in a U-Net. 3D pooling may aid the segmentation processing, for example in summarized neural network feature maps. 3D un-pooling undoes 3D pooling, for example in a U-Net. These operations may be implemented by way of one or more layers in the predictive or generative neural networks described herein. These operations may be applied directly on mesh elements, such as mesh edges or mesh faces. These operations provide for technical improvements over other approaches because the operations are invariant to mesh rotation, scale, and translation changes. In general, these operations depend on edge (or face) connectivity, therefore these operations remain invariant to mesh changes in 3D space as long as edge (or face) connectivity is preserved. That is, the operations may be applied to an oral care mesh and produce the same output regardless of the orientation, position or scale of that oral care mesh, which may lead to data precision improvement. MeshCNN is a general-purpose deep neural network library for 3D triangular meshes, which can be used for tasks such as 3D shape classification or mesh element labelling (e.g., for segmentation or mesh cleanup). MeshCNN implements these operations on mesh edges. Other toolkits and implementations may operate on edges or faces.

In some implementations of the techniques of this disclosure, neural networks may be trained to operate on 2D representations (such as images). In some implementations of the techniques of this disclosure, neural networks may be trained to operate on 3D representations (such as meshes or point clouds). An intraoral scanner may capture 2D images of the patient's dentition from various views. An intraoral scanner may also (or alternatively) capture 3D mesh or 3D point cloud data which describes the patient's dentition. According to various techniques, autoencoders (or other neural networks described herein) may be trained to operate on either or both of 2D representations and 3D representations.

A 2D autoencoder (comprising a 2D encoder and a 2D decoder) may be trained on 2D image data to encode an input 2D image into a latent form (such as a latent vector or a latent capsule) using the 2D encoder, and then reconstruct a facsimile of the input 2D image using the 2D decoder. In the case of a handheld mobile app which has been developed for such analysis (e.g., for the analysis of dental anatomy), 2D images may be readily captured using one or more of the onboard cameras. In other examples, 2D images may be captured using an intraoral scanner which is configured for such a function. Among the operations which may be used in the implementation a 2D autoencoder (or other 2D neural network) for 2D image analysis are 2D convolution, 2D pooling and 2D reconstruction error calculation.

### 2D Convolution:

2D image convolution may involve the “sliding” of a kernel across a 2D image and the calculation of elementwise multiplications and the summing of those elementwise multiplications into an output pixel. The output pixel that results from each new position of the kernel is saved into an output 2D feature matrix. In some implementations, neighboring elements (e.g., pixels) may be in well-defined locations (e.g., above, below, left and right) in a rectilinear grid.

### 2D Pooling:

A 2D pooling layer may be used to down sample a feature map and summarize the presence of certain features in that feature map.

### 2D Reconstruction Error:

2D reconstruction error may be computed between the pixels of the input and reconstructed images. The mapping between pixels may be well understood (e.g., the upper pixel [23,134] of the input image is directly compared to pixel [23,134] of the reconstructed image, assuming both images have the same dimensions).

Among the advantages provided by the 2D autoencoder-based techniques of this disclosure is the ease of capturing 2D image data with a handheld device. In some instances, where outside data sources provide the data for analysis, there may be instances where only 2D image data are available. When only 2D image data are available, then analysis using a 2D autoencoder is warranted.

Modern mobile devices (such as commercially available smartphones) may also have the capability of generating 3D data (e.g., using multiple cameras and stereophotogrammetry, or one camera which is moved around the subject to capture multiple images from different views, or both), which in some implementations, may be arranged into 3D representations such as 3D meshes, 3D point clouds and/or 3D voxelized representations. The analysis of a 3D representation of the subject may in some instances provide technical improvements over 2D analysis of the same subject. For example, a 3D representation may describe the geometry and/or structure of the subject with less ambiguity than a 2D representation (which may contain shadows and other artifacts which complicate the depiction of depth from the subject and texture of the subject). In some implementations, 3D processing may enable technical improvements because of the inverse optics problem which may, in some instances, affect 2D representations. The inverse optics problem refers to the phenomenon where, in some instances, the size of a subject, the orientation of the subject and the distance between the subject and the imaging device may be conflated in a 2D image of that subject. Any given projection of the subject on the imaging sensor could map to an infinite count of {size, orientation, distance} pairings. 3D representations enable the technical improvement in that 3D representations remove the ambiguities introduced by the inverse optics problem.

A device that is configured with the dedicated purpose of 3D scanning, such as a 3D intraoral scanner (or a CT scanner or MRI scanner), may generate 3D representations of the subject (e.g., the patient's dentition) which have significantly higher fidelity and precision than is possible with a handheld device. When such high-fidelity 3D data are available (e.g., in the application of oral care mesh classification or other 3D techniques described herein), the use of a 3D autoencoder is offers technical improvements (such as increased data precision), to extract the best possible signal out of those 3D data (i.e., to get the signal out of the 3D crown meshes used in tooth classification or setups classification).

A 3D autoencoder (comprising a 3D encoder and a 3D decoder) may be trained on 3D data representations to encode an input 3D representation into a latent form (such as a latent vector or a latent capsule) using the 3D encoder, and then reconstruct a facsimile of the input 3D representation using the 3D decoder. Among the operations which may be used to implement a 3D autoencoder for the analysis of a 3D representation (e.g., 3D mesh or 3D point cloud) are 3D convolution, 3D pooling and 3D reconstruction error calculation.

For each mesh element, a 3D convolution may be performed to aggregate local features from nearby mesh elements. Processing may be performed above and beyond the techniques for 2D convolution, to account for the differing count and locations of neighboring mesh elements (relative to a particular mesh element). A particular 3D mesh element may have a variable count of neighbors and those neighbors may not be found in expected locations (as opposed to a pixel in 2D convolution which may have a fixed count of neighboring pixels which may be found in known or expected locations). In some instances, the order of neighboring mesh elements may be relevant to 3D convolution.

### 3D Pooling:

A 3D pooling operation may enable the combining of features from a 3D mesh (or other 3D representation) at multiple scales. 3D pooling may iteratively reduce a 3D mesh into mesh elements which are most highly relevant to a given application (e.g., for which a neural network has been trained). Similarly to 3D convolution, 3D pooling may benefit from special processing beyond that entailed in 2D convolution, to account for the differing count and locations of neighboring mesh elements (relative to a particular mesh element). In some instances, the order of neighboring mesh elements may be less relevant to 3D pooling than to 3D convolution.

### 3D Reconstruction Error:

3D reconstruction error may be computed using one or more of the techniques described herein, such as computing Euclidean distances between corresponding mesh elements, between the two meshes. Other techniques are possible in accordance with aspects of this disclosure. 3D reconstruction error may generally be computed on 3D mesh elements, rather than the 2D pixels of 2D reconstruction error. 3D reconstruction error may enable technical improvements over 2D reconstruction error, because a 3D representation may, in some instances, have less ambiguity than a 2D representation (i.e., have less ambiguity in form, shape and/or structure). Additional processing may, in some implementations, be entailed for 3D reconstruction which is above and beyond that of 2D reconstruction, because of the complexity of mapping between the input and reconstructed mesh elements (i.e., the input and reconstructed meshes may have different mesh element counts, and there may be a less clear mapping between mesh elements than there is for the mapping between pixels in 2D reconstruction). The technical improvements of 3D reconstruction error calculation include data precision improvement.

Mesh element feature vectors A 3D representation may be produced using a 3D scanner, such as an intraoral scanner, a computerized tomography (CT) scanner, ultrasound scanner, a magnetic resonance imaging (MRI) machine or a mobile device which is enabled to perform stereophotogrammetry. A 3D representation may describe the shape and/or structure of a subject. A 3D representation may include one or more 3D mesh, 3D point cloud, and/or a 3D voxelized representation, among others. A 3D mesh includes edges, vertices, or faces. Though interrelated in some instances, these three types of data are distinct. The vertices are the points in 3D space that define the boundaries of the mesh. These points would alternatively be described as a point cloud but for the additional information about how the points are connected to each other, as described by the edges. An edge is described by two points and can also be referred to as a line segment. A face is described by a number of edges and vertices. For instance, in the case of a triangle mesh, a face comprises three vertices, where the vertices are interconnected to form three contiguous edges. Some meshes may contain degenerate elements, such as non-manifold mesh elements, which may be removed, to the benefit of later processing. Other mesh pre-processing operations are possible in accordance with aspects of this disclosure. 3D meshes are commonly formed using triangles, but may in other implementations be formed using quadrilaterals, pentagons, or some other n-sided polygon. In some implementations, a 3D mesh may be converted to one or more voxelized geometries (i.e., comprising voxels), such as in the case that sparse processing is performed. The techniques of this disclosure which operate on 3D meshes may receive as input one or more tooth meshes (e.g., arranged in one or more dental arches). Each of these meshes may undergo pre-processing before being input to the predictive architecture (e.g., including at least one of an encoder, decoder, pyramid encoder-decoder and U-Net). This pre-processing may include the conversion of the mesh into lists of mesh elements, such as vertices, edges, faces or in the case of sparse processing-voxels. For the chosen mesh element type or types, (e.g., vertices), feature vectors may be generated. In some examples, one feature vector is generated per vertex of the mesh. Each feature vector may contain a combination of spatial and/or structural features, as specified in the following table:

TABLE 1

| Element | Spatial Features | Structural Features |
|---|---|---|
| Edges | XYZ position of an edge | Edge curvature (depends on a |
| | midpoint, XYZ positions | connectivity neighborhood, |
| | of the edge vertices, or the | average curvature of two |
| | normal vector at edge | vertices), dihedral angles, edge |
| | midpoint (average of the | length, density measure such as |
| | normal vectors of two | a count of incident edges (i.e., a |
| | vertices). | count of the other neighboring |
| | | edges which share the vertices |
| | | of that edge). |
| Faces | XYZ position of a face | Face curvature (average |
| | centroid, surface normal | curvature of the vertices of the |
| | vector. | face), face area, density measure |
| | | such as count of adjacent faces |
| | | (i.e., which share at least one |
| | | edge with the face). |
| Points | XYZ position | Density measure such as the |
| | | count of neighboring points |
| | | within a radius of the point |
| Vertices | XYZ position, normal | Vertex curvature, density |
| | vector (weighted average | measure such as the count of |
| | of the normal vectors of | vertices within a radius of the |
| | the connecting faces for | vertex, density measure such as |
| | the vertex). | the count of incident edges. |
| Voxels | XYZ centroid. | Volume, [height × depth × width] |
| | | dimensions, density measure |
| | | such as a count of contained |
| | | vertices, density measure such as |
| | | count of intersected faces, |
| | | density measure such as count of |
| | | intersected edges. |

Table 1 discloses non-limiting examples of mesh element features. In some implementations, color (or other visual cues/identifiers) may be considered as a mesh element feature in addition to the spatial or structural mesh element features described in Table 1. As used herein (e.g., in Table 1), a point differs from a vertex in that a point is part of a 3D point cloud, whereas a vertex is part of a 3D mesh and may have incident faces or edges. A dihedral angle (which may be expressed in either radians or degrees) may be computed as the angle (e.g., a signed angle) between two connected faces (e.g., two faces which are connected along an edge). A sign on a dihedral angle may reveal information about the convexity or concavity of a mesh surface. For example, a positively signed angle may, in some implementations, indicate a convex surface. Furthermore, a negatively signed angle may, in some implementations, indicate a concave surface. To calculate the principal curvature of a mesh vertex, directional curvatures may first be calculated to each adjacent vertex around the vertex. These directional curvatures may be sorted in circular order (e.g., 0, 49, 127, 210, 305 degrees) in proximity to the vertex normal vector and may comprise a subsampled version of the complete curvature tensor. Circular order means: sorted in by angle around an axis. The sorted directional curvatures may contribute to a linear system of equations amenable to a closed form solution which may estimate the two principal curvatures and directions, which may characterize the complete curvature tensor. Consistent with Table 1, a voxel may also have features which are computed as the aggregates of the other mesh elements (e.g., vertices, edges and faces) which either intersect the voxel or, in some implementations, are predominantly or fully contained within the voxel. Rotating the mesh may not change structural features but may change spatial features. And, as described elsewhere in this disclosure, the term “mesh” should be considered in a non-limiting sense to be inclusive of 3D mesh, 3D point cloud and 3D voxelized representation. In some implementations, apart from mesh element features, there are alternative methods of describing the geometry of a mesh, such as 3D keypoints and 3D descriptors. Examples of such 3D keypoints and 3D descriptors are found in “TONIONI A, et al. in ‘Learning to detect good 3D keypoints.’, Int J Comput. Vis. 2018 Vol. 126, pages 1-20.”. 3D keypoints and 3D descriptors may, in some implementations, describe extrema (either minima or maxima) of the surface of a 3D representation. In some implementations, one or more mesh element features may be computed, at least in part, via deep feature synthesis (DFS), e.g. as described in: J. M. Kanter and K. Veeramachaneni, “Deep feature synthesis: Towards automating data science endeavors,” 2015 IEEE International Conference on Data Science and Advanced Analytics (DSAA), 2015, pp. 1-10, doi: 10.1109/DSAA.2015.7344858.

Representation generation neural networks based on autoencoders, U-Nets, transformers, other types of encoder-decoder structures, convolution and/or pooling layers, or other models may benefit from the use of mesh element features. Mesh element features may convey aspects of a 3D representation's surface shape and/or structure to the neural network models of this disclosure. Each mesh element feature describes distinct information about the 3D representation that may not be redundantly present in other input data that are provided to the neural network. For example, a vertex curvature may quantify aspects of the concavity or convexity of the surface of a 3D representation which would not otherwise be understood by the network. Stated differently, mesh element features may provide a processed version of the structure and/or shape of the 3D representation; data that would not otherwise be available to the neural network. This processed information is often more accessible, or more amenable for encoding by the neural network. A system implementing the techniques disclosed herein has been utilized to run a number of experiments on 3D representations of teeth. For example, mesh element features have been provided to a representation generation neural network which is based on a U-Net model, and also to a representation generation model based on a variational autoencoder with continuous normalizing flows. Based on experiments, it was found that systems using a full complement of mesh element features (e.g., “XYZ” coordinates tuple, “Normal vector”, “Vertex Curvature”, Points-Pivoted, and Normals-Pivoted) were at least 3% more accurate than systems that did not. Points-Pivoted describes “XYZ” coordinates tuples that have local coordinate systems (e.g., at the centroid of the respective tooth). Normals-Pivoted describes “Normal Vectors” which have local coordinate systems (e.g., at the centroid of the respective tooth). Furthermore, training converges more quickly when the full complement of mesh element features are used. Stated another way, the machine learning models trained using the full complement of mesh element features tended to be more accurate more quickly (at earlier epochs) than systems which did not. For an existing system observed to have a historical accuracy rate of 91%, an improvement in accuracy of 3% reduces the actual error rate by more than 30%.

Predictive models which may operate on feature vectors of the aforementioned features include but are not limited to: GDL Setups, RL Setups, VAE Setups, Capsule Setups, MLP Setups, Diffusion Setups, PT Setups, Similarity Setups, Tooth Classification, Setups Classification, Setups Comparison, VAE Mesh Element Labeling, MAE Mesh In-filling, Mesh Reconstruction Autoencoder, Validation Using Autoencoders, Mesh Segmentation, Coordinate System Prediction, Mesh Cleanup, Restoration Design Generation, Appliance Component Generation and Placement, and Archform Prediction. Such feature vectors may be presented to the input of a predictive model. In some implementations, such feature vectors may be presented to one or more internal layers of a neural network which is part of one or more of those predictive models.

According to particular implementations, convolution layers in the various 3D neural networks described herein may use edge data to perform mesh convolution. The use of edge information guarantees that the model is not sensitive to different input orders of 3D elements. In addition to or separate from using edge data, the convolution layers may use vertex data to perform mesh convolution. The use of vertex information is advantageous in that there are typically fewer vertices than edges or faces, so vertex-oriented processing may lead to a lower processing overhead and lower computational cost. In addition to or separate from using edge data or vertex data, the convolution layers may use face data to perform mesh convolution. Furthermore, in addition to or separate from using edge data, vertex data, or face data, the convolution layers may use voxel data to perform mesh convolution. The use of voxel information is advantageous in that, depending on the granularity chosen, there may be significantly fewer voxels to process compared to the vertices, edges or faces in the mesh. Sparse processing (with voxels) may lead to a lower processing overhead and lower computational cost (especially in terms of computer memory or RAM usage).

The neural networks of this disclosure may exploit one or more benefits of the operation of parameter tuning, whereby the inputs and parameters of a neural network are optimized to produce more data-precede results. One parameter which may be tuned is neural network learning rate (e.g., which may have values such as 0.1, 0.01, 0.001, etc.). Data augmentation schemes may also be tuned or optimized, such as schemes where “shiver” is added to the tooth meshes before being input to the neural network (i.e., small random rotations, translations and/or scaling may be applied to vary the dataset and make the neural network robust to variations in data).

A subset of the neural network model parameters available for tuning are as follows:
Learning rate (LR) decay rate (e.g., how much the LR decays during a training run)
Learning rate (LR). The floating-point value (e.g., 0.001) that is used by the optimizer.
LR schedule (e.g., cosine annealing, step, exponential)
Voxel size (for cases with sparse mesh processing operations)
Dropout % (e.g., dropout which may be performed in a linear encoder)
LR decay step size (e.g., decay every 10 or 20 or 30 epochs)
Model scaling, which may increase or decrease the count of layers and/or the count of parameters per layer.

Parameter tuning may be advantageously applied to the training of a neural network for the prediction of final setups or intermediate staging to provide data precision-oriented technical improvements. Parameter tuning may also be advantageously applied to the training of a neural network for mesh element labeling or a neural network for mesh in-filling. In some examples, parameter tuning may be advantageously applied to the training of a neural network for tooth reconstruction. In terms of classifier models of this disclosure, parameter tuning may be advantageously applied to a neural network for the classification of one or more setups (i.e., classification of one or more arrangements of teeth). The advantage of parameter tuning is to improve the data precision of the output of a predictive model or a classification model. Parameter tuning may, in some instances, provide the advantage of obtaining the last remaining few percentage points of validation accuracy out of a predictive or classification model.

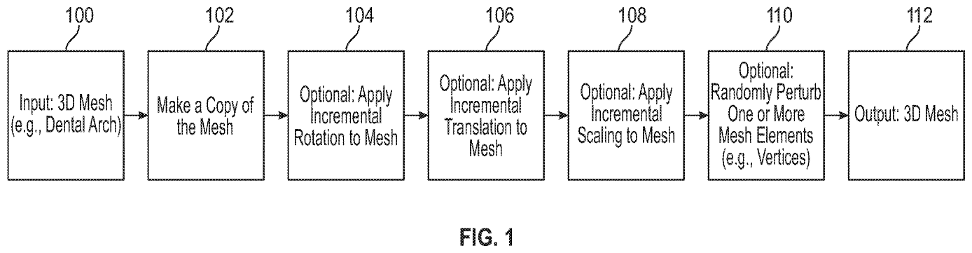

Various neural network models of this disclosure may draw benefits from data augmentation. Examples include models of this which are trained on 3D meshes, such as GDL Setups, RL Setups, VAE Setups, Capsule Setups, MLP Setups, Diffusion Setups, PT Setups, Similarity Setups, FDG Setups, Setups Classification, Setups Comparison, VAE Mesh Element Labeling, MAE Mesh In-filling, Mesh Reconstruction VAE, and Validation Using Autoencoders. Data augmentation, such as by way of the method shown in FIG. 1, may increase the size of the training dataset of dental arches. Data augmentation can provide additional training examples by adding random rotations, translations, and/or rescaling to copies of existing dental arches. In some implementations of the techniques of this disclosure, data augmentation may be carried out by perturbing or jittering the vertices of the mesh, in a manner similar to that described in (“Equidistant and Uniform Data Augmentation for 3D Objects”, IEEE Access, Digital Object Identifier 10.1109/ACCESS.2021.3138162). The position of a vertex may be perturbed through the addition of Gaussian noise, for example with zero mean, and 0.1 standard deviation. Other mean and standard deviation values are possible in accordance with the techniques of this disclosure.

FIG. 1 shows a data augmentation method that systems of this disclosure may apply to 3D oral care representations. A non-limiting example of a 3D oral care representation is a tooth mesh or a set of tooth meshes. Tooth data 100 (e.g., 3D meshes) are received at the input. The systems of this disclosure may generate copies of the tooth data 100 (102). In the example of FIG. 1, the systems of this disclosure may apply one or more stochastic rotations to the tooth data 100 (104). In the example of FIG. 1, the systems of this disclosure may apply stochastic translations to the tooth data 100 (106). The systems of this disclosure may apply stochastic scaling operations to the tooth data 100 (108). The systems of this disclosure may apply stochastic perturbations to one or more mesh elements of the tooth data 100 (110). The systems of this disclosure may output augmented tooth data 112 that are formed by way of the method of FIG. 1.

Because generator networks of this disclosure can be implemented as one or more neural networks, the generator may contain an activation function. When executed, an activation function outputs a determination of whether or not a neuron in a neural network will fire (e.g., send output to the next layer). Some activation functions may include: binary step functions, or linear activation functions. Other activation functions impart non-linear behavior to the network, including: sigmoid/logistic activation functions, Tanh (hyperbolic tangent) functions, rectified linear units (ReLU), leaky ReLU functions, parametric ReLU functions, exponential linear units (ELU), softmax function, swish function, Gaussian error linear unit (GELU), or scaled exponential linear unit (SELU). A linear activation function may be well suited to some regression applications (among other applications), in an output layer. A sigmoid/logistic activation function may be well suited to some binary classification applications (among other applications), in an output layer. A softmax activation function may be well suited to some multiclass classification applications (among other applications), in an output layer. A sigmoid activation function may be well suited to some multilabel classification applications (among other applications), in an output layer. A ReLU activation function may be well suited in some convolutional neural network (CNN) applications (among other applications), in a hidden layer. A Tanh and/or sigmoid activation function may be well suited in some recurrent neural network (RNN) applications (among other applications), for example, in a hidden layer. There are multiple optimization algorithms which can be used in the training of the neural networks of this disclosure (such as in updating the neural network weights), including gradient descent (which determines a training gradient using first-order derivatives and is commonly used in the training of neural networks), Newton's method (which may make use of second derivatives in loss calculation to find better training directions than gradient descent, but may require calculations involving Hessian matrices), and conjugate gradient methods (which may yield faster convergence than gradient descent, but do not require the Hessian matrix calculations which may be required by Newton's method). In some implementations, additional methods may be employed to update weights, in addition to or in place of the techniques described above. These additional methods include the Levenberg-Marquardt method and/or simulated annealing. The backpropagation algorithm is used to transfer the results of loss calculation back into the network so that network weights can be adjusted, and learning can progress.

Neural networks contribute to the functioning of many of the applications of the present disclosure, including but not limited to: GDL Setups, RL Setups, VAE Setups, Capsule Setups, MLP Setups, Diffusion Setups, PT Setups, Similarity Setups, Tooth Classification, Setups Classification, Setups Comparison, VAE Mesh Element Labeling, MAE Mesh In-filling, Mesh Reconstruction Autoencoder, Validation Using Autoencoders, imputation of oral care parameters, 3D mesh segmentation (3D representation segmentation), Coordinate System Prediction, Mesh Cleanup, Restoration Design Generation, Appliance Component Generation and Placement, or Archform Prediction. The neural networks of the present disclosure may embody part or all of a variety of different neural network models. Examples include the U-Net architecture, multi-later perceptron (MLP), transformer, pyramid architecture, recurrent neural network (RNN), autoencoder, variational autoencoder, regularized autoencoder, conditional autoencoder, capsule network, capsule autoencoder, stacked capsule autoencoder, denoising autoencoder, sparse autoencoder, conditional autoencoder, long/short term memory (LSTM), gated recurrent unit (GRU), deep belief network (DBN), deep convolutional network (DCN), deep convolutional inverse graphics network (DCIGN), liquid state machine (LSM), extreme learning machine (ELM), echo state network (ESN), deep residual network (DRN), Kohonen network (KN), neural Turing machine (NTM), or generative adversarial network (GAN). In some implementations, an encoder structure or a decoder structure may be used. Each of these models provides one or more of its own particular advantages. For example, a particular neural networks architecture may be especially well suited to a particular ML technique. For example, autoencoders are particularly suited to the classification of 3D oral care representations, due to the ability to encode the 3D oral care representation into a form which is more easily classifiable.

In some implementations, the neural networks of this disclosure can be adapted to operate on 3D point cloud data (alternatively on 3D meshes or 3D voxelized representation). Numerous neural network implementations may be applied to the processing of 3D representations and may be applied to training predictive and/or generative models for oral care applications, including: PointNet, PointNet++, SO-Net, spherical convolutions, Monte Carlo convolutions and dynamic graph networks, PointCNN, ResNet, MeshNet, DGCNN, VoxNet, 3D-ShapeNets, Kd-Net, Point GCN, Grid-GCN, KCNet, PD-Flow, PU-Flow, MeshCNN and DSG-Net. Oral care applications include, but are not limited to: setups prediction (e.g., using VAE, RL, MLP, GDL, Capsule, Diffusion, etc. which have been trained for setups prediction), 3D representation segmentation, 3D representation coordinate system prediction, element labeling for 3D representation clean-up (VAE for Mesh Element labeling), in-filling of missing elements in 3D representation (MAE for Mesh In-Filling), dental restoration design generation, setups classification, appliance component generation and/or placement, archform prediction, imputation of oral care parameters, setups validation, or other validation applications and tooth 3D representation classification.

Some implementations of the techniques of this disclosure incorporate the use of an autoencoder. Autoencoders that can be used in accordance with aspects of this disclosure include but are not limited to: AtlasNet, FoldingNet and 3D-PointCapsNet. Some autoencoders may be implemented based on PointNet.

Representation learning may be applied to setups prediction techniques of this disclosure by training a neural network to learn a representation of the teeth, and then using another neural network to generate transforms for the teeth. Some implementations may use a VAE or a Capsule Autoencoder to generate a representation of the reconstruction characteristics of the one or more meshes related to the oral care domain (including, in some instances, information about the structures of the tooth meshes). Then that representation (either a latent vector or a latent capsule) may be used as input to a module which generates the one or more transforms for the one or more teeth. These transforms may in some implementations place the teeth into final setups poses. These transforms may in some implementations place the teeth into intermediate staging poses. In some implementations, a transform may be described by a 9×1 transformation vector (e.g., that specifies a translation vector and a quaternion). In other implementations, a transform may be described by a transformation matrix (e.g., a 4×4 affine transformation matrix).

In some implementations, systems of this disclosure may implement a principal components analysis (PCA) on an oral care mesh, and use the resulting principal components as at least a portion of the representation of the oral care mesh in subsequent machine learning and/or other predictive or generative processing.

According to aspects of this disclosure, an autoencoder may be trained to generate a latent form of a 3D oral care representation. For example, the autoencoder may contain a 3D encoder (which encodes a 3D oral care representation into a latent form), and a 3D decoder (which reconstructs that latent from into a facsimile of the inputted 3D oral care representation). Although this disclosure refers to 3D encoders and 3D decoders, the term 3D should be interpreted in a non-limiting fashion to encompass multi-dimensional modes of operation. For example, systems of this disclosure may train and deploy multi-dimensional encoders and/or multi-dimensional decoders.

Systems of this disclosure may implement end-to-end training. Some of the end-to-end training-based techniques of this disclosure may involve two or more neural networks, where the two or more neural networks are trained together (i.e., the weights are updated concurrently during the processing of each batch of input oral care data). End-to-end training may, in some implementations, be applied to setups prediction by concurrently training a neural network which learns a representation of the teeth, along with a neural network which generates the tooth transforms.

According to some of the transfer learning-based implementations of this disclosure, a neural network (e.g., a U-Net) may be trained on a first task (e.g., such as coordinate system prediction). The neural network trained on the first task may be executed to provide one or more of the starting neural network weights for the training of another neural network that is trained to perform a second task (e.g., setups prediction). The first network may learn the low-level neural network features of oral care meshes and be shown to work well at the first task. The second network may exhibit faster training and/or improved performance by using the first network as a starting point in training. Certain layers may be trained to encode neural network features for the oral care meshes that were in the training dataset. These layers may thereafter be fixed (or be subjected to minor changes over the course of training) and be combined with other neural network components, such as additional layers, which are trained for one or more oral care tasks (such as setups prediction). In this manner, a portion of a neural network for one or more of the techniques of the present disclosure (e.g., setups prediction) may receive initial training on another task, which may yield important learning in the trained network layers. This encoded learning may then be built upon with further task-specific training of another network.

In accordance with this disclosure, transfer learning may be used for setups prediction, as well as for other oral care applications, such as mesh classification (e.g., tooth or setups classification), mesh element labeling, mesh element in-filling, procedure parameter imputation, mesh segmentation, coordinate system prediction, restoration design generation, mesh validation (for any of the applications disclosed herein). In some implementations, a neural network trained to output predictions based on oral care meshes may first be partially trained on one of the following publicly available datasets, before being further trained on oral care data: Google PartNet dataset, ShapeNet dataset, ShapeNetCore dataset, Princeton Shape Benchmark dataset, ModelNet dataset, ObjectNet3D dataset, Thingi10K dataset (which is especially relevant to 3D printed parts validation), ABC: A Big CAD Model Dataset For Geometric Deep Learning, ScanObjectNN, VOCASET, 3D-FUTURE, MCB: Mechanical Components Benchmark, PoseNet dataset, PointCNN dataset, MeshNet dataset, MeshCNN dataset, PointNet++ dataset, PointNet dataset, or PointCNN dataset.

In some implementations, a neural network which was previously trained on a first dataset (either oral care data or other data) may subsequently receive further training on oral care data and be applied to oral care applications (such as setups prediction). Transfer learning may be employed to further train any of the following networks: GCN (Graph Convolutional Networks), PointNet, ResNet or any of the other neural networks from the published literature which are listed above.

In some implementations, a first neural network may be trained to predict coordinate systems for teeth (such as by using the techniques described in WO2022123402A1 or US Provisional Application No. U.S. 63/366,492). A second neural network may be trained for setups prediction, according to any of the setups prediction techniques of the present disclosure (or a combination of any two or more of the techniques described herein). Transfer learning may transfer at least a portion of the knowledge or capability of the first neural network to the second neural network. As such, transfer learning may provide the second neural network an accelerated training phase to reach convergence. In some implementations, the training of the second network may, after being augmented with the transferred learning, then be completed using one or more of the techniques of this disclosure.

Systems of this disclosure may train ML models with representation learning. The advantages of representation learning include that the generative network (e.g., neural network that predicts a transform for use in setups prediction) can be configured to receive input with a known size and/or standard format, as opposed to receiving input with a variable size or structure. Representation learning may produce improved performance over other techniques, because noise in the input data may be reduced (e.g., because the representation generation model extracts hierarchical neural network features and/or reconstruction characteristics of an inputted representation (e.g., a mesh or point cloud) through loss calculations or network architectures chosen for that purpose).

Reconstruction characteristics may comprise values in of a latent representation (e.g., a latent vector) that describe aspects of the shape and/or structure of the 3D representation that was provided to the representation generation module that generated the latent representation. The weights of the encoder module of a reconstruction autoencoder, for example, may be trained to encode a 3D representation (e.g., a 3D mesh, or others described herein) into a latent vector representation (e.g., a latent vector). Stated another way, the capability to encode a large set (e.g., hundreds, thousands or millions) of mesh elements into a latent vector (e.g., of hundreds or a thousand real values—e.g., 512, 1024, etc.) may be learned by the weights of the encoder. Each dimension of that latent vector may contain a real number which describes some aspect of the shape and/or structure of the original 3D representation. The weights of the decoder module of the reconstruction autoencoder may be trained to reconstruct the latent vector into a close facsimile of the original 3D representation. Stated another way, the capability to interpret the dimensions of the latent vector, and to decode the values within those dimensions, may be learned by the decoder. In summary, the encoder and decoder neural network modules are trained to perform the mapping of a 3D representation into a latent vector, which may then be mapped back (or otherwise reconstructed) into a 3D representation that is substantially similar to an original 3D representation for which the latent vector was generated.

Returning to loss calculation, examples of loss calculation may include KL-divergence loss, reconstruction loss or other losses disclosed herein. Representation learning may reduce the size of the dataset required for training a model, because the representation model learns the representation, enabling the generative network to focus on learning the generative task. The result may be improved model generalization because meaningful neural network features of the input data (e.g., local and/or global features) are made available to the generative network. Stated another way, a first network may learn the representation, and a second network may make the predictive decision. By training two networks to perform their own separate tasks, each of the networks may generate more accurate results for their respective tasks than with a single network which is trained to both learn a representation and make a decision. In some instances, transfer learning may first train a representation generation model. That representation generation model (in whole or in part) may then be used to pre-train a subsequent model, such as a generative model (e.g., that generates transform predictions). A representation generation model may benefit from taking mesh element features as input, to improve the capability of a second ML module to encode the structure and/or shape of the inputted 3D oral care representations in the training dataset.

One or more of the neural networks models of this disclosure may have attention gates integrated within. Attention gate integration provides the enhancement of enabling the associated neural network architecture to focus resources on one or more input values. In some implementations, an attention gate may be integrated with a U-Net architecture, with the advantage of enabling the U-Net to focus on certain inputs, such as input flags which correspond to teeth which are meant to be fixed (e.g. prevented from moving) during orthodontic treatment (or which require other special handling). An attention gate may also be integrated with an encoder or with an autoencoder (such as VAE or capsule autoencoder) to improve predictive accuracy, in accordance with aspects of this disclosure. For example, attention gates can be used to configure a machine learning model to give higher weight to aspects of the data which are more likely to be relevant to correctly generated outputs. As such, and because a machine learning model configured with these attention gates (or mechanisms) utilizes aspects of the data that are more likely to be relevant to correctly generated outputs, the ultimate predictive accuracy of those machine learning models is improved.

The quality and makeup of the training dataset for a neural network can impact the performance of the neural network in its execution phase. Dataset filtering and outlier removal can be advantageously applied to the training of the neural networks for the various techniques of the present disclosure (e.g., for the prediction of final setups or intermediate staging, for mesh element labeling or a neural network for mesh in-filling, for tooth reconstruction, for 3D mesh classification, etc.), because dataset filtering and outlier removal may remove noise from the dataset. And while the mechanism for realizing an improvement is different than using attention gates, that ultimate outcome is that this approach allows for the machine learning model to focus on relevant aspects of the dataset, and may lead to improvements in accuracy similar to improvements in accuracy realized vis-à-vis attention gates.

In the case of a neural network configured to predict a final setup, a patient case may contain at least one of a set of segmented tooth meshes for that patient, a mal transform for each tooth, and/or a ground truth setup transform for each tooth. In the case of a neural network to predict a set of intermediate stage setups, a patient case may contain at least one of a set of segmented tooth meshes for that patient, a mal transform for each tooth, and/or a set of ground truth intermediate stage transforms for each tooth. In some implementations, a training dataset may exclude patient cases which contact passive stages (i.e., stages where the teeth of an arch do not move). In some implementations, the dataset may exclude cases where passive stages exist at the end of treatment. In some implementations, a dataset may exclude cases where overcrowding is present at the end of treatment (i.e., where the oral care provider, such as an orthodontist or dentist) has chosen a final setup where the tooth meshes overlap to some degree. In some implementations, the dataset may exclude cases of a certain level (or levels) of difficulty (e.g., easy, medium and hard).

In some implementations, the dataset may include cases with zero pinned teeth (or may include cases where at least one tooth is pinned). A pinned tooth may be designated by a technician as they design the treatment to stop the various tools from moving that particular tooth. In some implementations, a dataset may exclude cases without any fixed teeth (conversely, where at least one tooth is fixed). A fixed tooth may be defined as a tooth that shall not move in the course of treatment. In some implementations, a dataset may exclude cases without any pontic teeth (conversely, cases in which at least one tooth is pontic). A pontic tooth may be described as a “ghost” tooth that is represented in the digital model of the arch but is either not actually present in the patient's dentition or where there may be a small or partial tooth that may benefit from future work (such as the addition of composite material through a dental restoration appliance). The advantage of including a pontic tooth in a patient case is to leave space in the arch as a part of a plan for the movements of other teeth, in the course of orthodontic treatment. In some instances, a pontic tooth may save space in the patient's dentition for future dental or orthodontic work, such as the installation of an implant or crown, or the application of a dental restoration appliance, such as to add composite material to an existing tooth that is too small or has an undesired shape.

In some implementations, the dataset may exclude cases where the patient does not meet an age requirement (e.g., younger than 12). In some implementations, the dataset may exclude cases with interproximal reduction (IPR) beyond a certain threshold amount (e.g., more than 1.0 mm). The dataset to train a neural network to predict setups for clear tray aligners (CTA) may exclude patient cases which are not related to CTA treatment. The dataset to train a neural network to predict setups for an indirect bonding tray product may exclude cases which are not related to indirect bonding tray treatment. In some implementations, the dataset may exclude cases where only certain teeth are treated. In such implementations, a dataset may comprise of only cases where at least one of the following are treated: anterior teeth, posterior teeth, bicuspids, molars, incisors, and/or cuspids.

Some autoencoder-based implementations of this disclosure use capsule autoencoders to automate processing steps in the creation of oral care appliances (e.g., for orthodontic treatment or dental restoration). The advantage of using capsule autoencoders which have been trained on oral care data is to leverage latent space techniques which reduce the dimensionality of oral care mesh data and thereby refine those data, making the signal in the data stronger and more readily usable by downstream processing modules, whether those downstream modules may be other autoencoder(s), decoder(s), other neural networks, or other types of ML models (such as the supervised and unsupervised models described elsewhere in this disclosure). Capsule autoencoders were originally applied in the 2D domain to perform object recognition in 2D images, where capsules were trained to create a model of the object that was to be recognized. Such an approach enabled an object to be recognized in the 2D image, even if the object was imaged from a new view that was not present in the training dataset. Later research extended capsule autoencoders to the domain of 3D point clouds, such as in “3D Point Capsule Networks” in the proceedings of CVPR 2019, which is incorporated herein by reference in its entirety.

The present disclosure extends the outcomes of this research to apply capsule autoencoders to the domain of digital oral care, dealing with 3D point clouds, 3D meshes and 3D voxelized representation. The term “mesh” in the following should be considered interchangeable with 3D point cloud and 3D voxelized representations, in particular implementations. A 3D autoencoder may encode one or more 3D geometries (point clouds or meshes) into latent capsules which encode the reconstruction characteristics of the input 3D representation. These latent capsules exist in two or more dimensions and describe features of the input mesh (or point cloud) and the likelihoods of those features. A set of latent capsules stands in contrast to the latent vector which may be produced by a variational autoencoder (VaE), which may be encoded as a 1D vector. Among the contributions of the present technique is to advantageously apply capsule autoencoders to the digital oral care space, with the data precision-oriented technical advantage of improving predictive results.

Particular examples of applications include segmentation of 3D oral care geometries, setups prediction (both final setups and intermediate stages), mesh cleanup of 3D oral care geometries (e.g., both for the labeling of mesh elements and the filling-in of missing mesh elements), tooth classification (e.g., according to standard dental notation schemes), setups classification (e.g., as mal, staging and final setup) and automated dental restoration design generation.

The one or more latent capsules describing an input 3D representation (e.g., oral care geometries such as point clouds and/or meshes representing unsegmented dental arches, segmented teeth—such as arranged in a maloccluded setup, teeth with hardware attached, teeth without hardware attached, etc.) can be provided to a capsule decoder, to reconstruct a facsimile of the input 3D representation. This facsimile can be compared to the input 3D representation through the calculation of a reconstruction error, thereby demonstrating the information-rich nature of the latent capsule (i.e., that the latent capsule describes sufficient reconstruction characteristics of the input mesh, such that the mesh can be reconstructed from that latent capsule). A low reconstruction error (e.g., below a predetermined loss threshold) indicates that the reconstruction was a success. Some of the applications disclosed herein use this information-rich latent capsule for further processing (e.g., such as setups prediction, mesh segmentation, coordinate system prediction, mesh element labelling for mesh cleanup, in-filling of missing mesh elements or of holes in meshes, classification of setups, classification of oral care meshes, validation of setups and other validation appliances too). Some of the applications disclosed herein make one or more changes to the latent capsule, such as to effectuate changes in the reconstructed mesh, which may then be outputted for further use (e.g., to create a dental restoration appliance).

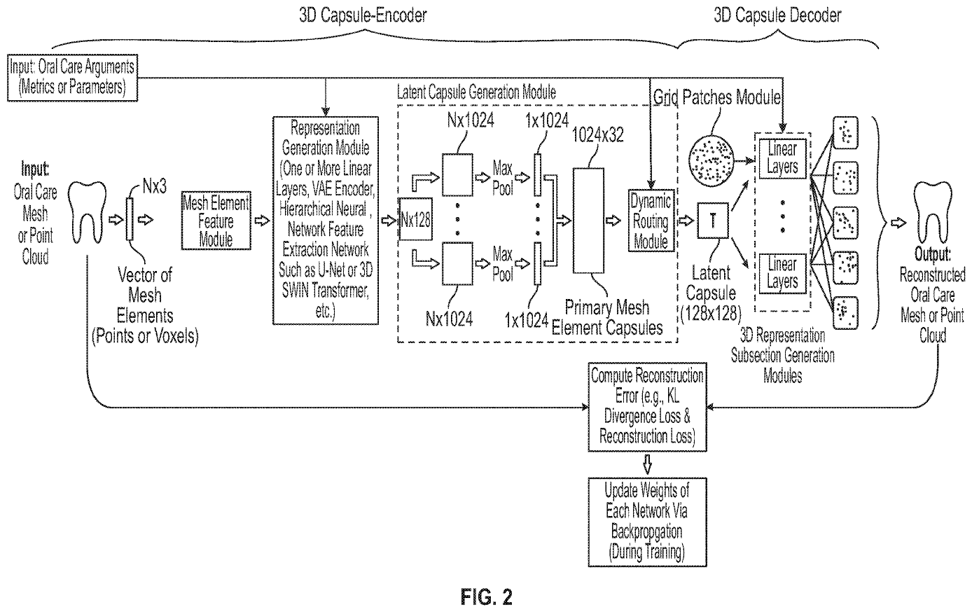

FIG. 2 illustrates an example training method of this disclosure for a capsule autoencoder for reconstructing oral care meshes (or point clouds). FIG. 2 shows a capsule autoencoder method for mesh reconstruction, which are primarily applied to oral care meshes in the non-limiting examples described herein, but which may also be applied to other healthcare meshes, or to personal safety meshes, such as meshes pertaining to the design, shape, function, and/or use of personal protective equipment, such as disposable respirators. The deployment method omits the two modules on the bottom. The training method encompasses the whole diagram. The latent capsule T may be a reduced dimensionality form of the inputted oral care mesh and may be used as an input to other processing.

Some existing techniques rely on inputting 3D point cloud data into a capsule autoencoder. Techniques of the present disclosure expand the input geometries to include 3D mesh data and 3D voxelized representations. In some instances, an input point cloud or mesh (such as containing oral care data) may be rearranged into one or more vectors of mesh elements. Such a vector may be Nx3 (in the case representing the XYZ coordinates of points or vertices). Such a vector may be Nx3 (in the case of representing mesh faces, each of which may be defined by 3 indices, each of which indexes into a list of vertices/points). Such a vector may be Nx2 (in the case of representing mesh edges, each of which may be defined by 2 indices, each of which can be indexed into a list of vertices/points). Such a vector may be Nx3 (in the case of representing voxels, each of which has an XYZ location, such as a centroid, where the Length×Width×Height of each voxel is known).

In some examples in accordance with aspects of this disclosure, a neural network, such as an MLP, may be used to extract features from the Nx3 mesh element input list, yielding an Nx128 list of feature vectors, one feature vector per mesh element. In some instances, a vector of one or more computed mesh element features (as defined elsewhere in this disclosure) may be computed for one or more of the N inputted mesh elements. In some implementations, these mesh element features may be used in place of the MLP-generated features. In some implementations, each mesh element may be given a feature which is a hybrid of MLP-generated features and the computed mesh element features, in which case the layer dimension may be augmented to be Nx(128+aug_len), where aug_len is the length of the augmentation vector, consisting of the computed mesh element features. For ease of discussion, and without the loss of generality, this layer will simply be referred to as Nx128 hereafter.

The length ‘aug_len’ may vary from implementation to implementation, depending on which mesh elements are analyzed and which mesh element features are chosen for use. In some instances, information from more than one type of mesh element may be introduced with the Nx128 vector (e.g., point/vertex information may be combined with face information, point/vertex information may be combined with edge information, or point/vertex information may be combined with voxel information). The analysis of different kinds of oral care meshes may call for one mesh element type or another, or for a particular set of mesh features, according to various applications.

The Nx128 layer may be passed to a set of subsequent convolutions layers, each of which has been trained to have its own parameter values. The purpose of each of these independent convolution layers may encode the individual mesh element capsules. The output of each of the convolution layers may be maxpooled to a size of 1024 elements. The count of these convolution layers may be a power of two (e.g., 8, 16, 32, 64). In some implementations, there may be 32 such convolution layers, each of which outputs a 1024 element vector from the maxpooling operation. These 32 maxpooling output vectors may be concatenated, forming a layer that may be 1024×32, called the Primary Mesh Element Capsules (PMEC). A dynamic routing module encodes these PMECs into one or more latent capsules, each of which may have square dimensions (e.g., 16×16, 32×32, 64×64, or 128×128). Non-square dimensions are also possible.

In some implementations, a dynamic routing module may enable the output of a latent capsule to be routed to a suitable neural network layer in a subsequent processing module of the capsule autoencoder. The dynamic routing module uses unsupervised techniques (e.g., clustering and/or other unsupervised techniques) to arrange the output of the set of max-pooled feature maps into one or more stacked latent capsules. These latent capsules summarize feature information from the input 3D representation (e.g., one or more tooth meshes or point clouds) and also the likelihood information associated with each capsule. These stacked capsules contain sufficient information about the input 3D representation to reconstruct that 3D representation via the Capsule-Decoder module.

A grid of mesh elements (i.e., such as points/vertices, edges, face or voxels) may be generated by Grid Patches module. Points will be used for the mesh element, in this example. In some implementations, this grid may comprise of randomly arranged points. In other implementations, this grid may reflect a regular and/or rectilinear arrangement of points. The points in each of these grid patches are the “raw material” from which the reconstructed 3D representation may be formed.

The latent capsule (e.g., with dimension 128×128) may be replicated β times, and each of those β latent capsules may be appended with each of the grid patch of randomly generated mesh elements (e.g., points/vertices) in turn, before being input to one or more MLPs. In some examples, such an MLP may comprise of fully connected layers with the following dimensions: {64-64-32-16-3}. The goal of such an operation is to tailor the mesh elements to a specific local area of the 3D representation which may be to be reconstructed. The decoder iterates, generating additional random grid patches and outputting more random portions of the reconstructed 3D representation (i.e., as point cloud patches). These point cloud patches are accumulated until a reconstruction loss drops below a target threshold. The reconstruction loss may be computed using one or more of reconstruction loss (as defined herein) and KL-Divergence loss.

An autoencoder, such as a variational autoencoder (VAE), may be trained to encode 3D mesh data in a latent space vector A, which may exist in an information-rich low-dimensional latent space. This latent space vector A may be particularly suitable for later processing by digital oral care applications (e.g., such as mesh cleanup, mesh segmentation, mesh validation, mesh classification, setups classification, setups prediction and restoration design generation, among others), because A enables high-dimensional tooth mesh data to be efficiently manipulated. Such a VAE may be trained to reconstruct the latent space vector A back into a facsimile of the input mesh (or transform or other data structure describing a 3D oral care representation). In some implementations, the latent space vector A may be strategically modified, so as to result in changes to the reconstructed mesh (or other data structure). In some instances, the reconstructed mesh may be a tooth mesh with an altered and/or improved shape, such as would be suitable for use in the design of a dental restoration appliance, such as a 3M FILTEK Matrix or a veneer. The term mesh should be considered in a non-limiting sense to be inclusive of 3D mesh, 3D point cloud and 3D voxelized representation.

Aspects of a tooth mesh reconstruction autoencoder (e.g., a variational autoencoder optionally utilizing normalizing flows) that can be used in accordance with techniques of this disclosure are described below. Continuous normalizing flows (CNF) may comprise a series of invertible mappings which may transform a probability distribution. CNF may be implemented by a succession of blocks in the decoder of an autoencoder. Such blocks may constrict a complex probability distribution, thereby enabling the decoder to learn to map a simple distribution to a more complicated distribution and back, which leads to a data precision-related technical improvement that enables the distribution of tooth shapes after reconstruction to be more representative of the distribution of tooth shapes in the training dataset. The invertibility of a CNF provides a resource-reduction technical advantage of improved mathematical efficiencies during training, thereby providing resource usage-related technical improvements.

The tooth reconstruction VAE may advantageously make use of loss functions, nonlinearities (aka neural network activation functions) and/or solvers which are not mentioned by existing techniques. Examples of loss functions may include: mean absolute error (MAE), mean squared error (MSE), L1-loss, L2-loss, KL-divergence, entropy, and reconstruction loss. Such loss functions enable each generated prediction to be compared against the corresponding ground truth value in a quantified manner, leading to one or more loss values which can be used to train, at least in part, one or more of the neural networks. Examples of solvers may include: dopri5, bdf, rk4, midpoint, adams, explicit_adams, and fixed_adams. The solvers may enable the neural networks to solve systems of equations and corresponding unknown variables. Examples of nonlinearities may include: tanh, relu, softplus, elu, swish, square, and identity. The activation functions may be used to introduce nonlinear behavior to the neural networks in a manner that enables the neural networks to better represent the training data. Losses may be computed through the process of training the neural networks via backpropagation. Neural network layers such as the following may be used: ignore, concat, concat_v2, squash, concatsquash, scale and concatscale.

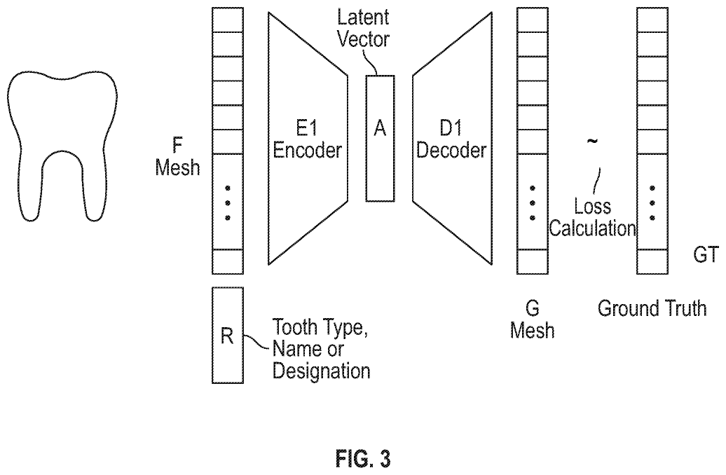

In some implementations, the tooth reconstruction VAE model may be trained on patient cases of teeth in malocclusion, or alternatively in local coordinates. FIG. 3 shows a method of training such a VAE.

According to the mesh reconstruction VAE training shown in FIG. 3, a 3D oral care representation F may be provided to the encoder E1 (along with optional tooth type information R), which may generate latent vector A. Latent vector A may be reconstructed into reconstructed 3D oral care representation G. Loss may be computed between the reconstructed 3D oral care representation G and ground truth 3D oral care representation GT (e.g., using the VAE loss calculation methods or other loss calculation methods described herein). Backpropagation may be used to train E1 and D1 with such loss.

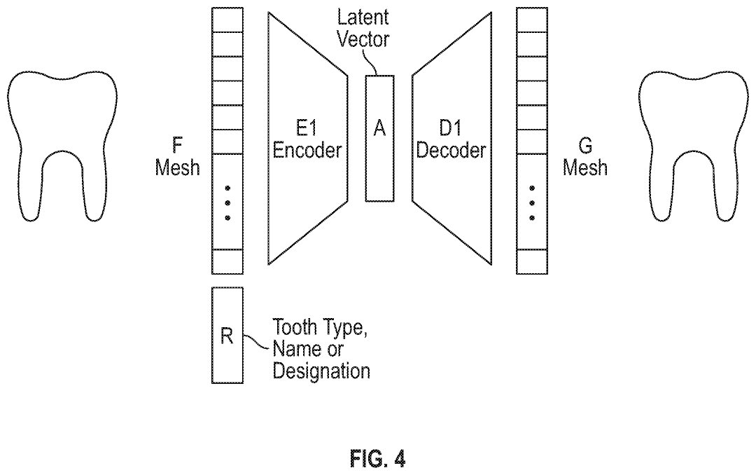

FIG. 4 shows the trained mesh reconstruction VAE in deployment. The mesh reconstruction VAE shown reconstructing a tooth mesh in deployment is shown in FIG. 4. R is an optional input, particularly in the case of tooth mesh classification, when such information R is not yet available (due to the tooth mesh classification neural network being trained to generate tooth type information R as an output, according to particular implementations). R may, in some implementations, be used to improve other techniques such as mesh element labelling techniques, mesh reconstruction techniques, oral care mesh classification techniques (e.g., such as tooth classification or setups classification), among others.

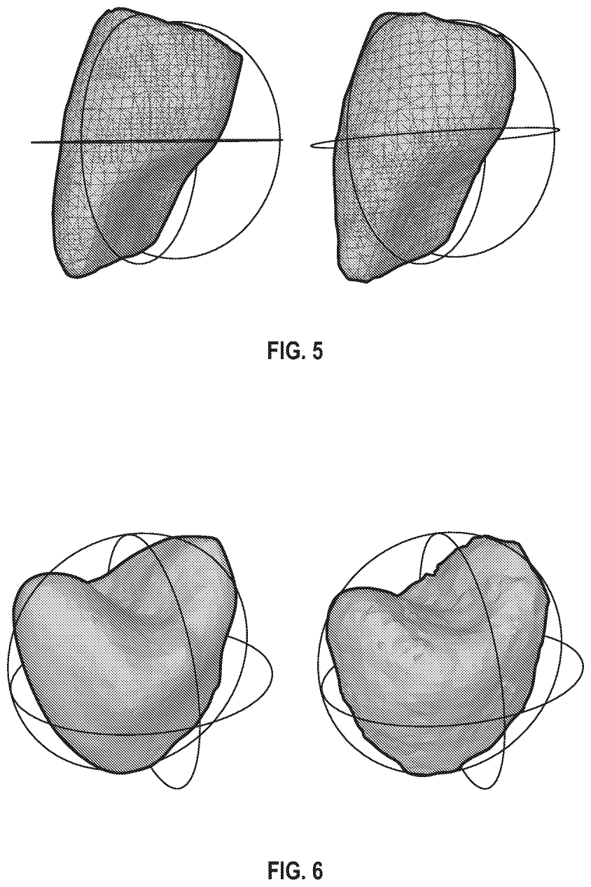

FIGS. 5 and 6 show reconstructed tooth meshes. FIG. 5 illustrates examples of an input tooth mesh (left) and the outputted reconstructed tooth mesh (right). FIG. 6 illustrates additional examples of an input tooth mesh (left) and the outputted reconstructed tooth mesh (right). The use cases shown in FIG. 6 are different from the use cases shown in FIG. 5.

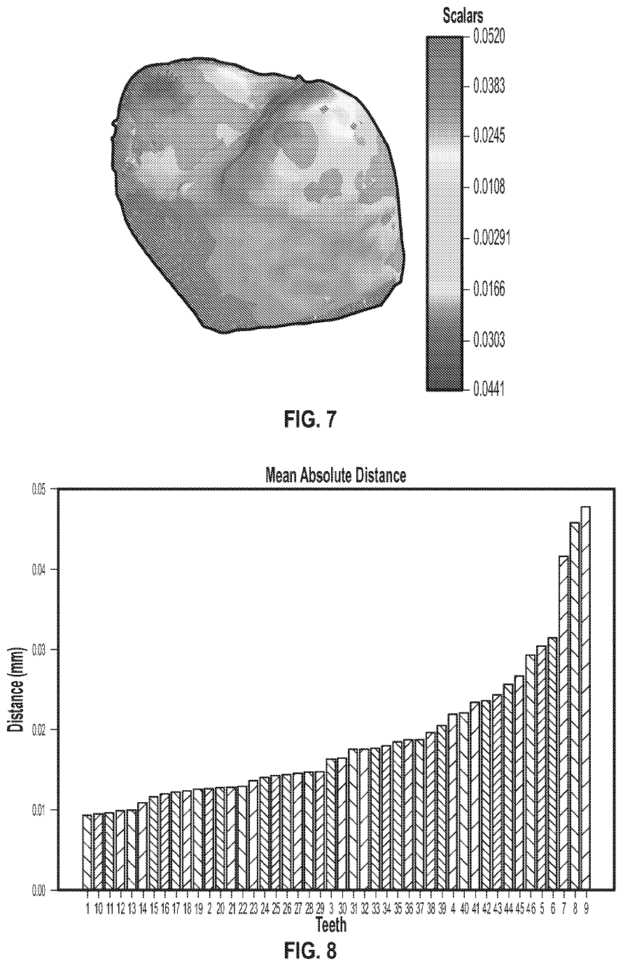

FIG. 7 shows a depiction of the reconstruction error from the reconstructed tooth shown in FIG. 6, called a reconstruction error plot. That is, FIG. 7 shows reconstruction error in the above results, in a form referred to as a “reconstruction error plot.” Units are in millimeters (mm) in FIG. 7. Notice that the reconstruction error is less than 50 microns at the cusp tips, and much less than 50 microns over most of the tooth surface. Compared to a typical tooth with a size of 1.0 cm, an error rate of 50 microns (or less) means that the tooth surface was reconstructed with an error rate of less than 0.5%.

FIG. 8 is a histogram in which each bar or bin represents an individual tooth and represents the mean absolute distance of all vertices involved in the reconstruction of that tooth in a data that was used to evaluate a mesh reconstruction model.

The tooth mesh reconstruction autoencoder, of which a variational autoencoder (VAE) is an example, may be trained to encode a tooth as a reduced-dimensionality form, called a latent space vector. The reconstruction VAE may be trained on example tooth meshes. The tooth mesh may be received by the VAE, deconstructed into a latent space vector using a 3D encoder and then reconstructed into a facsimile of the input mesh using a 3D decoder. Existing techniques for setups prediction lack such a deconstruction/reconstruction method. One advantage of this method is that the encoder E1 may become trained to encode a tooth mesh (or mesh of a dental appliance, gums, or other body part or anatomy) into a reduced-dimension form that can be used in the training and deployment of any of suite of powerful setups prediction methods (e.g., GDL Setups, RL Setups, VAE Setups, Capsule Setups, MLP Setups and Diffusion Setups, among others). This reduced-dimensionality form of the tooth may enable the setups prediction neural network to more efficiently encode the reconstruction characteristics of the tooth, and better learn to place the tooth into a pose suitable for either final setups or intermediate stages, thereby providing technical improvements in terms of both data precision and resource footprint.

The reconstructed mesh may be compared to the input mesh, for example using a reconstruction error (as described elsewhere in this disclosure), which quantifies the differences between the meshes. This reconstruction error may be computed using Euclidean distances between corresponding mesh elements between the two meshes. There are other methods of computing this error too which may be derived from material described elsewhere in this disclosure. FIGS. 7 and 8 show example reconstruction errors, in accordance with the techniques described herein.

In some implementations, the mesh or meshes which are provided to the mesh reconstruction VAE may first be converted to vertex lists (or point clouds) before being provided to the encoder E1. This manner of handling the input to E1 may be conducive to either a single mesh input (such as in a tooth mesh classification task) or a set of multiple teeth (such as in the setups classification task). The input meshes do not need to be connected.

The encoder E1 may be trained to encode a tooth mesh into a latent space vector A (or “tooth representation vector”). In the course of the restoration design task, encoder E1 may arrange an input tooth mesh into a mesh element vector F, and encode it into a latent space vector A. This latent space vector A may be a reduced dimensionality representation of F that describes the important geometrical attributes of F. Latent space vector A may be provided to the decoder D1 to be restored to full resolution or near full resolution, along with the desired geometrical changes. The restored full resolution mesh or near-full resolution mesh may be described by G, which may then be arranged into the output mesh.

In some implementations, such as in restoration design generation, the tooth name, the tooth designation and/or tooth type R may be concatenated with the latent vector A, as a means of conditioning the VAE on such information, to improve the ability of the VAE to respond to specific tooth types or designations.

The performance of the mesh reconstruction VAE can be measured using reconstruction error calculations. In some examples, reconstruction error may be computed as element-to-element distances between two meshes, for example using Euclidean distances. Other distance measures are possible in accordance with various implementations of the techniques of this disclosure, such as Cosine distance, Manhattan distance, Minkowski distance, Chebyshev distance, Jaccard distance (e.g. intersection over union of meshes), Haversine distance (e.g., distance across a surface), and Sorensen-Dice distance.

The performance of a mesh reconstruction VAE may, in some implementations, be verified via reconstruction error plots and/or other key performance indicators. The latent space vectors for one or more input tooth meshes may be plotted (e.g., in 2D) using UMAP or t-SNE dimensionality reduction techniques and compared, to select the best available separability between classes of tooth (molar, premolar, incisor, etc.), indicating that the model has an awareness of the strong geometric variation between classes, and a strong similarity within a class. This would be illustrated by clear, non-overlapping clusters in the resulting UMAP/t-SNE plots.

In some instances, the latent vector corresponding to a mesh may be used as a part of a classifier to classify that mesh. For example, classification may be performed to identify a tooth type or to detect errors in the mesh or an arrangement of meshes, such as in a validation operation). The latent vector and/or computed mesh element features (such as spatial and/or structural mesh features described herein) may be provide to a supervised machine learning model to classify the mesh. A non-exhaustive list of possible supervised ML models is found elsewhere in this disclosure.

In some implementations, a reconstruction VAE may be trained to reconstruct any arbitrary tooth type. In other implementations, a reconstruction VAE may be trained to reconstruct a specific tooth type (e.g., a first molar, or a central incisor).

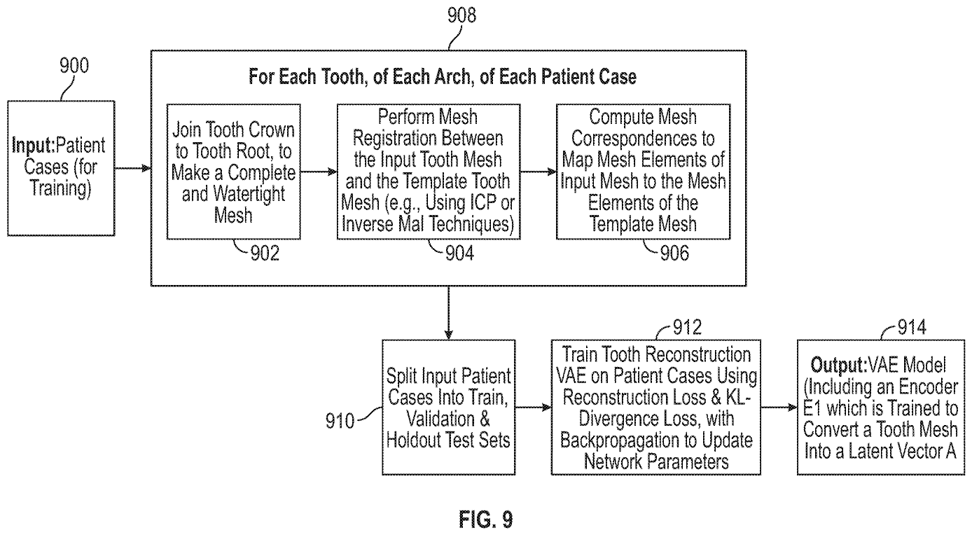

FIG. 9 describes the training of a mesh reconstruction VAE which, in some implementations, may be used to encode a tooth mesh (or other 3D oral care representation) into a latent representation (e.g., a latent vector) A. This VAE may also be trained to encode other kinds of 3D representations (e.g., meshes that describe gums, fixture model components, oral care hardware such as brackets and/or attachments, dental restoration appliance components, other portions of anatomy, or the like) into a latent vector A. In some implementations, the latent representation(s) may, in some implementations, be reconstructed using a decoder, which may generate reconstructed meshes (e.g., tooth meshes) or other reconstructed representations. The reconstructed meshes may contain filled-in material (e.g., gaps, holes or incomplete aspects may be filled-in with mesh elements). In some implementations, the latent representation(s) may be reconstructed, and a reconstruction error may subsequently be computed. When the reconstruction error for one or more aspects of the reconstructed mesh (e.g., the reconstruction error in proximity to one or more mesh elements) is beyond a threshold error, then the techniques may generate an indication that an anomaly has been detected. For example, when a tooth mesh contains hardware (e.g., a bracket), the mesh elements corresponding to that bracket may be flagged with a reconstruction error beyond a threshold. The techniques may generate an indication that hardware (or other anomalous material) was found to be attached to the tooth. The reconstruction error reflects how well the mesh has been reconstructed. When the reconstruction error is beyond a threshold, either one or both of the original and reconstructed meshes may be deemed defective. FIG. 9 provides further details on training a tooth crown reconstruction VAE.

FIG. 9 shows a method that systems of this disclosure may implement to train a reconstruction autoencoder for reconstructing a 3D representation of the patient's dentition. The particular example of FIG. 9 illustrates training of a variational autoencoder (VAE) for reconstructing a tooth mesh 900. For each tooth in a patient case 900 (908), the systems of this disclosure may generate a watertight mesh by merging the tooth's crown mesh with the corresponding root mesh such that the vertices on the open edge of the crown mesh match up with the vertices on the open edge of the root mesh (902). The systems of this disclosure may perform a registration step (904) to align a tooth mesh with a template tooth mesh (e.g., using the iterative closest point technique or by applying the inverse mal transform for that tooth), with the technical enhancement of improving the accuracy and data precision of the mesh correspondence computation at 906. The systems of this disclosure may compute correspondences between a tooth mesh and the corresponding template tooth mesh, with the technical improvement of conditioning the tooth mesh to be ready to be provided to the reconstruction autoencoder. The dataset of prepared tooth meshes are split into train, validation and holdout test sets (910), which are then used to train a reconstruction autoencoder (912), described herein as a tooth VAE, tooth reconstruction VAE or more generally as a reconstruction autoencoder. The tooth VAE may comprise a 3D encoder which encodes a tooth mesh into a latent form (e.g., a latent vector A), and a subsequent 3D decoder reconstructs that tooth into a facsimile of the inputted tooth mesh. The tooth VAE of this disclosure may be trained using a combination of reconstruction loss and KL-Divergence loss, and optionally other of the loss functions described herein. The output of this method is a trained tooth VAE 914.

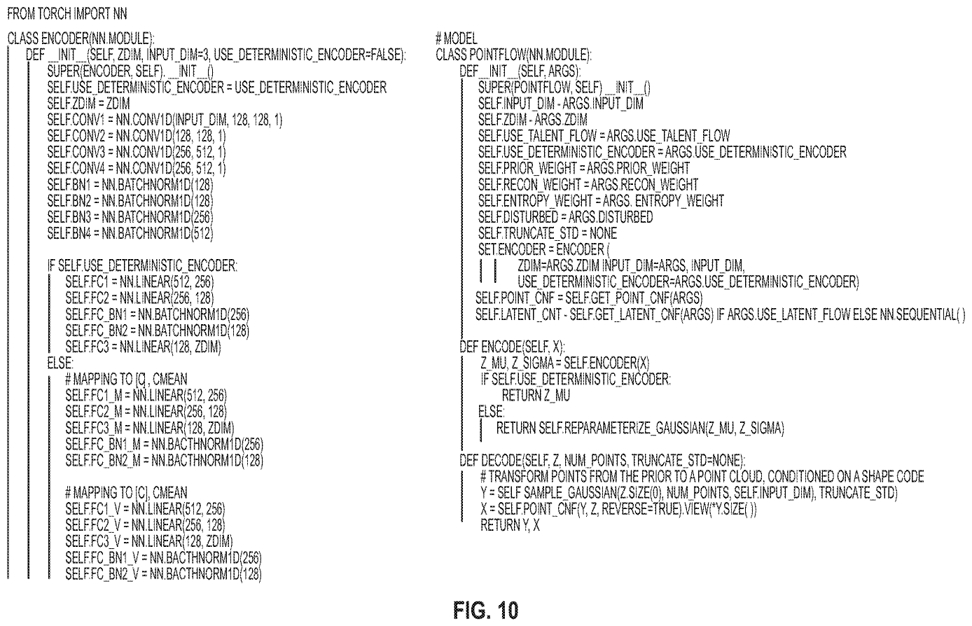

FIG. 10 shows non-limiting code implementing an example 3D encoder and an example 3D decoder for a mesh reconstruction VAE. FIG. 10 illustrates source code (in Python) corresponding to the encoder and the decoder. These implementations may include: convolution operations, batch norm operations, linear neural network layers, Gaussian operations, and continuous normalizing flows (CNF), among others.

One of the steps which may take place in the VAE training data pre-processing is the calculation of mesh correspondences. Correspondences may be computed between the mesh elements of the input mesh and the mesh elements of a reference or template mesh with known structure. The goal of mesh correspondence calculation may be to find matching points between the surfaces of an input mesh and of a template (reference) mesh. Mesh correspondence may generate point to point correspondences between input and template meshes by mapping each vertex from the input mesh to at least one vertex in the template mesh. Correspondences may be computed between the mesh elements of the input mesh and the mesh elements of a reference or template mesh with known structure. In one example, a range of entries in the vector may correspond to the mesial lingual cusp tip; another range of elements may correspond to the distal lingual cusp tip; another range of elements may correspond to the mesial surface of that tooth; another range of elements may correspond to the lingual surface of that tooth, and so on. In the case of a tooth mesh reconstruction autoencoder (such as a VAE), in some implementations, the autoencoder may be trained on just a subset of teeth (e.g., only molars or only upper left first molars). In other implementations, the autoencoder may be trained on a larger subset or all of the teeth in the mouth. In some implementations, an input vector may be provided to the autoencoder (e.g., a vector of flags) which may define or otherwise influence the autoencoder as to which type of tooth mesh may have been received by the autoencoder as input. A data precision improvement of this approach is to mesh correspondences in mesh reconstruction to reduce sampling error, improve alignment, and improve mesh generation quality. Further details on the use of mesh correspondences with the autoencoder models of this disclosure is found elsewhere in this disclosure.

In some implementations, an iterative closest point (ICP) algorithm may be run between the input tooth mesh and a template tooth mesh, during the computation of mesh correspondences. The correspondences may be computed to establish vertex-to-vertex relationships (between the input tooth mesh and the reconstructed tooth mesh), for use in computing reconstruction error.

In some implementations, an inverse mal transform may be applied to bring the input tooth mesh into at least approximate alignment with a template tooth mesh, during the computation of mesh correspondences. In some implementations, both ICP and an inverse mal transform may be applied.

According to particular implementations, training data may be generalized to one or more arches of teeth (e.g., among other 3D oral care representations) or may be more specific to particular teeth within an arch (e.g., among other 3D oral care representations). In situations in which more specific training data is leveraged, the specific training data can be presented as a tooth template. For instance, a tooth template may be specific to one or more tooth types (e.g., lower right central incisor). In some implementations, a tooth template may be generated which is an average of many examples of a certain type of tooth (such as an average of lower first molars). In some implementations, a tooth template may be generated which is an average of many examples of more than one tooth type (such as an average of first and second bicuspids from both upper and lower arches).

In some implementations, the pre-processing procedure may involve one or more of the following steps: generation of watertight meshes (e.g. making sure that the boundary of the root mesh seals cleanly against the boundary of the crown mesh), registration to align the tooth mesh with a template mesh (e.g., using either ICP or the inverse mal transform), and the computation of mesh correspondences (i.e., to generate mesh element-to-mesh element correspondences between the input tooth mesh and a template tooth mesh).

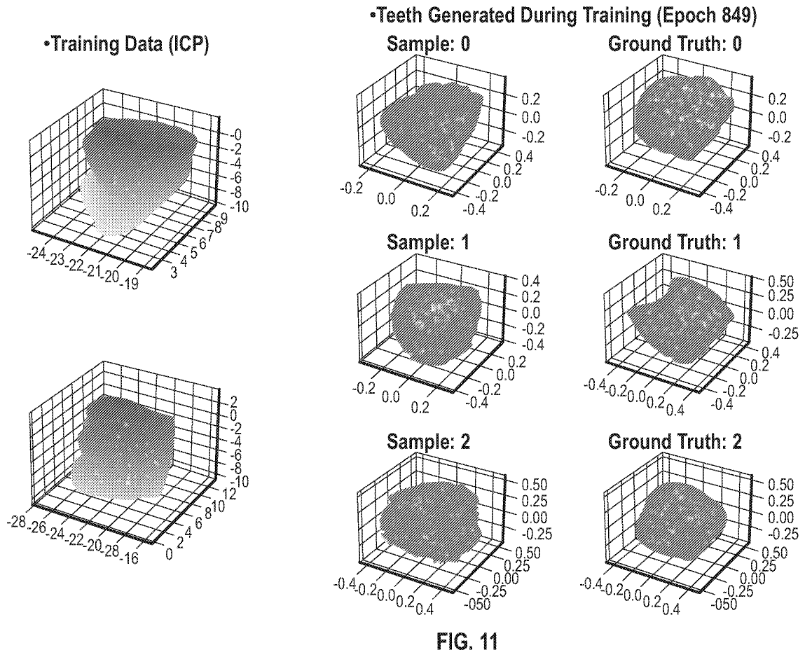

FIG. 11 illustrates tooth reconstructions generated after the 849th training epoch of a tooth reconstruction autoencoder. In FIG. 11, the left side (labelled as “Training Data (ICP)”) shows a tooth mesh (in the form of a 3D point cloud) after the completion of the pre-processing steps, where pre-processing used ICP to do the registration. The right side shows two things: the output of the tooth reconstruction VAE (in the left column) and the corresponding ground truth tooth 3D representation. In this instance as well, the 3D representation of each tooth is represented by a point cloud. This output was generated at epoch 849 of the reconstruction VAE training.

The above description deals primarily with the processing of mesh, point cloud and/or voxel data into latent space vectors, as a means for reducing the dimensionality of those data and strengthening the signal-to-noise ratio of those data, such that an ML classifier can make decisions based on those data. Applications include but are not limited to VAE Setups, MLP Setups, MAE Mesh In-Filling, VAE Mesh Element Labelling, VAE for Tooth Mesh Classification, and some examples of Setups Classification. A reconstruction autoencoder trained based on the above material is also relevant to validation operations, such as segmentation validation, coordinate system validation, mesh cleanup validation, restoration design validation, fixture model validation, clear tray aligner (CTA) trimline validation, setups validation, oral care appliance component validation (either or both of placement and generation), and hardware (bracket, attachment, etc.) placement validation, to name some examples.

Autoencoders of this disclosure (such as a VAE or capsule autoencoder) may process other types of oral care data, such as text data, categorical data, spatiotemporal data, real-time data and/or vectors of real numbers, such as may be found among the procedure parameters. Data may be qualitative or quantitative. Data may be nominal or ordinal. Data may be discrete or continuous. Data may be structured, unstructured or semi-structured. The autoencoders of this disclosure may also encode such data into latent space vectors (or latent capsules) for later reconstruction. Those latent vectors/latent capsules may be used for prediction and/or classification. The reconstructions may be used for model verification, and for validation applications, for example, through the calculation of reconstruction error and/or the labeling of data elements.

A latent vector A which may be generated by the encoder E1 in a fully trained mesh reconstruction autoencoder (e.g., for tooth meshes), may be a reduced-dimensionality representation of the input mesh (e.g., a tooth mesh). In some implementations, the latent vector A may be a vector of 128 real numbers (or some other size, such as 256 or 512). The decoder D1 of the fully trained mesh reconstruction autoencoder may be capable to take the latent vector A as input and reconstruct a close facsimile of the input tooth mesh, with low reconstruction error. In some implementations, modifications may be made to the latent vector A, so as to effect changes in the shape of the reconstructed mesh that is generated from the decoder D2. Such modifications may be made after first mapping-out the latent space, to gain insight into the effects of making particular change. There are a variety of loss functions which may be used in the training of E1 and D1, which may involve terms related to reconstruction loss and/or KL-Divergence between distributions (e.g., in some instances to minimize the distance between the latent space distribution and a multidimensional Gaussian distribution). One purpose of the reconstruction loss term is to compare the predicted reconstructed tooth 3D representation to the corresponding ground truth reconstructed tooth 3D representation. One purpose of the KL-divergence term is to make the latent space more Gaussian, and therefore improve the quality of reconstructed meshes (i.e., especially in the case where the latent space vector may be modified, to change the shape of the outputted mesh, for example to segment a 3D mesh, or to perform tooth design generation for use in generating a dental reconstruction appliance).

In some implementations, modifications may be made to the latent vector A so as to change the characteristics of the reconstructed mesh (such as with the generation of a dental restoration tooth design mesh). If the loss L is computed using only reconstruction loss, and changes are made to the latent vector A, then in some use case scenarios, the reconstructed mesh may reflect the expected form of output (e.g., be a recognizable tooth). In other use case scenarios however, the output of the reconstructed mesh may not conform to the expected form of output (e.g., not be a recognizable tooth).

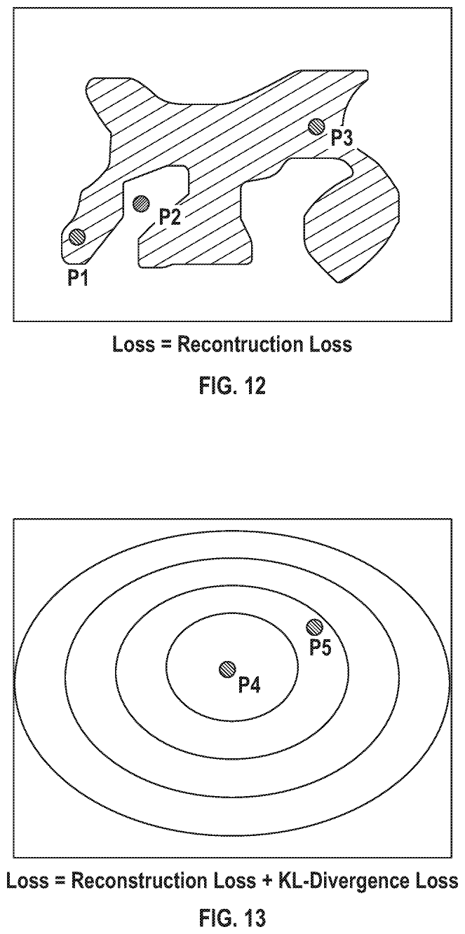

FIG. 12 illustrates a latent space where loss incorporates reconstruction loss but does not incorporate KL-Divergence loss. In FIG. 12, point P1 corresponds to the original form of a latent space vector A. Point P2 corresponds to a different location in the latent space, which may be sampled as a result of making modifications to the latent vector A, but where the mesh which is reconstructed from P2 may not give good output (e.g., does not look like a recognizable or otherwise suitable tooth). Point P3 corresponds to still a different location in the latent space, which may be sampled as a result of making a different set of modifications to the latent vector A, but where the mesh which is reconstructed from P3 may give good output (e.g., has the appearance of a tooth design which is suitable for use in generating a dental restoration appliance). In the case where loss involves only reconstruction loss, the subset of the latent space which can be sampled to produce a latent space vector P3 which yielding a valid reconstructed mesh may be irregular or hard to predict.

FIG. 13 illustrates an example of a latent space where loss includes both reconstruction loss and KL-divergence loss. A loss calculation may, in some implementations, incorporate a KL-divergence term. If the loss is improved by incorporating a KL-divergence term, the quality of the latent space may improve significantly. The latent space may become more Gaussian under this new scenario (as shown in FIG. 13), a latent supervector A corresponds to point P4 near the center of a multidimensional Gaussian curve. Changes may be made to the latent supervector A, yielding point P5 nearby P4, where the resulting reconstructed mesh is highly likely to reflect desired attributes (e.g., is highly likely to be a valid tooth). The introduction of the KL-divergence term to loss may make the process of modifying the latent space vector A and getting a valid reconstructed mesh more reliable. In some implementations, as with a capsule autoencoder, the latent vector may be replaced with a latent capsule, which may undergo modification and subsequently be reconstructed. This autoencoder framework may, in some implementations, be adapted to the segmentation of tooth meshes. Additionally, this autoencoder framework may, in some implementations, be adapted to the task of tooth coordinate system prediction. In some implementations, a mesh reconstruction autoencoder for coordinate system prediction may compress the tooth data into latent vector form, and then provide the latent vector as input to a second ML module (e.g., an MLP) which has been trained for coordinate system prediction (e.g., for coordinate system prediction on a mesh, with the goal of defining a local coordinate system for that mesh, such as a tooth mesh).

For a given domain (e.g., tooth restoration design generation, MAE tooth in-filling, or setups design, etc.), the latent space can be mapped-out, so that changes to the latent space vector A may lead to reasonably well reconstructed meshes. The latent space may be systematically mapped by generating latent vectors with carefully chosen variations in value (e.g., by experimenting with different combinations of 128 values in an example latent vector). In some instances, a grid search of values may be performed, with the advantage of efficiently exploring the latent space. With the latent space mapped-out, the shape of a mesh may be modified by nudging the values in one or more elements of the latent vector values towards the portion of the mapped out latent space which has been found to correspond to the desired tooth characteristics. The use of KL-divergence in the loss calculation increases the likelihood that the modified latent vector gets reconstructed into a valid example of the inputted 3D oral care representation (e.g., 3D mesh of a tooth).

In the case of restoration design generation, the mesh may correspond to at least some portion of a tooth. Changes may be made to a latent vector A, such that the resulting reconstructed tooth mesh may have characteristics which meet the specification set by the restoration design parameters. A neural network for tooth restoration design generation is described in US Provisional Application No. U.S. 63/366,514, the entire disclosure of which is incorporated herein by reference.

A tooth setup may be designed at least in part, by modifying a latent vector that corresponds to one or more teeth (e.g., each described as 3D point clouds, voxels or meshes) of an arch or arches which are to be placed in a setup configuration. This mesh may be encoded into a latent vector A which then undergoes modification to adjust the poses of the resulting tooth poses. The modified latent vector A′ may then be reconstructed into the mesh or meshes which describe the setup. Such a technique may be used to design a final setup configuration or an intermediate stage configuration, or the like.

The modifications to a latent vector may, in some implementations, be carried out via an ML model, such as one of the neural network models or other ML models disclosed elsewhere in this disclosure. In some implementations, a neural network may be trained to operate within the latent space of such vectors A of setups meshes. The mapping of the latent space of A may have been previously generated by making controlled adjustments to trial latent vectors and observing the resulting changes to a setups configuration (i.e., after the modified A has been reconstructed back into a full mesh or meshes of the dental arch). The mapping of the latent space may, in some instances, follow methodical search patterns, such as in a grid search.

In some implementations, a tooth reconstruction VAE may take a single input of tooth name/type/designation R, which may command the VAE to output a tooth mesh of the designated type. This can be accomplished by generating a latent vector A′ for use in reconstructing a suitable tooth mesh. In some implementations, this latent vector A′ may be sampled or generated “on the fly”, out of a prior mapping of the latent vector space. Such a mapping may have been performed to understand which portions of the latent vector space correspond to different shapes, structures and/or geometries of tooth. For example, out of the 128 real values in an example latent vector A′ (other sizes are possible), certain elements, and perhaps certain ranges of values for those vector elements may have been determined to correspond to a certain type/name/designation of tooth and/or a tooth with a certain shape or other intended characteristics. This model for tooth mesh generation may also apply to the generation of oral care hardware, appliances and appliance components (such as to be used for orthodontic treatment). This model may also be trained for the generation of other types of anatomy. This model may also be trained for the generation of other types on non-oral care meshes as well.

The mesh comparison module may compare two or more meshes, for example for the computation of a loss function or for the computation of a reconstruction error. Some implementations may involve a comparison of the volume and/or area of the two meshes. Some implementations may involve the computation of a minimum distance between corresponding vertices/faces/edges/voxels of two meshes. For a point in one mesh (vertex point, mid-point on edge, or triangle center, for example) compute the minimum distance between that point and the corresponding point in the other mesh. In the case that the other mesh has a different number of elements or there is otherwise no clear mapping between corresponding points for the two meshes, different approaches can be considered. For example, the open-source software packages CloudCompare and MeshLab each have mesh comparison tools which may play a role in the mesh comparison module for the present disclosure. In some implementations, a Hausdorff Distance may be computed to quantify the difference in shape between two meshes. The open-source software tool Metro, developed by the Visual Computing Lab, can also play a role in quantifying the difference between two meshes. The following paper describes the approach taken by Metro, which may be adapted by the neural networks applications of the present disclosure for use in mesh comparison and difference quantification: “Metro: measuring error on simplified surfaces” by P. Cignoni, C. Rocchini and R. Scopigno, Computer Graphics Forum, Blackwell Publishers, vol. 17(2), June 1998, pp 167-174.

Some techniques of this disclosure may incorporate the operation of, for one or more points on the first mesh, shooting a ray normal to the mesh surface and calculating the distance before that ray is incident upon the second mesh. The lengths of the resulting line segments may be used to quantify the distance between the meshes. According to some techniques of this disclosure, the distance may be assigned a color based on the magnitude of that distance and that color may be applied to the first mesh, by way of visualization.

Mesh element labelling techniques have several advantageous applications to the processing of 3D oral care representations (such as 3D oral care meshes), with the ultimate goal of creating oral care appliances. In particular mesh element labeling is advantageous to the segmentation of 3D oral care representations. Mesh element labeling is also advantageous to the task of 3D oral care mesh cleanup (3D representation cleanup), which may involve, in some implementations, the labeling of mesh elements, the removal of labeled mesh elements and the repair or filling-in of any resulting holes or rough boundaries. The following sections discuss mesh segmentation and mesh cleanup.

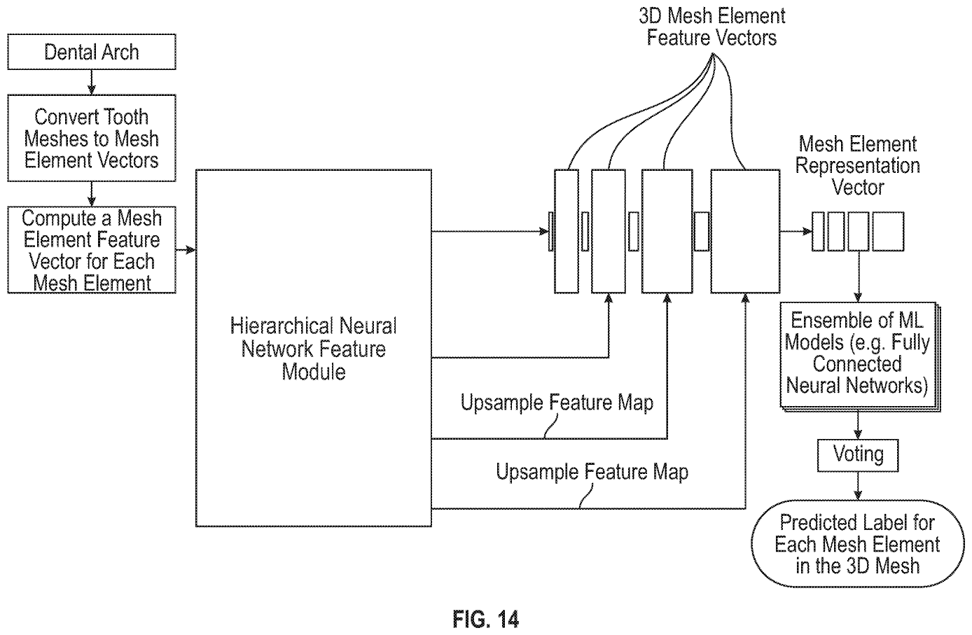

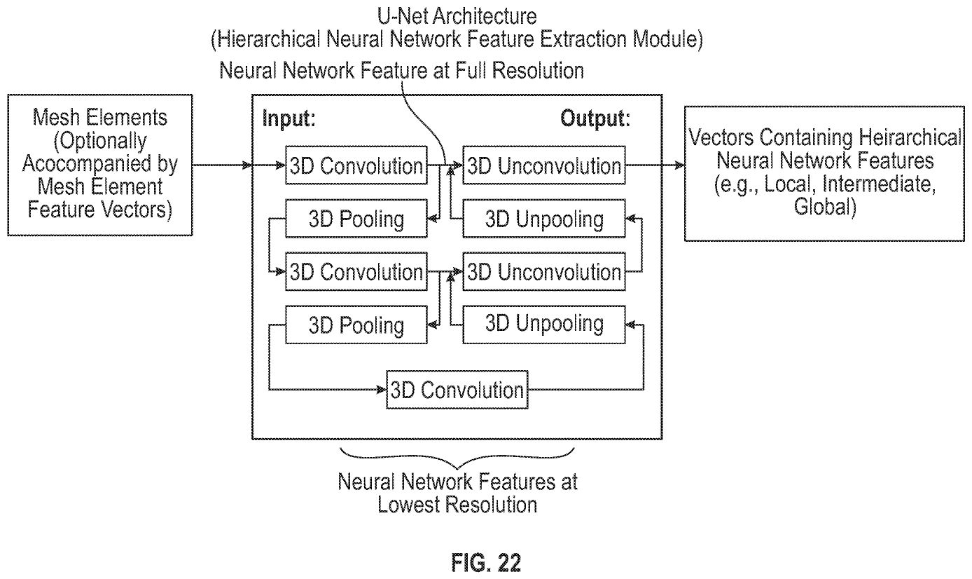

FIG. 14 illustrates an example of a mesh element labelling model which is based on denoising diffusion probabilistic models (DDPM) and which may be used to enable either of the 3D mesh segmentation (e.g., semantic segmentation) and 3D mesh cleanup methods. A DDPM for 3D representation segmentation may comprise at least one of a forward pass (e.g., which may involve many steps of adding iteratively more noise to an input 3D representation-which may be used in training an ML model to carry out the reverse process) and a reverse path (e.g., which may use an ML model, such as a neural network, to iteratively denoise a noisy representation, resulting in a segmentation of the input 3D representation). A DDPM for 3D representation segmentation may, in some implementations, approximate aspects of a Markov process. A U-Net (e.g., the U-Net shown as a part of the method in FIG. 22) may be trained to perform the reverse process, which may begin operations on a noisy representation and iteratively denoise that representation to produce a denoised representation which may comprise one or more mesh element labels (alternatively the noisy representation may be directly denoised into one or more segmented 3D representations, such as 3D point clouds or 3D meshes).

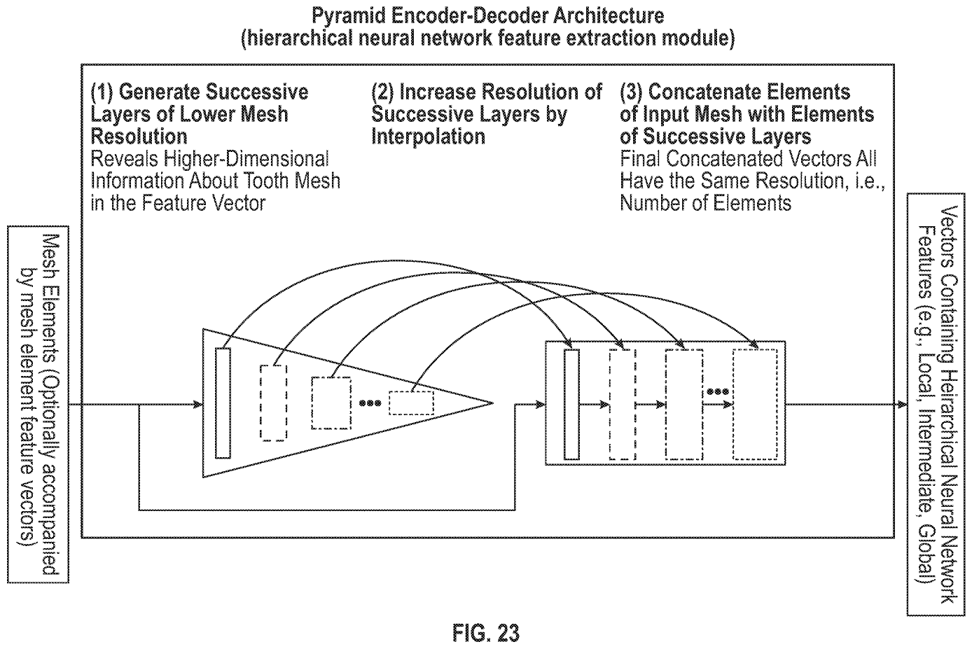

In some implementations, a DDPM for 3D representation segmentation may comprise the following steps: 1) Iteratively add noise (e.g., Gaussian noise) to an input 3D oral care representation, to produce a succession of increasingly noisy versions of that input 3D oral care representation which may then be used in training a denoising neural network of the reverse process. 2) Use the U-Net in FIG. 37 (U-shaped method of convolution/unconvolution and/or pooling/unpooling operations) to extract feature maps from the succession of increasingly noisy 3D oral care representations in setup #1. 3) Collect mesh element-level representations by upsampling the feature maps from the U-Net in step #2 and concatenating those upsampled feature maps. 4) The concatenated mesh element-level feature vectors from step #3 may be used to train one or more ML models for mesh element labeling (e.g., to train an ensemble of neural networks for mesh element labeling). The hierarchical neural network feature module (HNNFM) in FIG. 14 may contain one or more: U-Nets (see FIG. 22), pyramid encoder-decoder structures (see FIG. 23), or 3D SWIN transformers, among other architectures.

This section describes a method of segmenting a 3D oral care representation, such as a 3D oral care mesh. FIG. 14 pertains to 3D mesh segmentation and 3D mesh cleanup. Both of these techniques share an important attribute, the labelling of 3D mesh elements. In the case of 3D mesh segmentation (e.g., as pertaining to the segmentation of oral care meshes, such as teeth), the various mesh elements of the mesh may be labelled according to which portion of the dental anatomy the mesh elements belong (e.g., gums, upper right central incisor, lower left 2^{nd} bicuspid). Tooth mesh segmentation may label elements according to membership in the various teeth, as designated by one or more of the dental notation systems mentioned herein (e.g., Palmer). In some implementations, for facial-lingual segmentation, each of the mesh elements may be labelled according to membership in either the facial side of the arch or the lingual side of the arch. Other dental anatomy segmentation implementations are possible.

The pre-segmentation mesh (e.g., a dental arch produced by an intraoral scanner or CT scanner) may be received by the segmentation system. Mesh element feature vectors may be computed, one vector for each mesh element. One or more mesh element features from elsewhere in this disclosure may be used to form a feature vector for a mesh element. Mesh elements may comprise of edges, faces, vertices and voxels (or any combination thereof).

In some implementations, the lists of mesh element feature vectors may be provided to a neural network that refines the mesh element feature vectors, to extract local and global features from those feature vectors, such as the U-Net structure shown in FIG. 22. The U-Net may comprise of 3D mesh convolution and/or subsequent 3D mesh pooling operations, which may serve to reduce the resolution of the mesh and extract neural network features at increasingly global scales. After a succession of such operations, after the global-most neural network features have been extracted, there may be a succession of 3D mesh unpooling and 3D mesh unconvolution operations which return the mesh to the original scale. After the various levels of the U-Net structure have generated outputs, there may be scale-up and concatenation operations. F1, F2, F3 and F4 may be 3D mesh element-wise feature vectors which may have been scaled-up to the original mesh resolution. These feature vectors are concatenated and provided as inputs to one or more ML models for mesh element classification. Any of the supervised ML models disclosed elsewhere in this disclosure may be used for this classification, such as SVM and Logistic Regression. In some examples, an ensemble of ML classifiers may take the mesh element representation vectors as inputs and generate mesh element classification labels. In some implementations, an ensemble of fully connected neural networks may be used for such classification. In some cases, a multi-layer perceptron (MLP) may be used for this classification, comprising linear layers and associated ReLU activation functions (e.g., which have the advantage in that not all neurons fire at the same time-which enables a more tailored response to the inputs than activation functions which all fire for every evaluation) and batch normalization operations. Other activation functions are possible, such the activation functions mentioned elsewhere in this disclosure. Each of the ensemble of ML models may output a predicted class label for each mesh element. A voting mechanism may then be employed to combine these results and output a final class label prediction for each 3D mesh element. Some implementations may use a transformer to assist in applying labels to mesh elements.

The mesh cleanup and mesh segmentation implementations differ in the arrangement of the ground truth mesh element labels. In the case of tooth segmentation, ground truth data may be given for each arch mesh that is to be segmented (i.e., each of the teeth in the arch has its mesh elements labeled according to which tooth the mesh element belongs). In turn, such a loss can be computed for facial-lingual segmentation and/or for teeth-gums segmentation (as defined in US Provisional Application No. U.S. 63/366,490). Various of the loss functions of this disclosure may be used to compare the mesh element labels of the predicted segmentation to the ground truth segmentation. Cross-entropy loss is an exemplary choice of the several candidate loss functions for this comparison. Other possible losses are disclosed elsewhere in this disclosure. In the case of mesh cleanup, ground truth data may be given for each arch mesh that is to be cleaned up. For example, in the case of extraneous material removal, each mesh element corresponding to extraneous material in the arch may be labelled as such, and each mesh element that does not comprise of extraneous material (i.e., that is to be retained after mesh cleanup) is labelled as such. In the case of divot removal, each mesh element corresponding to a divot in the arch may be labelled as such, and each mesh element that does not comprise of a divot (i.e., that is to be retained after mesh cleanup) is labelled as such.

After the segmentation labels are applied, a process is executed to copy the mesh element of a particular label into a new mesh (aka tooth cutting), and the mesh is saved (e.g., to an electronic storage medium) for further processing. After the mesh cleanup labeling is completed, a process is executed to remove each designed mesh element from the mesh (e.g., using classical mesh processing techniques), and then a process may optionally be executed to fill-in any holes which may have been created by that process (e.g., using the technique described elsewhere in this disclosure which has been trained for mesh in-filling).

Mesh element labeling for mesh segmentation may also be accomplished using an autoencoder which has been trained for the purpose, such as a variational autoencoder, as described elsewhere in this disclosure.

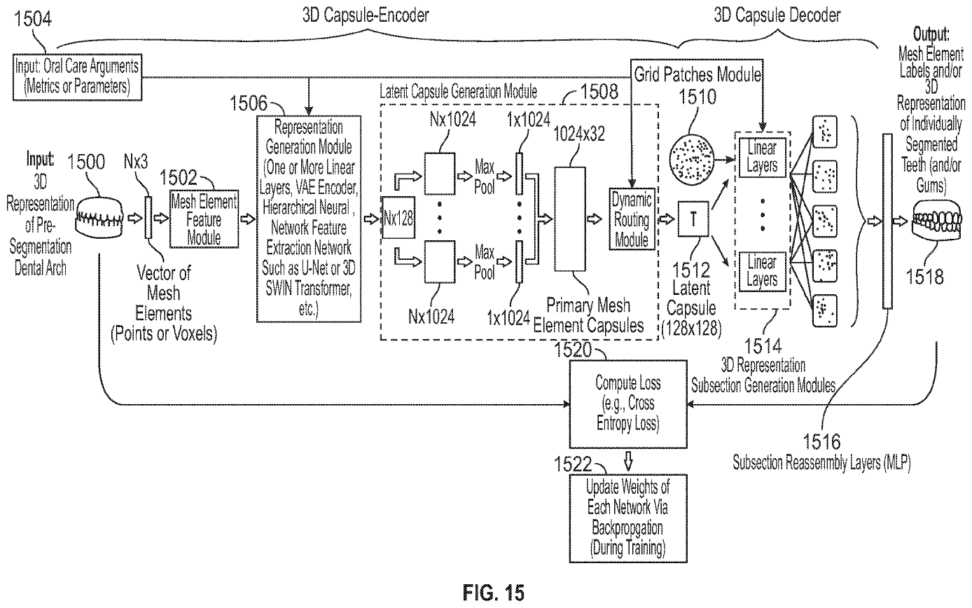

This portion of the disclosure describes a method of segmenting a 3D oral care representation, such as a 3D oral care mesh. FIG. 15 illustrates an example training method for a capsule autoencoder for 3D representation segmentation (e.g., segmenting 3D meshes). Oral care arguments 1504 may be provided to influence the functioning of the segmentation method, including: 1) minimum triangle area threshold, 2) max/min angle between adjacent faces, 3) smoothness argument to influence mesh element size, and the like. The pre-segmentation 3D representation 1500 (e.g., 3D meshes) may be arranged into vectors of mesh elements, which may be provided to a mesh element feature module 1502. The mesh elements (along with optional mesh element feature vectors) may be provided to a representation generation module 1506, which may in some implementations, compute hierarchical neural network features for the 3D representation(s). The generated latent representations may be provided to a latent capsule generation module 1508, which may assemble a latent capsule 1512 from the one or more latent vectors. The latent capsule may be provided to one or more 3D representation subsection generation modules 1514, which may be trained to generate mesh element labels for respective sections of the 3D representation, with the aid of the grid patches module 1510. The subsections may be provided to one or more subsection reassembly layers 1516, which may generate the final mesh element labels for the 3D representation (or the final segmented 3D representations of teeth) 1518.

3D representation segmentation may be implemented using a capsule autoencoder which has been trained for segmentation, such as the method shown in FIG. 15. Loss may be computed (1520) to compare a predicted segmentation (e.g., mesh element labels or individually segmented tooth meshes) to a corresponding ground truth segmentation. Cross entropy loss may, in some implementations, be computed, and the networks may be updated by backpropagation (1522). Other losses described herein may be used for training. The techniques of the present disclosure may train and use a capsule autoencoder to segment oral care meshes (such as raw unsegmented 3D mesh data of dental arches that is outputted from an intraoral scanner). This segmentation may be implemented by capsule association, which may leverage dynamic routing, where each latent capsule may be trained to recognize a sub-portion of the 3D representation, and a final sub-section reassembly layer(s) 1516 (e.g., one or more fully connected layers with optional skip connections, one or more transformer encoders, or one or more transformer decoders, etc.) may organize these sub-portions into whole segmented collections of mesh elements. Each capsule may correspond to a portion of the tooth arch mesh (alternatively to a portion of the tooth arch point cloud). Each capsule may have an associated label and may apply that label to certain collections of mesh elements. Such a capsule autoencoder (such as the 3D-PointCapsNet network) may be trained on examples of patient case data where the raw unsegmented 3D mesh data of dental arches may be available and ground truth segmentations of those same data may also be available. Other kinds of oral care meshes may be segmented too. In some instances, transfer learning techniques may be applied to aid the training process and transfer the encoding from other prior neural networks into the new neural network which may be the subject of training. Using the present technique, oral care meshes may be segmented on a per-capsule segmentation. Possible segmentation approaches include but are not limited to: tooth segmentation, facial lingual segmentation, teeth-gums segmentation. SegCaps networks may, in some implementations, aid in this 3D representation segmentation method.

The capsule-encoder (of the first part of the method) may encode the pre-segmentation mesh into one or more latent capsules. A latent capsule may, in some implementations, be a data structure of at least two dimensions, whereas, in some implementations, the latent vector A may be 1D. The capsule-decoder may reconstruct these latent capsules into a facsimile of the input 3D mesh (i.e., or other 3D representation), where sub-portions or the 3D mesh may be segmented (or labeled). For example, different groups of mesh elements may be labeled according to membership in different anatomical portions of the teeth and/or gums. The sub-section reassembly layer(s) 1516 (which may be an MLP) may merge these labeled groupings of mesh elements into larger, cohesive groupings of mesh elements which may correspond to teeth and/or gums. The sub-section reassembly layer 1516 may bring these smaller portions of the 3D mesh together into labeled groupings. Once the mesh elements for each tooth may have been labeled, tooth cutting may be performed (according to US Provisional Application No. U.S. 63/366,490) and the segmented tooth meshes may be outputted for later processing and use.

Capsules may be randomly initialized by sampling randomly from the Grid Patches Module. As training of the segmentation implementation proceeds, these randomly initialized capsules may become specialized to certain kinds of structures and/or shapes in the oral care meshes of the training dataset. In the case of tooth segmentation, capsules may become specialized to such 3D oral care representation fragments as cusp tips, occlusal surfaces, lingual surfaces, incisal edges, gingival margins, gingival surfaces, mesial (or distal) tooth surfaces), tooth surfaces with low curvature, tooth surfaces with high curvature, convex tooth surfaces, concave tooth surfaces, and the like.

At the end of the method in FIG. 15, there may one or more layers which may have been trained to combine capsules into larger 3D oral care representation parts (such as fragments of tooth crowns or whole tooth crowns). These ending layers are called sub-section reassembly layers 1516. These sub-section reassembly layers 1516 may, in some implementations, use only a fraction of the training data that was used to train the rest of the capsule autoencoder. The sub-section reassembly layers 1516 may provide the mesh element results of one or more capsules (i.e., point/vertex clouds, edges, faces or voxels), and combine those mesh elements into meaningful and/or recognizable parts (such as a tooth crown or gums). In this fashion, the trained capsule autoencoder may be specialized to perform segmentation of 3D representations (e.g., point clouds, meshes, voxelized representations, etc.). The training of the sub-section reassembly layers 1516 may use cross entropy loss and backpropagation, for example. Other losses described herein are possible. Intersection over union (IOU) accuracy is one metric that may be used to measure the accuracy of the resulting segmentation. IOU may be defined as the overlapping mesh area of the predicted and ground truth meshes, divided by the overall combined area of the two meshes.

This disclosure describes advantageous and new techniques for mesh processing in Digital Oral Care using geometric deep learning (GDL) models which have been trained on oral care meshes. 3D meshes of teeth (e.g., those produced by an intraoral scanner or by scanning a 3D representation of teeth, for example, a fixture model) may be processed in the course of creating dental and orthodontic appliances. An important step in that processing involves the removal of anomalous material from the meshes, an activity called mesh cleanup, where errors or non-standard aspects of a tooth mesh (or meshes) may be corrected, in preparation for later processing and appliance creation.

A 3D representation may comprise of a 3D mesh, 3D point cloud or 3D voxelized representation. Furthermore, the term mesh should be considered in a non-limiting sense to be inclusive of 3D mesh, 3D point cloud and 3D voxelized representations.

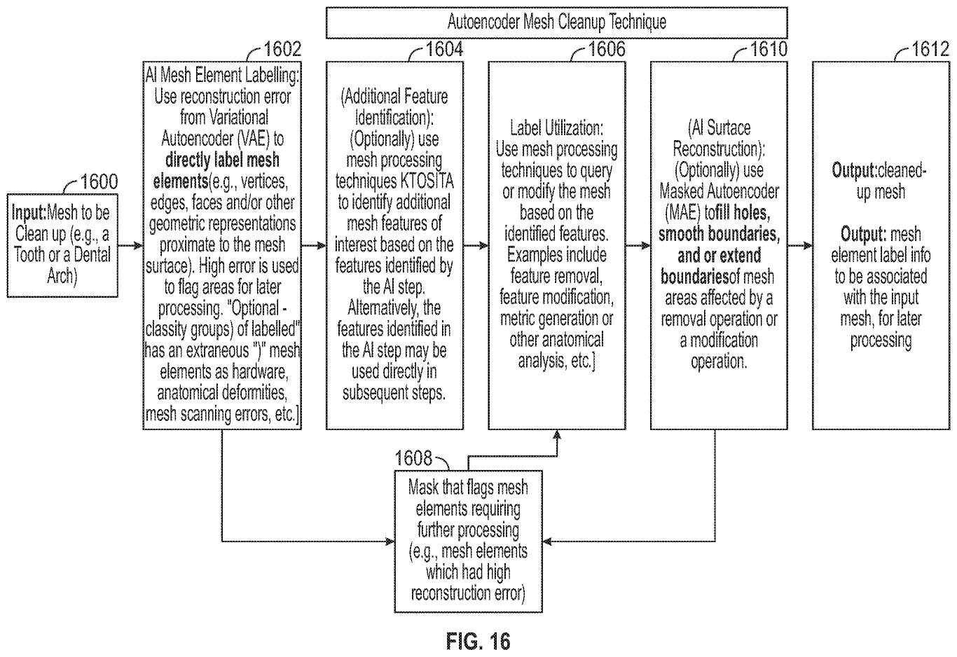

This disclosure features two related and advantageous techniques which may use autoencoders to perform steps in a mesh cleanup method. The first technique may use an autoencoder for labelling mesh elements (e.g., mesh elements which are to be removed). This first technique may be performed for anomaly detection, such as the detection of oral care hardware on a tooth. The second technique may use an autoencoder for reconstructing missing portions of a mesh (e.g., to fill-in the hole left after the removal of mesh elements). Some implementations of the first technique may use a variational autoencoder (VAE). Some implementations of the second technique may use a masked autoencoder (MAE). FIG. 16 shows how these two techniques may be used in concert. The first and second techniques may also incorporate other types of unsupervised machine learning models, such as the examples described elsewhere in this disclosure.

FIG. 16 illustrates an example of mesh cleanup using autoencoders. One or more meshes 1600 which may require modification (or “cleanup”) a received as input to a neural network which has been trained for mesh element labeling (1602). A mesh reconstruction autoencoder may be trained, according to the techniques of this disclosure, to label mesh elements which are anomalous and require modification or removal. Such a reconstruction autoencoder (e.g., comprising a 3D encoder followed by a 3D decoder) may be trained to encode the received mesh(es) 1600 into a latent form and then reconstruct into a reconstructed mesh, where reconstruction error is computed over various aspects of the reconstructed mesh (e.g., to compare those aspects, such as mesh elements, to the input mesh), thereby flagging aspects of the reconstructed mesh which deviate from the input mesh by more than a threshold. Optional mesh processing techniques (1604) which are known to one skilled in the art (KTOSITA) may then be used to identify any additional aspects (e.g., mesh elements) of the input mesh requiring modification or removal. A mask 1608 which flags aspects of mesh(es) 1600 which require further processing may be produced by the mesh element labeling method 1602. Mesh processing techniques (1606) may be applied to modify mesh(es) 1600, in some instances utilizing mask 1608. In some implementations, a masked autoencoder (which has been trained according to the description contained herein) may be used (1610) to fill holes, smooth boundaries and/or generally repair damage sustained by the mesh by the operations (1606). The resulting cleaned up mesh 1612 is outputted for further processing (e.g., for oral care appliance generation).

Correspondences between features are often useful in data analytics applications where identifying similar features is helpful. The calculation of correspondences is frequently done in Computer Vision, particularly for object tracking, but also for other applications. The use of correspondences enables data such as 3D data to be ordered in a more structured format, enabling similar parts of one 3D representation Mesh1 to be compared more easily to the corresponding parts of another 3D representation Mesh2, for example, by a neural network. When a neural network is consuming and making sense of input data, depending on the network architecture used, it can be beneficial to place all of the mesh data in order, as the network can focus more on the data structure without needing to compare every part of the data with every other possible part of the data. Instead, the neural network (or other ML model) can observe how similar parts of the data change relative to each other, and in this process learn what the typical variations in the data are. In this case, ordering of similar features helps advance the learning process.

The first part of this process is the identification of corresponding similar features in each data sample (e.g., each tooth within an arch, or each example of the same tooth type within a larger dataset). These corresponding features might be the mesh elements representing all distal incisal edges, or canine cusps, for example. Typically, neural networks take an ordered vector of features as input. As a 3D structure is an object composed of unordered elements or features, it can be difficult to structure this data in such a way that neural networks can easily make sense of the data. By performing a correspondence computation on these features as a preprocessing step, the techniques of this disclosure can then arrange the input vector for our network in such a way that all similar features (e.g., incisal edges or cusps) appear at the same location in the input vector regardless of what data sample (e.g., tooth) they came from.

This preprocessing may also have the advantage of reducing the complexity of the neural network, as the preprocessing has less work to do to make some initial sense of the data.

Among the various advantages of the VAE architecture is the fact that VAEs may be stable to train. VAEs do not suffer from negatives such as mode collapse. VAEs may build the latent representation of the data using a plurality of data samples. This may force the model to take into account various modes of the data, thus avoiding mode collapse.

KL divergence loss may cause data to take on at least some characteristics of Gaussian behavior when rendered in a latent form. The KL Divergence term of the model may encourage the distribution of one or more elements of the latent vector to be Gaussian and may penalize the model (via this KL Divergence loss) for any deviations from a Gaussian distribution.

Autoencoders may, in some implementations, be trained on unlabeled datasets in an unsupervised fashion. This feature may enable the vast quantities of unlabeled data to be used for training, without the need for expensive and sometimes inaccurate labelling, enabling a more robust resulting trained neural network model due to the larger datasets which may be used for model training.

The mesh element labelling method 1602 of FIG. 16 shows a variational autoencoder (VAE) which may be trained for mesh element labeling using, at least in part, examples of 3D meshes which have had ground truth mesh element labels associated with the mesh elements of the 3D meshes. Such an autoencoder may be used, for example, for anomaly detection. The VAE may generate mesh element labels for one or more mesh elements of a 3D representation, enabling that 3D representation to undergo, for example, mesh segmentation or mesh cleanup.

In some implementations, these mesh element labels may be used for 3D mesh segmentation (such as with tooth segmentation, facial lingual segmentation and teeth-gums segmentation). In some implementations, an autoencoder may be used for 3D mesh segmentation. In some implementations, a variational autoencoder may be used to encode 3D mesh data into a latent space vector which may contain mesh element-level latent features. In some implementations, a GAN Inversion operation (particularly one with semantic-aware properties) may be performed on the embedding vector(s) produced by a 3D segmentation U-Net structure, to obtain mesh-element level latent features (or properties). Such mesh-element level latent features (e.g., neural network features) may be provided to an ML model for labelling or classifying mesh elements, such as in FIG. 14. In some implementations, a 3D denoising diffusion probabilistic model (DDPM), a 3D adaptation of Swapping Assignments between multiple Views (SwAV) or a 3D masked autoencoder (MAE) may be used for 3D mesh segmentation. 3D mesh segmentation may in some implementations, be accomplished through the manipulation of a latent vector A. The full pre-segmentation mesh may be provided to an encoder E1, yielding a latent vector A. This latent vector A may be edited to isolate one or more teeth (in the case of tooth segmentation). Portions of the arch which do not correspond to that tooth or teeth may be removed from the mesh via these latent vector edits. The modified latent vector may then be reconstructed into one or more meshes, yielding the segmented tooth or teeth as output.

In some implementations, these mesh element labels may be used for anomaly detection, as a part of a mesh cleanup operation. A variational autoencoder may be trained to serve as an anomaly detection autoencoder, which detects anomalies by labelling mesh elements. The anomalous mesh elements may be identified by identifying the mesh elements which have a reconstruction error which is above a threshold. The reconstruction error may be computed as the result of executing a variational autoencoder (VAE) on an input mesh. Although this implementation describes the use of a VAE, it should be understood that, without the loss of generality, other types of autoencoders may be substituted for the VAE (e.g., capsule autoencoders, and/or stacked autoencoders). A mesh may be provided to a VAE, which may decompose that mesh into a latent space vector through the execution of an encoder structure. The latent space vector may correspond, at least in part, to a lower-dimensional representation of the input mesh. The VAE may then restore this lower-dimensional representation of the mesh into a higher-dimensional (or original dimension) representation of the mesh through the execution of a decoder structure. The encoder and decoder structures of the VAE may be trained on a dataset of accurately segmented tooth meshes, such that the encoder and decoder may become adept at decomposing and subsequently reconstructing pristine tooth meshes. If after deployment of the VAE, a tooth mesh is input to the VAE which is not pristine (i.e., contains an anomaly, such as a bracket, attachment or other piece of oral care hardware), then the VAE may struggle to reconstruct the tooth mesh (e.g., the VAE may not accurately reconstruct mesh elements in proximity to the anomalous object). Because the encoder and/or decoder were not trained to deconstruct and/or reconstruct the hardware (or other anomaly, such as extraneous material, divot, undercut, abfraction or lingual bar), then the reconstructed tooth mesh may not closely resemble the input tooth mesh (at least at the localized area of the anomalous object). The resemblance between input and reconstructed tooth meshes may be measured using reconstruction error. Reconstruction error may be computed by a number of means including but not limited to the Euclidean distance between vertex A in the input mesh and the corresponding vertex in the reconstructed mesh, or the closest point of the input mesh to the surface of the reconstructed mesh. Each mesh element in the input mesh may get assigned a reconstruction error. A mesh element with a reconstruction error above a designated threshold (e.g., 50 μm, 100 μm or some similar measurement, according to the needs of various applications) may be considered to be poorly reconstructed, and therefore labelled as anomalous. Otherwise, the mesh element is labelled as not anomalous. In some implementations, the labels for one or more mesh elements may be provided to a mesh classifier ML model, which may classify the mesh based, at least in part, on the one or more mesh element labels. The mesh classifier ML model may, in some implementations, identify the type or classification of a detected anomaly. Such a mesh classifier may, for example, consist of an encoder structure, a U-Net such as that implemented by the MinkowskiEngine toolkit, a U-Net such as one using MeshCNN features, or a Primal-Dual Mesh Convolutional Network as developed by MIT/UTH Zurich. A mask or vector of mesh element labels may be generated by the “AI Mesh Element Labelling” module. This mask may be used by latter modules to designate mesh elements which may benefit from further processing. Some implementations may employ a decision tree model (or other ML model disclosed herein) to choose which further processing step or steps to execute on a tooth mesh or meshes. Other applicable classifiers are disclosed elsewhere in this disclosure.

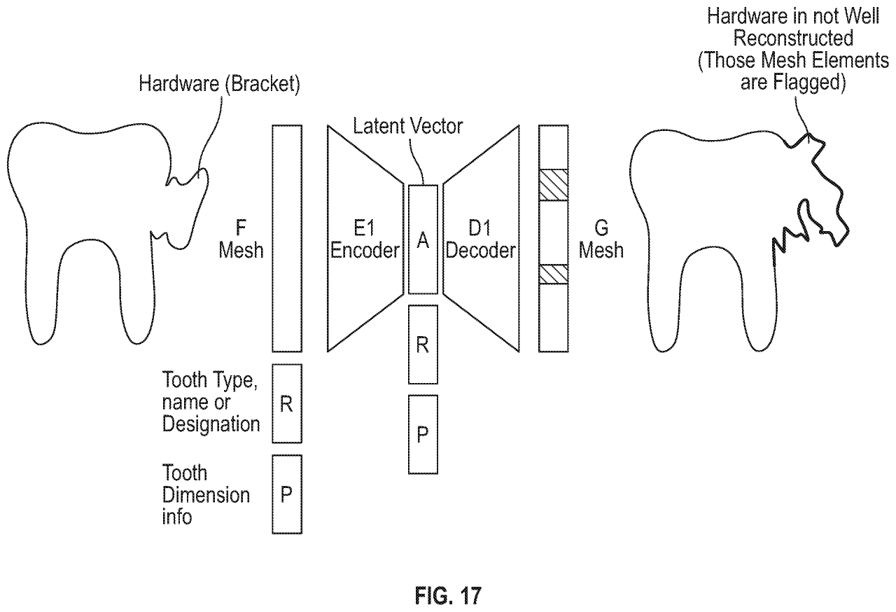

FIG. 17 shows an example implementation of the VAE for tooth mesh reconstruction, where a pristine tooth mesh has been reconstructed by the VAE. FIG. 17 shows an example implementation of the VAE for tooth mesh reconstruction, where the VAE has attempted to reconstruct an anomalous tooth mesh (i.e., a tooth mesh with an attached orthodontic bracket). The autoencoder of FIG. 17 is trained for mesh element anomaly detection. In this example, the autoencoder reconstructs the mesh elements of the tooth mesh with relatively low reconstruction error but struggles to reconstruct the mesh elements of the attached orthodontic bracket (i.e., the mesh elements corresponding to the bracket are reconstructed with high reconstruction error). The tooth mesh elements corresponding to the bracket are labelled as anomalous. A mask may be generated by the VAE which flags these anomalous tooth mesh elements.

In some implementations, the nature of the anomalous material may be determined. For example, some portion of the input tooth mesh may be isolated (e.g., by eliminating the well-reconstructed portions). The remaining portion of the input tooth mesh may represent the portion which did not become well-reconstructed in this example. Such a portion may be provided to a mesh classifier to identify the nature of the anomaly (e.g., to determine that the anomaly is a bracket, or the like).

In some implementations, the Autoencoder for Mesh Element Labeling technique (e.g., VAE for mesh element labeling) may be conditioned on optional inputs elsewhere in this disclosure, such as a vector P containing to tooth dimension information, one or more latent vectors B, and/or information R relating to tooth name, designation, tooth type and/or tooth classification. The model may be conditioned on such optional inputs by concatenating such inputs with the one or more input vectors (i.e., input to the encoder) and/or by concatenating such inputs with one or more latent vectors which are generated by the encoder in the Autoencoder for Mesh Element Labeling (VAE for mesh element labeling).

The VAE model may be trained using examples of pristine tooth meshes (i.e., tooth meshes which are free of foreign objects, hardware, extraneous material, divots, undercuts, abfractions, lingual bars or other non-pristine geometrical features). In some implementations, a VAE may be trained using examples of a single tooth designation, for example a lower right central incisor. The resulting VAE may then be deployed for use in labeling mesh elements in lower right central incisors. In some implementations, a VAE could be trained on pristine examples of a subset of teeth, for example, the incisors and cuspids. The resulting VAE may then be deployed exclusively for use in labeling mesh elements in incisors and cuspids. In some implementations, a VAE may be trained on just molars, or on the full set of teeth. The key is that the training dataset be free of anomalies, so that the resulting deployed VAE may be unable to accurately reconstruct such anomalies when those anomalies are encountered in deployment. The inaccurately reconstructed anomaly structures (i.e., the mesh elements of those structures) may then identified through the calculation of reconstruction error and/or flagged for further processing. There are other techniques which may benefit from a tooth reconstruction autoencoder to trained on a single tooth type (or otherwise a subset of tooth types), such as the MLP Setups and VAE Setups techniques. Such techniques may benefit from the training of a tooth reconstruction autoencoder on one or a small number of tooth types, because the resulting latent vector (or latent capsule) may have an improved ability to represent the inputted 3D representation. The resulting latent vector or latent capsule may be more advantageous for use in training a setups prediction ML model, due to increased accuracy of tooth representation.

Similar to the VAE for Mesh Element Labeling, a capsule autoencoder may be trained to use a capsule-encoder structure to encode a mesh (or other 3D representation) as one or more latent capsules, and then use a capsule-decoder structure to reconstruct the one or more latent capsules into a facsimile of the input mesh (or other input 3D representation). Such an autoencoder may be trained to encode and reconstruct typical (or nominal oral care meshes) (e.g., typical or healthy tooth crown meshes). When in deployment, an atypical mesh (or other 3D representation) is provided to the autoencoder, the autoencoder may reconstruct a mesh which differs from the input mesh in certain ways, thereby flagging the atypical nature of the input mesh. In the instance that the input mesh is an oral care mesh with attached hardware (such as a crown with an orthodontic bracket attached), the capsule autoencoder may reconstruct a mesh where the mesh elements corresponding to the bracket are not well formed and/or do not resemble the bracket. In such a case, the reconstruction error may be computed between the input and reconstructed meshes, and may reveal which mesh elements are not well reconstructed. These mesh elements may be flagged or labelled as anomalous, and in need of further processing, such as to have the anomalous mesh elements removed and the resulting hole(s) filled-in, similarly to the VAE applications for hardware removal. In some implementations, the anomalous portion of the mesh may be provided to a mesh classification neural network, which may classify the nature of the anomaly based, at least in part, on the shape and/or structure of the anomalous portion of the mesh. In some implementations, one or more mesh element labels may be provided to a mesh classification neural network, to aide that neural network in the classification of the anomaly.

The surface reconstruction method 1610 of FIG. 16 describes an autoencoder which may perform mesh surface reconstruction. In some examples, mesh surface reconstruction may be beneficial after labeled mesh elements have been removed from the mesh (e.g., mesh elements corresponding to hardware, or mesh elements corresponding to other mesh anomalies, such as extraneous material, divots, undercuts, abfractions or lingual bars). In some examples, input mesh data, such as tooth crowns, may be incomplete because adjacent teeth, hardware or other objects were in the way of the intraoral scanner at the time of data collection. In some implementations, surface reconstruction may involve the filling-in or imputation of missing mesh elements. Techniques of this disclosure may train and deploy a masked autoencoder to perform such in-filling or imputation tasks.

A region of masked mesh elements may be defined for two or more contiguous mesh elements. According to various implementations, the mask may contain one or more regions of masked mesh elements. In some examples, a mesh element such as a vertex in a mesh or a point in a point cloud may be masked. Masking may, in some implementations, involve overwriting one or more of the mesh element feature vector values associated with a mesh element (e.g., overwrite the XYZ coordinates of a mesh element) with a masking token. A masked autoencoder may be trained to consume these masked mesh elements (e.g., vertices whose XYZ coordinates have been overwritten by the masking token value) and reconstruct the missing coordinate data. The autoencoder may have information indicating that a masked mesh element is a part of the mesh and information indicating which mesh elements are neighbors (e.g., connectivity information is preserved). However, the autoencoder is denied knowledge of the XYZ coordinates of the mesh element's location (or is denied knowledge of other mesh element features) by the masking token values.

The autoencoder may be trained to reconstruct the input mesh in a manner that fills in or imputes missing portions of the input mesh, according to the distribution of mesh examples in the training dataset. In an example, a masked reconstruction autoencoder may be trained to reconstruct lower right central incisors, based on a dataset of thousands of lower right central incisors, where a stochastically generated mask is applied to one or more of those training examples. The mask applies the masking token to aspects of a training example (e.g., overwrites the XYZ coordinates of one or more mesh elements with the masking token value). The application of this mask may, in some instances, be seen to augment the training dataset. Over many iterations of training, the reconstruction autoencoder becomes trained to accurately reconstruct a lower left central incisor, in spite of these patches of mesh elements which have been masked or obscured.

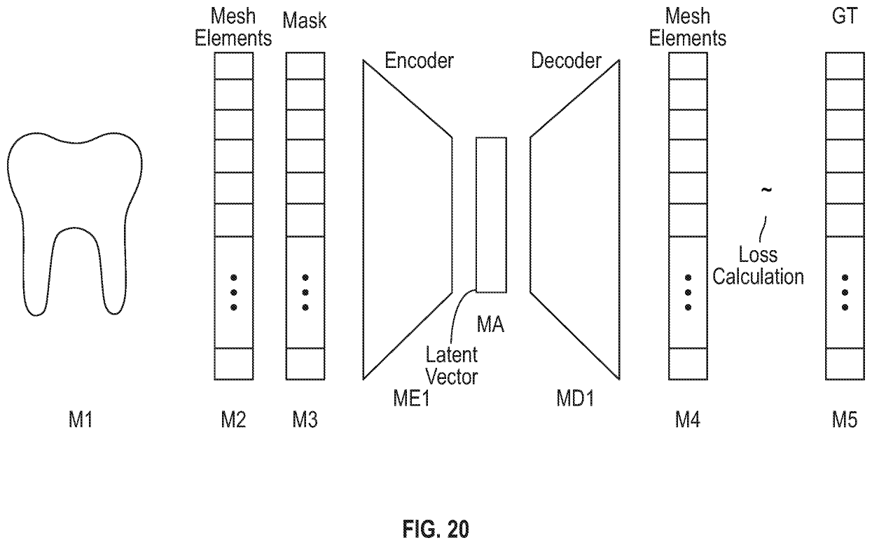

Mesh surface reconstruction may involve the process of regenerating one or more new sub-meshes within a larger mesh or modifying the positions and/or orientations of existing mesh elements (such as vertices) in an anomalous part of a mesh such that those mesh elements come to form the surface of a more desirably-shaped 3D representation, for example, by modifying or replacing the vertices (or other mesh elements) of an attachment structure in a tooth mesh such that these vertices now take the form of a smooth tooth surface (i.e., thereby effectively removing the 3D representation of the attachment from the mesh). One such approach is the implementation of a Masked Autoencoder (MAE) whereby a neural network (e.g., reconstruction autoencoder) may be trained in an unsupervised manner to “mask” portions of the surface of a tooth or other oral care mesh (such as one or more dental arches, before or after segmentation, possibly provided directly from an intraoral scanner) at the input and reconstruct the entire unmasked input data at the output (see FIG. 20). FIG. 20 illustrates an example training method for a masked autoencoder to fill-in missing mesh elements in a mesh. Once trained, the labeling information (e.g., from a reconstruction error calculation) may be used to inform the network about which vertices should be regenerated or repositioned at inference time (aka deployment). The encoder-decoder structure of the MAE largely follows the same structure as other members of the Autoencoder family but may also account for the masking of certain sub-elements within the input vector. In this case the input data may optionally be registered and/or have correspondence applied given some template mesh such that the vertices may be ordered consistently across data samples, enabling more efficient training and masking of appropriate mesh elements. In another implementation, the MAE architecture may be modified to include aspects of other (generative) network architectures such as generative adversarial neural networks (GAN) to enable more representative or accurate in-filling of the labelled mesh vertices. In the case of a GAN, a generator may be trained to perform the mesh surface reconstruction, and a discriminator may be trained, in part, to train the generator.

A tooth mesh M1 may be provided to the module (shown in FIG. 20). This example describes how an MAE may be trained to fill-in missing elements of a tooth mesh, though the technique may apply to any other oral care mesh (i.e., gums, other anatomy, brackets/attachments or other hardware such as restoration appliance components) or general form of mesh. The elements of tooth M1 (e.g., vertices, edges, faces or voxels) may be enumerated into a vector M2. This vector may be compared to a masking vector M3, and be used to set affected elements of M2 to a designated value (e.g. to set the masked elements to zero). This masking vector may be provided to the module by, for example, the mesh element labelling method 1602 described herein. The M3-masked M2 vector may be provided to encoder ME1, yielding latent vector MA. Latent vector MA may be provided to decoder MD1, yielding reconstructed mesh M4. M4 may be compared to ground truth vector M5 via a loss function, such as mean squared error (MSE) or others described herein. MSE may, in some implementations, be computed only on the reconstructed mesh elements (the mesh elements which are masked by M3 at the input). In other implementations, MSE may be computed on other mesh elements. Other loss functions are possible, such as those disclosed elsewhere in this disclosure.

Mesh correspondences may, in some implementations, be computed to give better structure to the input vector M2. The mesh elements of M2 may be rearranged in correspondence to one or more template meshes. This operation serves to standardize the ordering of mesh elements in M2, and better enable the MAE to learn the structure of certain kinds of meshes (e.g., teeth or other forms of anatomy, or appliances or hardware).

The mesh correspondence calculation procedure is advantageous, as the correspondences may impart a known order on the vector of provided mesh elements. This order may make training of the encoder or decoder faster and more accurate. The training of the encoder-decoder may converge at an earlier time when the input data vectors that have a consistent structure, as opposed to when the input data vectors which have a variable structure. Correspondences may provide better structure to the input data, such that the MAE model may focus more on the structure of the input tooth mesh and devote less network encoding to the understanding of how to identify the structure by itself.

In some implementations, the Autoencoder for Mesh Reconstruction (MAE for Mesh In-Filling) may be conditioned on optional inputs from elsewhere in this disclosure, such as a vector P pertaining to tooth dimensions, one or more latent vectors B, and/or information R relating to tooth name, designation, tooth type and/or tooth classification. The model may be conditioned on such optional inputs by concatenating such inputs with the one or more input vectors (i.e., input to the encoder) and/or by concatenating such inputs with one or more latent vectors which are outputted by the encoder in the Autoencoder for Mesh Reconstruction (MAE for Mesh In-Filling).

In some instances, an autoencoder for mesh in-filling may take as inputs one or more mesh element features (as described herein) for one or more mesh elements. Such mesh elements may improve the data quality of the latent encoding of the mesh which is produced by the autoencoder (e.g., the encoder portion of the autoencoder). Such mesh element features may improve the encoder's ability to encode aspects of the structure and/or shape of the received mesh.

The training dataset may be composed of whole, reasonably well-formed tooth meshes (or other 3D oral care representations). Mesh should be understood to encompass other 3D representations described herein (e.g., 3D point clouds, voxels, surfaces, etc.). The tooth meshes of the training dataset may be duplicated and the copied may be modified in order to generate new data samples to use for training, to augment the training dataset. In some implementations, mesh processing techniques may be used to cut-out sections of the tooth surface (or otherwise label sections to be ignored—such as with a masking token). For example, a random mesh element may be chosen, and all mesh elements within a threshold distance (e.g., geodesic distance or Euclidean distance) may be cut-out or otherwise be labeled to be ignored. In some implementations, an unsupervised approach may be used to randomly cut-out sections of the tooth surface (or label sections to be ignored—such as with a masking token) and train the model to reconstruct that missing portion(s) of mesh elements. In other implementations, sections of contiguous mesh elements may be flagged with masking token values, which are then consumed by a masking autoencoder. The masking token value may be used to overwrite one or more values of the mesh element feature vectors (e.g., the XYZ coordinates, or other mesh element features) of the mesh elements which are to be masked. The masked autoencoder may have access to data indicating the presence/absence of one or more masked mesh element in the structure of the mesh. In some implementations, the masked autoencoder may not be given information about the location of the mesh element (e.g., the X, Y or Z coordinates may be removed). Some implementations may conform to one or more operations from the following list:
1. Perform registration on every tooth in the dataset to align each tooth to a known orientation.
2. Perform correspondence of each tooth in this dataset to get an ordered vector M2 of all mesh elements (e.g., vertices) in relation to a (predefined) tooth template.
3. Split the vector M2 into equally sized chunks
4. Randomly select one or more sections in this vector M2 to become the mask M3. Label all mesh elements of each selected section as “masked” (e.g., using the masking token). In some implementations, a randomly chosen mesh element may be designated as the “seed” for a contiguous section of mesh elements. Further mesh elements may be added to this contiguous section by traversing the edges of the mesh (e.g., in depth-first or breadth-first fashions, or combinations thereof).
5. Designate the masked mesh elements to be ignored/disregarded by the masked autoencoder (e.g., by setting one or more elements of the associated mesh element feature vector of those elements to zero, null or masking token values). This is now the input vector to the masked autoencoder model at training time.
6. After the encoder of the masked autoencoder receives the input of the unmasked contiguous sections of mesh elements and generates an embedding vector as output, re-insert the masked mesh elements into their positions in the vector and influence the decoder to reconstruct the vector. The result of reconstruction is a mesh with filled-in the data in the masked mesh elements (e.g., mesh elements with masking token values). The loss may quantify the extent to which decoder MD1 of FIG. 20 reconstructs the latent vector MA into a reconstructed facsimile M4 of the input mesh M1 (which may, in some implementations be designated as the ground truth M5).

In some instances, an MAE network may be trained (e.g., using transfer learning) on examples of 3D oral care representations, such as teeth. In some implementations, after training (e.g., for a classification task), the encoder output (e.g., which may comprise a latent embedding) may be used as a representation from which to classify the content of the input data. The embeddings may be used to efficiently train another network (e.g., a set of fully connected layers) to classify the underlying data. In this case the decoder may be set aside after training, and the trained encoder may be deployed for use during inference.

In some implementations, the full list (see steps 1-6 above) may be executed during both training and inference. In this approach, the input mesh areas that are problematic or need to be modified may be masked, and the decoder's role may be to reconstruct/replace the masked areas, thus fixing whatever flaws may have been present in the input data (e.g., a chip in a tooth, crack in an appliance, or missing mesh elements due to occlusion during intraoral scanning). In this case, during training, random parts of a tooth may be masked, allowing the model to learn to fill-in masked areas in an unsupervised manner and at inference time the damaged/corrupted areas may be masked instead, for the purpose of filling-in or completing those areas.

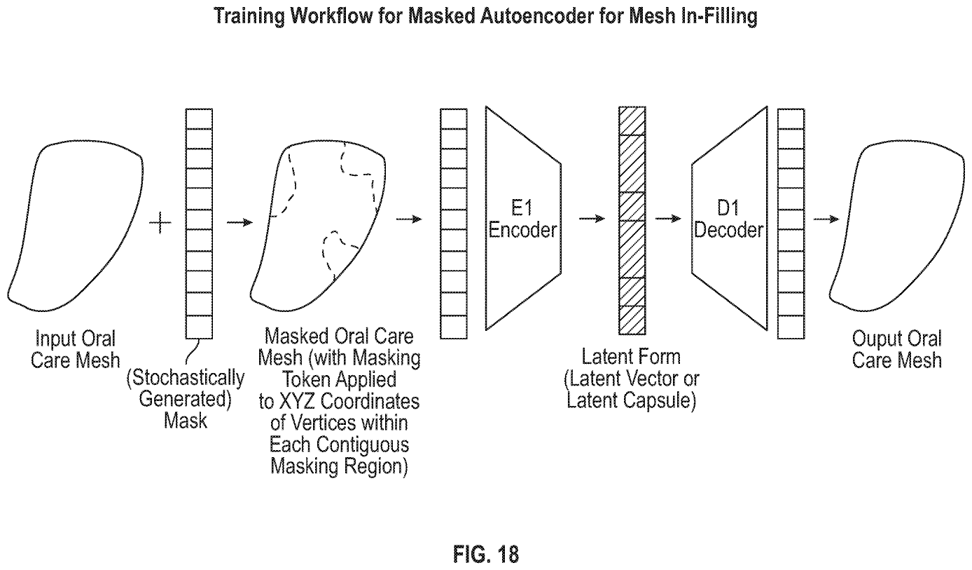

FIG. 18 shows a training method for a masked autoencoder (MAE) for the in-filling of missing aspects of 3D oral care representations. An input 3D oral care representation is received at the input. Although this particular example focuses on teeth, other types of 3D oral care representations described herein may be used in accordance with aspects of this disclosure. A mask may be randomly generated, where each element of the mask corresponds to a mesh element, and indicates whether that mesh element should have some information hidden from the masked autoencoder (e.g., by overwriting elements of the mesh element feature vector with a masking token). Information regarding the existence of a masked mesh element, and/or information regarding which other mesh elements are neighbors (e.g., by way of edges) may be provided to the MAE. However, in some implementation, certain mesh element features may be withheld from the MAE (e.g., the XYZ coordinates of a mesh element—such as a vertex or point).

The mask may be applied to the input 3D oral care representation, overwriting one or more elements of the mesh element feature vector for each mesh element (e.g., the XYZ coordinates of affected mesh elements may be overwritten with a masking token). The masked mesh elements may then be provided to the MAE, which may encode the masked data into a latent form (such as a latent vector) using an encoder, and reconstruct the latent vector into a facsimile of the input 3D oral care representation. Loss calculation may be performed to quantify the difference between the input and reconstructed forms of the 3D oral care representation. Reconstruction loss and/or KL-Divergence loss may be computed (or alternatively, one or more of the other losses disclosed herein). Such loss may be used to train, at least in part, the encoder or decoder of the masked autoencoder. The loss calculation helps to train the autoencoder to fill-in any missing aspects of a trial input 3D oral care representation, according to the distribution of the 3D oral care representations in the training dataset. Many input 3D oral care representations (e.g., tooth meshes) from cohort patient cases may be used for training. Over the course of training, the MAE learns about a distribution over the shape and/or structure of typical teeth. In some implementations, the MAE may be trained for a particular tooth type (e.g., lower left central incisor), with the advantage of improvements in data precision and the capability of the MAE to accurately reconstruct that type of tooth. The MAE enables a form of data augmentation in that each inputted training sample may be augmented with a different mask, thereby challenging the autoencoder to become robust to a wide variety of input data (e.g., different kinds of anomalies or missing mesh elements in the inputted 3D meshes or point clouds).

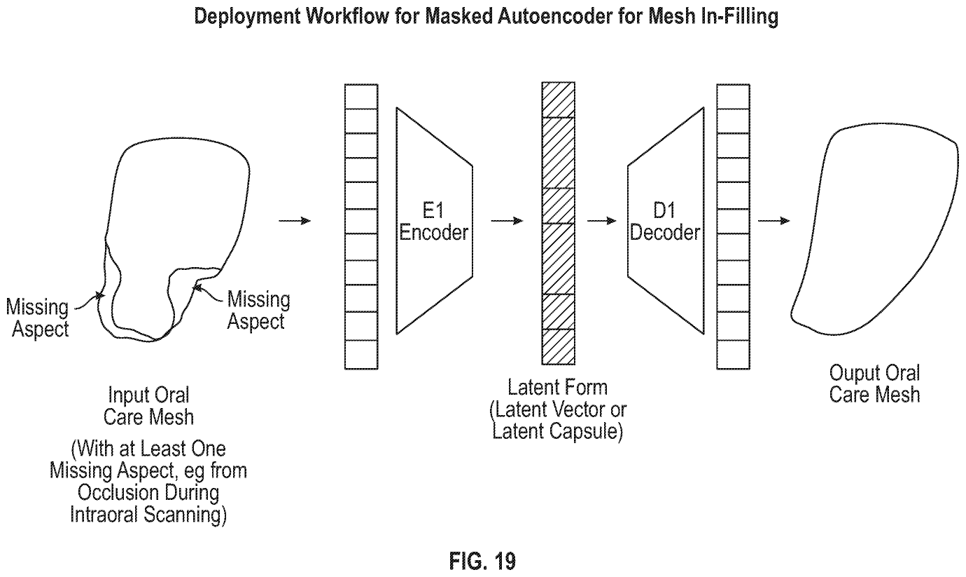

FIG. 19 shows a deployment method for the use of a trained method for a masked autoencoder for the in-filling of missing aspects of 3D oral care representations. Stated another way, FIG. 19 illustrates a deployment example of a masked autoencoder used to reconstruct an oral care mesh in accordance with aspects of this disclosure. A trial input 3D oral care representation, such as tooth, is provided to the input. This trial tooth may have some aspect which is missing, for example, due to a portion of the tooth having been obscured during intraoral scanning. The tooth mesh elements are provided to the MAE, which encodes the tooth data into a latent form and reconstructs the latent form into a repaired, augmented, or filled-in version of the inputted 3D oral care representation. The filling-in, augmentation, or repair operation draws upon the MAE's learnings about the distribution of tooth shapes and/or structures during training.

In some implementations, a MAE for mesh reconstruction may assist in the operation of a tooth mesh segmentation operation, by cleaning-up the results of dental mesh segmentation. After each tooth crown is cut away from the raw un-segmented arch, that crown may benefit from the operation of the MAE. The MAE can, for example, fill-in missing surfaces that the intraoral scanner missed due to occlusion by adjacent teeth (e.g., along the mesial or distal surfaces of the tooth). Sharp edges on a tooth mesh may, in some examples, indicate missing data. In this instance the MAE operations would follow the completion of the tooth segmentation, as a means of improving the output of tooth segmentation.

In some implementations, an operational (deployed) MAE may input a mesh and a mask which defines the area of that mesh to be altered/replaced by the MAE model. The MAE may then proceed to fill-in the missing mesh elements, as defined by the mask. Data augmentation may be employed to expand the dataset available for training the MAE. Many training data examples may be generated from the same tooth mesh by varying the mask that is applied to that tooth. A random subset of tooth mesh elements may be selected and masked-off. The resulting mesh and mask can be added to the training dataset. That same tooth mesh may be combined with a different random mask, and the resulting pair also be added to the training dataset. This may be done at runtime, with the advantage of avoiding the need to store a large dataset. Instead, the dataset may, in some implementations, be generated on-the-fly and those samples may be discarded immediately after being used in that training batch, and so on. In some examples, the randomly selected subset of tooth mesh elements may be contiguous, so as to represent a continuous portion of the tooth mesh surface. In other examples, the randomly selected subset of tooth mesh elements may correspond to more than one contiguous region of the tooth mesh surface.

In some implementations, an MAE may be trained to modify the position and/or orientation of one or more teeth in an arch for the purpose of designing a setup. In some instances, the teeth may have previously been segmented. Some of the teeth in the arch may be designated for movement and others designated for no movement (i.e., be fixed) by an algorithm or some other process.

In some implementations, the MAE may be used to modify elements of one or more tooth transforms (e.g., a 4×4 transformation matrix, or a vector transform, or the like). Such transforms may be used to place teeth, appliance components or fixture model components into poses which are suitable for appliance generation. For example, teeth may be placed into setups poses. For example, the MAE may be trained to fill-in the elements of a transformation matrix (or other transform). In some instances, all transform elements may be filled-in, and in other instances only a subset of transform elements may be filled-in by techniques of this disclosure.

In some instances, one or more teeth may be designed to not move during orthodontic treatment. The MAE may be trained to manipulate the teeth which are to be moved in a manner such that the fixed teeth do not move. The benefits may include minimal tooth movement for the patient, which may also give better anchoring to the aligner to push against the teeth that aren't to be moved.

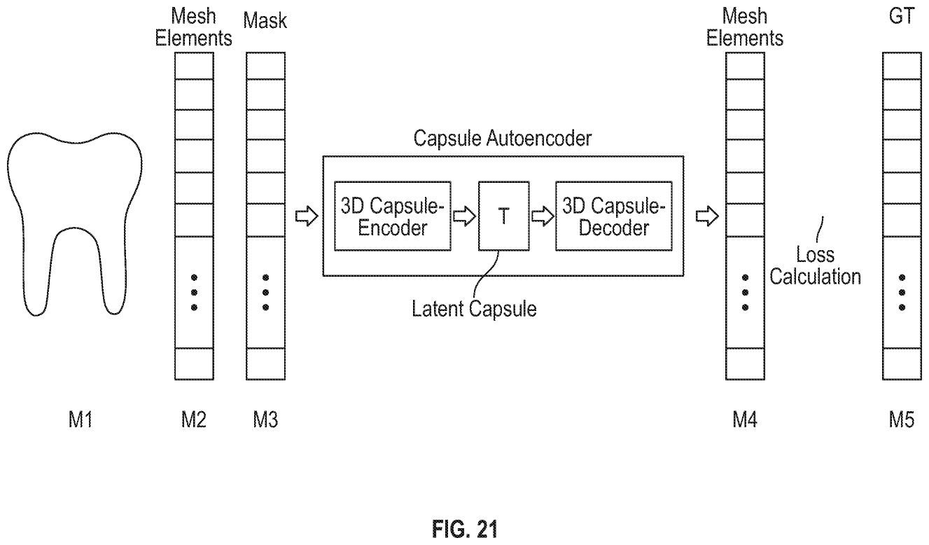

FIG. 21 illustrates an example training method of a masked capsule autoencoder to fill in missing mesh elements in a mesh, in accordance with one or more aspects of this disclosure. In some implementations, such as in FIG. 21, the MAE for mesh in-filling may replace the encoder and decoder structures with capsule-encoder and capsule-decoder structures, respectively. Other implementation considerations may be duplicated from the aforementioned description.

In some implementations, a neural network may be trained for mesh (or point cloud or voxel) completion with the aid of skip connections. Skip connections may connect the output of an encoder to the input of a corresponding decoder at each of a succession of levels of resolution (e.g., such as in the U-Net). Skip connections between encoder and decoder may facilitate training/learning of a representation of the input 3D oral care representation and may generally promote information flow around the network.

The generative implementations described herein may, in some implementations, include one or more hierarchical feature extraction modules (e.g., modules which extract global, intermediate or local neural network features from a 3D representation—such as a point cloud). Examples of hierarchical neural network feature extraction modules (HNNFEM) include 3D SWIN Transformer architectures, U-Nets or pyramid encoder-decoders, among others. A HNNFEM may be trained to generate multi-scale voxel (or point or other mesh element) embeddings of a 3D representation (or multi-scale embeddings of other mesh elements described herein). For example, a HNNFEM of one or more layers (or levels) may be trained on 3D representations of patient dentitions to generate neural network feature embeddings which encompass global, intermediate or local aspects of the 3D representation of the patient's dentition.

Techniques of this disclosure may, in some implementations, use PointNet, PointNet++, or derivative neural networks (e.g., networks trained via transfer learning using either PointNet or PointNet++ as a basis for training) to extract local or global neural network features from a 3D point cloud or other 3D representation (e.g., a 3D point cloud describing aspects of the patient's dentition-such as teeth or gums). Techniques of this disclosure may, in some implementations, use U-Nets to extract local or global neural network features from a 3D point cloud or other 3D representation.

3D oral care representations are described herein as such because 3-dimensional representations are currently state of the art. Nevertheless, 3D oral care representations are intended to be used in a non-limiting fashion to encompass any representations of 3-dimensions or higher orders of dimensionality (e.g., 4D, 5D, etc.), and it should be appreciated that machine learning models can be trained using the techniques disclosed herein to operate on representations of higher orders of dimensionality.

In some instances, input data may comprise 3D mesh data, 3D point cloud data, 3D surface data, 3D polyline data, 3D voxel data, or data pertaining to a spline (e.g., control points). An encoder-decoder structure may comprise one or more encoders, or one or more decoders. In some implementations, the encoder may take as input mesh element feature vectors for one or more of the inputted mesh elements. By processing mesh element feature vectors, the encoder is trained in a manner to generate more accurate representations of the input data. For example, the mesh element feature vectors may provide the encoder with more information about the shape and/or structure of the mesh, and therefore the additional information provided allows the encoder to make better-informed decisions and/or generate more-accurate latent representations of the mesh. Examples of encoder-decoder structures include U-Nets, autoencoders or transformers (among others). A representation generation module may comprise one or more encoder-decoder structures (or portions of encoders-decoder structures—such as individual encoders or individual decoders). A representation generation module may generate an information-rich (optionally reduced-dimensionality) representation of the input data, which may be more easily consumed by other generative or discriminative machine learning models.

A U-Net may comprise an encoder, followed by a decoder. The architecture of a U-Net may resemble a U shape. The encoder may extract one or more global neural network features from the input 3D representation, zero or more intermediate-level neural network features, or one or more local neural network features (at the most local level as contrasted with the most global level). The output from each level of the encoder may be passed along to the input of corresponding levels of a decoder (e.g., by way of skip connections). Like the encoder, the decoder may operate on multiple levels of global-to-local neural network features. For instance, the decoder may output a representation of the input data which may contain global, intermediate or local information about the input data. The U-Net may, in some implementations, generate an information-rich (optionally reduced-dimensionality) representation of the input data, which may be more easily consumed by other generative or discriminative machine learning models.

An autoencoder may be configured to encode the input data into a latent form. An autoencoder may train an encoder to reformat the input data into a reduced-dimensionality latent form in between the encoder and the decoder, and then train a decoder to reconstruct the input data from that latent form of the data. A reconstruction error may be computed to quantify the extent to which the reconstructed form of the data differs from the input data. The latent form may, in some implementations, be used as an information-rich reduced-dimensionality representation of the input data which may be more easily consumed by other generative or discriminative machine learning models. In most scenarios, an autoencoder may be trained to input a 3D representation, encode that 3D representation into a latent form (e.g., a latent embedding), and then reconstruct a close facsimile of that input 3D representation as the output.

A transformer may be trained to use self-attention to generate, at least in part, representations of its input. A transformer may encode long-range dependencies (e.g., encode relationships between a large number of inputs). A transformer may comprise an encoder or a decoder. Such an encoder may, in some implementations, operate in a bi-directional fashion or may operate a self-attention mechanism. Such a decoder may, in some implementations, may operate a masked self-attention mechanism, may operate a cross-attention mechanism, or may operate in an auto-regressive manner. The self-attention operations of the transformers described herein may, in some implementations, relate different positions or aspects of an individual 3D oral care representation in order to compute a reduced-dimensionality representation of that 3D oral care representation. The cross-attention operations of the transformers described herein may, in some implementations, mix or combine aspects of two (or more) different 3D oral care representations. The auto-regressive operations of the transformers described herein may, in some implementations, consume previously generated aspects of 3D oral care representations (e.g., previously generated points, point clouds, transforms, etc.) as additional input when generating a new or modified 3D oral care representation. The transformer may, in some implementations, generate a latent form of the input data, which may be used as an information-rich reduced-dimensionality representation of the input data, which may be more easily consumed by other generative or discriminative machine learning models.

In some implementations, an encoder-decoder structure may first be trained as an autoencoder. In deployment, one or more modifications may be made to the latent form of the input data. This modified latent form may then proceed to be reconstructed by the decoder, yielding a reconstructed form of the input data which differs from the input data in one or more intended aspects. Oral care arguments, such as oral care parameters or oral care metrics may be supplied to the encoder, the decoder, or may be used in the modification of the latent form, to influence the encoder-decoder structure in generating a reconstructed form that has desired characteristics (e.g., characteristics which may differ from that of the input data).

Techniques of this disclosure may, in some instances, be trained using federated learning. Federated learning may enable multiple remote clinicians to iteratively improve a machine learning model (e.g., validation of 3D oral care representations, mesh segmentation, mesh cleanup, other techniques which involve labeling mesh elements, coordinate system prediction, non-organic object placement on teeth, appliance component generation, tooth restoration design generation, techniques for placing 3D oral care representations, setups prediction, generation or modification of 3D oral care representations using autoencoders, generation or modification of 3D oral care representations using transformers, generation or modification of 3D oral care representations using diffusion models, 3D oral care representation classification, imputation of missing values), while protecting data privacy (e.g., the clinical data may not need to be sent “over the wire” to a third party). Data privacy is particularly important to clinical data, which is protected by applicable laws. A clinician may receive a copy of a machine learning model, use a local machine learning program to further train that ML model using locally available data from the local clinic, and then send the updated ML model back to the central hub or third party. The central hub or third party may integrate the updated ML models from multiple clinicians into a single updated ML model which benefits from the learnings of recently collected patient data at the various clinical sites. In this way, a new ML model may be trained which benefits from additional and updated patient data (possibly from multiple clinical sites), while those patient data are never actually sent to the 3rd party. Training on a local in-clinic device may, in some instances, be performed when the device is idle or otherwise be performed during off-hours (e.g., when patients are not being treated in the clinic). Devices in the clinical environment for the collection of data and/or the training of ML models for techniques described herein may include intra-oral scanners, CT scanners, X-ray machines, laptop computers, servers, desktop computers or handheld devices (such as smart phones with image collection capability). In addition to federated learning techniques, in some implementations, contrastive learning may be used to train, at least in part, the ML models described herein. Contrastive learning may, in some instances, augment samples in a training dataset to accentuate the differences in samples from difference classes and/or increase the similarity of samples of the same class.

In some instances, a local coordinate system for a 3D oral care representation, such as a tooth, may be described by one or more transforms (e.g., an affine transformation matrix, translation vector or quaternion). Systems of this disclosure may be trained for coordinate system prediction using past cohort patient case data. The past patient data may include at least: one or more tooth meshes or one or more ground truth tooth coordinate systems. Machine learning models such as: U-Nets, encoders, autoencoders, pyramid encoder-decoders, transformers, or convolution and/or pooling layers, may be trained for coordinate system prediction. Representation learning may determine a representation of a tooth (e.g., encoding a mesh or point cloud into a latent representation, for example, using a U-Net, encoder, transformer, convolution and/or pooling layers or the like), and then predict a transform for that representation (e.g., using a trained multilayer perceptron, transformer, encoder, transformer, or the like) that defines a local coordinate system for that representation (e.g., comprising one or more coordinate axes). In the instance where the coordinate system is predicted for a tooth mesh, the mesh convolutional techniques described herein can leverage invariance to rotations, translations, and/or scaling of that tooth mesh to generate predications that techniques that are not invariant to the rotations, translations, and/or scaling of that tooth mesh cannot generate. Pose transfer techniques may be trained for coordinate system prediction, in the form of predicting a transform for a tooth. Reinforcement learning techniques may be trained for coordinate system prediction, in the form of predicting a transform for a tooth.

Machine learning models such as: U-Nets, encoders, autoencoders, pyramid encoder-decoders, transformers, or convolution and/or pooling layers, may be trained as a part of a method for hardware (or appliance component) placement. Representation learning may train a first module to determine an embedded representation of a 3D oral care representation (e.g., encoding a mesh or point cloud into a latent form using an autoencoder, or using a U-Net, encoder, transformer, block of convolution and/or pooling layers or the like). That representation may comprise a reduced dimensionality form and/or information-rich version of the inputted 3D oral care representation. In some implementations, the generation of a representation may be aided by the calculation of a mesh element feature vector for one or more mesh elements (e.g., each mesh element). In some implementations, a representation may be computed for a hardware element (or appliance component). Such representations are suitable to be provided to a second module, which may perform a generative task, such as transform prediction (e.g., a transform to place a 3D oral care representation relative to another 3D oral care representation, such as to place a hardware element or appliance component relative to one or more teeth) or 3D point cloud generation. Such a transform may comprise an affine transformation matrix, translation vector or quaternion or the like. Machine learning models which may be trained to predict a transform to place a hardware element (or appliance component) relative to elements of patient dentition include: MLP, transformer, encoder, or the like. Systems of this disclosure may be trained for 3D oral care appliance placement using past cohort patient case data. The past patient data may include at least: one or more ground truth transforms and one or more 3D oral care representations (such as tooth meshes, or other elements of patient dentition). In the instance where a U-Net (among other neural networks) is trained to generate the representations of tooth meshes, the mesh convolution and/or mesh pooling techniques described herein leverage invariance to rotations, translations, and/or scaling of that tooth mesh to generate predications that techniques that are not invariant to the rotations, translations, and/or scaling of that tooth mesh cannot generate.

Techniques described herein may be trained to generate or modify 3D oral care representations (e.g., tooth restoration designs, appliance components, and other examples of 3D oral care representations described herein). For example, the techniques may generate or modify mesh element labels for 3D representations, which may enable those 3D representations to undergo mesh segmentation, mesh cleanup, or mesh modification. Such 3D representations may comprise point clouds, polylines, meshes, voxels and the like. Such 3D oral care representation may be generated according to the requirements of the oral care arguments which may, in some implementations, be supplied to the generative model. Oral care arguments may include oral care parameters as disclosed herein, or other real-valued, text-based or categorical inputs which specify intended aspects of the one or more 3D oral care representations which are to be generated. In some instances, oral care arguments may include oral care metrics, which may describe intended aspects of the one or more 3D oral care representations which are to be generated (e.g., to describe intended aspects of mesh element labels which are generated for use in mesh cleanup). Oral care arguments are specifically adapted to the implementations described herein. For example, the oral care arguments may specify the intended the designs (e.g., including shape and/or structure) of 3D oral care representations which may be generated (or modified) according to techniques described herein. In short, implementations using the specific oral care arguments disclosed herein generate more accurate 3D oral care representations than implementations that do not use the specific oral care arguments. In some instances, a text encoder may encode a set of natural language instructions from the clinician (e.g., generate a text embedding). A text string may comprise tokens. An encoder for generating text embeddings may, in some implementations, apply either mean-pooling or max-pooling between the token vectors. In some instances, a transformer (e.g., BERT or Siamese BERT) may be trained to extract embeddings of text for use in digital oral care (e.g., by training the transformer on examples of clinical text, such as those given below). In some instances, such a model for generating text embeddings may be trained using transfer learning (e.g., initially trained on another corpus of text, and then receive further training on text related to digital oral care). Some text embeddings may encode text at the word level. Some text embeddings may encode text at the token level. A transformer for generating a text embedding may, in some implementations, be trained, at least in part, with a loss calculation which compares predicted outputs to ground truth outputs (e.g., softmax loss, multiple negatives ranking loss, MSE margin loss, cross-entropy loss or the like). In some instances, the non-text arguments, such as real values or categorical values, may be converted to text, and subsequently embedded using the techniques described herein. The following are examples of natural language instructions that may be issued by a clinician to the generative models described herein: “For each tooth crown in the arch, fill-in missing portions of the tooth (e.g., portions which may have been missed during intraoral scanning).”, or “Label anomalous mesh elements of a dental arch, anomalous mesh elements which may correspond to errors in scanning or to clinical diagnosis.”.

### Examples

Example 1. A method comprising:
receiving, by processing circuitry of a computing device, an input 3D representation of oral care data;
modifying, by the processing circuitry, the input 3D representation of oral care data to form a modified 3D representation of oral care data, at least in part by replacing at least one coordinate of a mesh element of the input 3D representation of oral care data with a masking token;
providing, by the processing circuitry, as training data, the modified 3D representation of oral care data to a masked autoencoder model; and
training, by the processing circuitry, the masked autoencoder model to reconstruct a facsimile of the input 3D representation of oral care data.

Example 2. The method of Example 1, wherein the mesh element is at least one of a vertex or a point.

Example 3. The method of Example 1, wherein the input 3D representation of oral care data is a 3D mesh.

Example 4. The method of Example 1, wherein the input 3D representation of oral care data is a 3D point cloud

Example 5. The method of Example 1, wherein the masking token signals to the masked autoencoder that the mesh element is present in a structure of the input 3D representation of oral care data, and where the coordinates of that mesh element are not made available to the autoencoder.

Example 6. The method of Example 1, wherein the modified 3D representation of oral care data includes a plurality of mesh elements masked in contiguous blocks.

Example 7. The method of Example 1, further comprising applying a mask to the input 3D representation of oral care data prior to providing the training data to the masked autoencoder.

Example 8. The method of Example 1, wherein the input 3D representation of oral care data represents a tooth.

Example 9. The method of Example 8, wherein training the masked autoencoder comprises training the masked autoencoder based on distribution information associated with the input 3D representation of oral care data.

Example 10. The method of Example 7, further comprising randomly generating the mask.

Example 11. The method of Example 1, wherein the masked autoencoder comprises a multi-dimensional encoder configured to encode the input 3D representation of oral care data to a latent space representation and a multi-dimensional decoder configured to reconstruct the latent space representation into the facsimile of the input 3D representation of oral care data.

Example 12. The method of Example 1, further comprising computing a reconstruction error to quantify a difference between the input 3D representation of oral care data and the facsimile of the input 3D representation of oral care data.

Example 13. The method of Example 12, wherein computing the reconstruction error comprises computing a term associated with at least one of a reconstruction loss calculation or KL-divergence calculation.

Example 14. The method of Example 1, further comprising, providing, as additional input data to the masked autoencoder, at least one of: (i) one or more vectors P containing at least one value pertaining to at least one method of computing a dimension of at least one tooth, or (ii) one or more vectors R at least one of tooth name, designation, tooth type and tooth classification.

Example 15. The method of Example 1, wherein the masked autoencoder is a reconstruction autoencoder.

Example 16. The method of Example 1, wherein the reconstruction autoencoder is a variational autoencoder (VAE).

Example 17. A method comprising:
receiving, by processing circuitry of a computing device, an input 3D representation of oral care data;
providing, by the processing circuitry, as training data, the 3D representation of oral care data to a trained masked autoencoder model as execution-phase input;
executing, by the processing circuitry, the trained masked autoencoder model to fill in one or more missing mesh elements of the input 3D representation of oral care data to form a reconstructed 3D representation of oral care data; and
outputting the reconstructed oral care representation.

Example 18. The method of Example 17, further comprising identifying, by the processing circuitry, the one or more missing mesh elements of the input 3D representation of oral care data.

Example 19. The method of Example 17, wherein the one or more missing mesh elements comprise at least one of one or more vertices, one or more faces, one or more edges, one or more points or one or more voxels.

Example 20. The method of Example 17, wherein the input 3D representation of oral care data is a 3D mesh.

Example 21. The method of Example 17, wherein the input 3D representation of oral care data is a 3D point cloud

Example 22. The method of Example 17, wherein the input 3D representation of oral care data represents a tooth.

Example 23. The method of Example 17, wherein the masked autoencoder is a variational autoencoder (VAE).

Example 24. The method of Example 17, wherein the computing device is deployed at a clinical context.

Example 25. The method of Example 24, wherein the method is performed at the clinical context.

Example 26. A method comprising:
receiving, by processing circuitry of a computing device, an input 3D representation of oral care data;
providing, by the processing circuitry, as training data, the input 3D representation of oral care data to a completion model, wherein the completion model comprises at least one of: at least one encoder, at least one decoder, or at least on skip connection between an encoder and a decoder; and
training, by the processing circuitry, the completion neural network model to reconstruct a facsimile of the input 3D representation of oral care data, wherein one or more aspects missing of the input 3D representation of oral care data have been filled in.

1. A method comprising:
receiving, by processing circuitry of a computing device, an input three-dimensional (3D) representation of oral care data;
executing, by the processing circuitry, an encoder of a trained autoencoder network to encode the input 3D representation of oral care data into a latent space representation having a lower order of dimensionality than the first 3D representation of oral care data;
executing, by the processing circuitry, a decoder of the trained autoencoder network to reconstruct the latent space representation to form an output 3D representation of oral care data that is a facsimile of the input 3D representation of oral care data; and
computing, by the processing circuitry, a reconstruction error to quantify a difference between a at least one mesh element of the input 3D representation of oral care data and a corresponding at least one mesh element of the output 3D representation of oral care data.

2. The method of claim 1, wherein the input 3D representation of oral care data comprises at least one of a 3D mesh, a point cloud, or a voxelized representation.

3. The method of claim 1, further comprising performing, by the processing circuitry, an anomaly detection based on the reconstruction error.

4. The method of claim 1, wherein each of the at least one mesh element and the corresponding at least one mesh element comprise at least one of a respective edge, a respective vertex, a respective face, a respective voxel, or a respective point of a point cloud.

5. The method of claim 1, further comprising:
determining that the reconstruction error exceeds a predetermined threshold value; and
in response to determining that the reconstruction error exceeds the predetermined threshold value, assigning, by the processing circuitry, the at least one mesh element or the corresponding at least one mesh element a classification label.

6. The method of claim 1, wherein the trained autoencoder network comprises a trained variational autoencoder (VAE) network.

7. The method of claim 1, wherein computing the reconstruction error comprises computing a distance between at least one aspect of the input 3D oral care representation and the corresponding aspect in the output 3D representation of oral care data.

8. The method of claim 7, wherein the trained autoencoder network is trained according to a paradigm that includes normalizing flows.

9. The method of claim 1, further comprising providing, by the processing circuitry, additional execution-phase input comprising one or more 3D meshes or one or more 3D point clouds describing one or more teeth of the input 3D representation of oral care data to the trained autoencoder network.

10. The method of claim 1, further comprising, providing, by the processing circuitry, as additional input data to the autoencoder model, at least one of: (i) one or more vectors P containing at least one value pertaining to at least one method of computing a dimension of at least one tooth, or (ii) one or more vectors R at least one of tooth name, designation, tooth type and tooth classification.

11. The method of claim 1, further comprising computing, by the processing circuitry, a loss associated with at least one of a term associated with a reconstruction loss calculation, or a term associated with a KL-divergence loss calculation.

12. The method of claim 1, wherein the computing device is deployed at a clinical context, and wherein the method is performed in near real-time during an encounter with a patient.

13. A device comprising:
interface hardware configured to receive an input three-dimensional (3D) representation of oral care data;
processing circuitry configured to:
execute an encoder of a trained autoencoder network to encode the input 3D representation of oral care data into a latent space representation;
execute a decoder of the trained autoencoder network to reconstruct the latent space representation to form an output 3D representation of oral care data that is a facsimile of the input 3D representation of oral care data; and
compute a reconstruction error to quantify a difference between at least one mesh element of the input 3D representation of oral care data and a corresponding at least one mesh element of the output 3D representation of oral care data; and
a memory unit configured to store the reconstruction error.

14. The device of claim 13, wherein the input 3D representation of oral care data comprises at least one of a 3D mesh, a point cloud, or a voxelized representation.

15. The device of claim 13, wherein the processing circuitry is further configured to perform an anomaly detection based on the reconstruction error.

16. The device of claim 13, wherein each of the at least one mesh element and the corresponding at least one mesh element comprise at least one of a respective edge, a respective vertex, a respective face, a respective voxel, or a respective point of a point cloud.

17. The device of claim 13, wherein the processing circuitry is further configured to:
determining that the reconstruction error exceeds a predetermined threshold value; and
in response to determining that the reconstruction error exceeds the predetermined threshold value, assigning, by the processing circuitry, the at least one mesh element or the corresponding at least one mesh element a classification label.

18. The device of claim 13, wherein the trained autoencoder network comprises a trained variational autoencoder (VAE) network.

19. The device of claim 13, wherein to compute the reconstruction error, the processing circuitry is configured to compute a distance between at least one aspect of the input 3D representation of oral care data and the corresponding aspect in the output 3D representation of oral care data.

20. The device of claim 13, wherein the processing circuitry is further configured to provide additional execution-phase input comprising one or more 3D meshes or one or more 3D point clouds describing one or more teeth of the input 3D oral care representation to the trained autoencoder network.
